(19) United States
(12) Patent Application Publication
(10) Pub. No.: US 2023/0384160 A1
(43) Pub. Date: Nov. 30, 2023

(54) LIGHT RECEIVING DEVICE

(71) Applicant: SONY SEMICONDUCTOR SOLUTIONS CORPORATION, KANAGAWA (JP)

(72) Inventor: HISASHI AKIYAMA, KANAGAWA (JP)

(21) Appl. No.: 18/249,759

(22) PCT Filed: Sep. 16, 2021
(86) PCT No.: PCT/JP2021/034101

§ 371 Date: Apr. 20, 2023

(30) Foreign Application Priority Data
Oct. 30, 2020 (JP) 2020-182692

(51) Int. Cl. G01J 4/04; H01L 27/146; G02B 5/30

(52) U.S. Cl. CPC G01J 4/04; H01L 27/14636; G02B 5/3058; H01L 27/14625

(57) ABSTRACT

A light receiving device according to an embodiment of the present disclosure includes a plurality of photoelectric conversion element units. Each of the photoelectric conversion element units includes a plurality of photoelectric conversion elements, the photoelectric conversion elements being M×N in total number, with M photoelectric conversion elements arranged in a first direction, and N photoelectric conversion elements arranged in a second direction. Each of the photoelectric conversion elements includes a quarter wavelength layer, a wire grid polarizer, and a photoelectric conversion section that are disposed in this order from a light entrance side. The M photoelectric conversion elements disposed side by side along the first direction include the quarter wavelength layers that have the same fast axis orientation. The N photoelectric conversion elements disposed side by side along the second direction include the quarter wavelength layers that have different fast axis orientations. The N photoelectric conversion elements disposed side by side along the second direction include the wire grid polarizers that have the same polarization orientation. The M photoelectric conversion elements disposed side by side along the first direction include the wire grid polarizers that have different polarization orientations.

### TECHNICAL FIELD

The present disclosure relates to a light receiving device, and more specifically, to a light receiving device including a photoelectric conversion element with a wire grid polarizer and a quarter wavelength layer.

### BACKGROUND ART

A photoelectric conversion element and a light receiving device that include a wire grid polarizer (Wire Grid Polarizer, WGP) and a quarter wavelength layer are known from Japanese Unexamined Patent Application Publication No. 2020-013842, for example. Specifically, the photoelectric conversion element includes the quarter wavelength layer, the wire grid polarizer, and a photoelectric conversion section that are disposed in this order from a light entrance side.

### CITATION LIST

### Patent Literature

Patent Literature 1: Japanese Unexamined Patent Application Publication No. 2020-013842

### SUMMARY OF THE INVENTION

The photoelectric conversion element disclosed in this patent publication makes it possible to change a polarized state of light entering the photoelectric conversion element into another polarized state, and allows the polarized state thus changed to be efficiently detected by the photoelectric conversion section via the wire grid polarizer. Accordingly, it is possible to provide a light receiving device for examining whether the polarized state is a left-handed circularly polarized state or a right-handed circularly polarized state, for example. However, there is strong demand for a light receiving device that makes it possible to easily know what polarized light component is included in a large amount in light, a light receiving device that makes it possible to easily know a so-called degree of polarization, or a light receiving device that makes it possible to extract light having specific linear polarization.

Accordingly, it is desirable to provide a light receiving device that makes it possible to easily know what polarized light component is included in a large amount in light. Further, it is desirable to provide a method of easily measuring a polarized state of an object to be observed. Moreover, it is desirable to provide a light receiving device that makes it possible to easily know the so-called degree of polarization. Further, it is desirable to provide a light receiving device that makes it possible to extract light having specific linear polarization.

A light receiving device according to a first aspect of the present disclosure includes a plurality of photoelectric conversion element units.

Each of the photoelectric conversion element units includes a plurality of photoelectric conversion elements, the photoelectric conversion elements being M×N in total number, with M photoelectric conversion elements arranged in a first direction, and N photoelectric conversion elements arranged in a second direction different from the first direction,
each of the photoelectric conversion elements includes a quarter wavelength layer, a wire grid polarizer, and a photoelectric conversion section that are disposed in this order from a light entrance side,
the M photoelectric conversion elements disposed side by side along the first direction include the quarter wavelength layers that have the same fast axis orientation,
the N photoelectric conversion elements disposed side by side along the second direction include the quarter wavelength layers that have different fast axis orientations,
the N photoelectric conversion elements disposed side by side along the second direction include the wire grid polarizers that have the same polarization orientation, and
the M photoelectric conversion elements disposed side by side along the first direction include the wire grid polarizers that have different polarization orientations.

A polarized state measuring method for an object according to the present disclosure is a polarized state measuring method for an object using a light receiving device.

The light receiving device includes a plurality of photoelectric conversion element units,
each of the photoelectric conversion element units includes a plurality of photoelectric conversion elements, the photoelectric conversion elements being M×N in total number, with M photoelectric conversion elements arranged in a first direction, and N photoelectric conversion elements arranged in a second direction different from the first direction,
each of the photoelectric conversion elements includes a quarter wavelength layer, a wire grid polarizer, and a photoelectric conversion section that are disposed in this order from a light entrance side,
the M photoelectric conversion elements disposed side by side along the first direction include the quarter wavelength layers that have the same fast axis orientation,
the N photoelectric conversion elements disposed side by side along the second direction include the quarter wavelength layers that have different fast axis orientations,
the N photoelectric conversion elements disposed side by side along the second direction include the wire grid polarizers that have the same polarization orientation, and
the M photoelectric conversion elements disposed side by side along the first direction include the wire grid polarizers that have different polarization orientations.

The polarized state measuring method includes
acquiring image data by capturing an image of the object with the light receiving device, and
obtaining a comparison result by comparing, at the light receiving device, the image data acquired that indicates a polarized state with standard polarized state data of a standard object.

A light receiving device according to a second aspect of the present disclosure includes a plurality of photoelectric conversion element units.

Each of the photoelectric conversion element units includes a first photoelectric conversion element, a second photoelectric conversion element, a third photoelectric conversion element, a fourth photoelectric conversion element, a fifth photoelectric conversion element, and a sixth photoelectric conversion element,
the first photoelectric conversion element, the second photoelectric conversion element, the third photoelectric conversion element, and the fourth photoelectric conversion element each include a wire grid polarizer and a photoelectric conversion section that are disposed in this order from a light entrance side,
the fifth photoelectric conversion element and the sixth photoelectric conversion element each include a quarter wavelength layer, a wire grid polarizer, and a photoelectric conversion section that are disposed in this order from the light entrance side,
a polarization orientation targeted for transmission by the wire grid polarizer included in the first photoelectric conversion element is α degrees,
a polarization orientation targeted for transmission by the wire grid polarizer included in the second photoelectric conversion element is (α+45) degrees,
a polarization orientation targeted for transmission by the wire grid polarizer included in the third photoelectric conversion element is (α+90) degrees,
a polarization orientation targeted for transmission by the wire grid polarizer included in the fourth photoelectric conversion element is (α+135) degrees,
a polarization orientation targeted for transmission by the wire grid polarizer included in the fifth photoelectric conversion element is α′ degrees,
a polarization orientation targeted for transmission by the wire grid polarizer included in the sixth photoelectric conversion element is α′ degrees, and
where a fast axis orientation of the quarter wavelength layer included in the fifth photoelectric conversion element is β degrees, a fast axis orientation of the quarter wavelength layer included in the sixth photoelectric conversion element is (β±90) degrees.

A light receiving device according to a third aspect of the present disclosure includes a plurality of photoelectric conversion element units.

Each of the photoelectric conversion element units includes a first photoelectric conversion element, a second photoelectric conversion element, a third photoelectric conversion element, and a fourth photoelectric conversion element,
the first photoelectric conversion element, the second photoelectric conversion element, the third photoelectric conversion element, and the fourth photoelectric conversion element each include a first quarter wavelength layer, a second quarter wavelength layer, a wire grid polarizer, and a photoelectric conversion section that are disposed in this order from a light entrance side,
a polarization orientation targeted for transmission by the wire grid polarizer included in the first photoelectric conversion element is α degrees,
a polarization orientation targeted for transmission by the wire grid polarizer included in the second photoelectric conversion element is (α+45) degrees,
a polarization orientation targeted for transmission by the wire grid polarizer included in the third photoelectric conversion element is (α+90) degrees,
a polarization orientation targeted for transmission by the wire grid polarizer included in the fourth photoelectric conversion element is (α+135) degrees,
a fast axis orientation of the first quarter wavelength layer included in the first photoelectric conversion element is β degrees,
a fast axis orientation of the first quarter wavelength layer included in the second photoelectric conversion element is (β+45) degrees,
a fast axis orientation of the first quarter wavelength layer included in the third photoelectric conversion element is (β+90) degrees,
a fast axis orientation of the first quarter wavelength layer included in the fourth photoelectric conversion element is (β+135) degrees, and
in each of the photoelectric conversion elements, an angle formed between a fast axis orientation of the second quarter wavelength layer and the fast axis orientation of the first quarter wavelength layer is ±45 degrees.

### BRIEF DESCRIPTION OF THE DRAWINGS

FIGS. 1A and 1B are conceptual diagrams respectively illustrating an order of arrangement of N quarter wavelength layers included in a photoelectric conversion element unit and an order of arrangement of M wire grid polarizers included therein, in a light receiving device of Example 1.

FIG. 2 is a conceptual diagram of an order of arrangement of 8×8 photoelectric conversion elements included in the photoelectric conversion element unit in the light receiving device of Example 1.

FIG. 3 is a schematic partial cross-sectional view of a portion of the photoelectric conversion element unit in the light receiving device of Example 1.

FIG. 4 is a schematic plan view of a wire grid polarizer included in a photoelectric conversion element in the light receiving device of Example 1.

FIG. 5 is a schematic plan view of a wire grid polarizer included in a photoelectric conversion element in the light receiving device of Example 1.

FIGS. 6A and 6B are schematic diagrams each qualitatively illustrating amounts of light (light intensities) received by photoelectric conversion sections of the photoelectric conversion elements included in the photoelectric conversion element unit in the light receiving device of Example 1.

FIGS. 7A and 7B are schematic diagrams each qualitatively illustrating amounts of light (light intensities) received by the photoelectric conversion sections of the photoelectric conversion elements included in the photoelectric conversion element unit in the light receiving device of Example 1.

FIGS. 8A and 8B are schematic diagrams each qualitatively illustrating amounts of light (light intensities) received by the photoelectric conversion sections of the photoelectric conversion elements included in the photoelectric conversion element unit in the light receiving device of Example 1.

FIGS. 9A, 9B, and 9C respectively illustrate an image obtainable in a state similar to that in FIG. 6A, an image obtainable in a state similar to that in FIG. 8A, and an image obtainable in a state similar to that in FIG. 8B.

FIG. 10 is an example of a schematic diagram qualitatively illustrating amounts of light (light intensities) received by the photoelectric conversion sections of the photoelectric conversion elements included in the photoelectric conversion element unit when an abnormality is found in the light receiving device of Example 1.

FIG. 11 is a schematic partial cross-sectional view of a portion of a photoelectric conversion element unit in a modification example of the light receiving device of Example 1.

FIG. 12 is an equivalent circuit diagram of a photoelectric conversion section in the modification example of the light receiving device of Example 1.

FIG. 13 is a schematic partial cross-sectional view of a photoelectric conversion element unit in a light receiving device of Example 2.

FIG. 14 is a conceptual diagram of an order of arrangement of 3×2 photoelectric conversion elements included in the photoelectric conversion element unit in the light receiving device of Example 2.

FIGS. 15A and 15B are schematic diagrams respectively illustrating polarized states of light passing through the quarter wavelength layers included in the photoelectric conversion element unit and states of light passing through the wire grid polarizers included therein, in the light receiving device of Example 2.

FIGS. 16A and 16B are diagrams schematically illustrating a fast axis orientation of a quarter wavelength layer included in a fifth photoelectric conversion element in the light receiving device of Example 2, a polarization orientation of a wire grid polarizer included therein, a polarized state of light having passed through the quarter wavelength layer, and a state of the light having passed through the wire grid polarizer; and FIGS. 16C and 16D are diagrams schematically illustrating a fast axis orientation of a quarter wavelength layer included in a sixth photoelectric conversion element in the light receiving device of Example 2, a polarization orientation of a wire grid polarizer included therein, a polarized state of light having passed through the quarter wavelength layer, and a state of the light having passed through the wire grid polarizer.

FIGS. 17A and 17B are diagrams schematically illustrating the fast axis orientation of the quarter wavelength layer included in the fifth photoelectric conversion element in the light receiving device of Example 2, the polarization orientation of the wire grid polarizer included therein, a polarized state of light having passed through the quarter wavelength layer, and a state of the light having passed through the wire grid polarizer; and FIGS. 17C and 17D are diagrams schematically illustrating the fast axis orientation of the quarter wavelength layer included in the sixth photoelectric conversion element in the light receiving device of Example 2, the polarization orientation of the wire grid polarizer included therein, a polarized state of light having passed through the quarter wavelength layer, and a state of the light having passed through the wire grid polarizer.

FIG. 18 is a diagram schematically illustrating amounts of light (light intensities) received by the photoelectric conversion sections of the 3×2 photoelectric conversion elements included in the photoelectric conversion element unit in the light receiving device of Example 2.

FIGS. 19A and 19B are diagrams each illustrating an imaging state of the light receiving device of Example 2.

FIGS. 20A and 20B are diagrams for describing a so-called degree of polarization.

FIG. 21 is a schematic partial cross-sectional view of a modification example of the photoelectric conversion element unit in the light receiving device of Example 2.

FIG. 22 is a schematic partial cross-sectional view of a portion of a photoelectric conversion element unit in a light receiving device of Example 3.

FIGS. 23A, 23B, and 23C are schematic diagrams respectively illustrating a polarized state of light passing through a first quarter wavelength layer included in the photoelectric conversion element unit in the light receiving device of Example 3, a polarized state of the light passing through a second quarter wavelength layer included therein, and a state of the light passing through the wire grid polarizer included therein.

FIGS. 24A, 24B, and 24C are schematic diagrams respectively illustrating a polarized state of light passing through the first quarter wavelength layer included in the photoelectric conversion element unit in the light receiving device of Example 3, a polarized state of the light passing through the second quarter wavelength layer included therein, and a state of the light passing through the wire grid polarizer included therein.

FIGS. 25A, 25B, and 25C are schematic diagrams respectively illustrating a polarized state of light passing through the first quarter wavelength layer included in the photoelectric conversion element unit in the light receiving device of Example 3, a polarized state of the light passing through the second quarter wavelength layer included therein, and a state of the light passing through the wire grid polarizer included therein.

FIGS. 26A, 26B, and 26C are schematic diagrams respectively illustrating a polarized state of light passing through the first quarter wavelength layer included in the photoelectric conversion element unit in the light receiving device of Example 3, a polarized state of the light passing through the second quarter wavelength layer included therein, and a state of the light passing through the wire grid polarizer included therein.

FIG. 27 is a schematic perspective view of the wire grid polarizer included in the photoelectric conversion element in the light receiving device of the present disclosure.

FIG. 28 is a schematic perspective view of a modification example of the wire grid polarizer.

FIGS. 29A and 29B are schematic partial cross-sectional views of the wire grid polarizer.

FIGS. 30A and 30B are schematic partial cross-sectional views of the wire grid polarizer.

FIGS. 31A, 31B, 31C, and 31D are schematic partial end views of an underlying insulating layer and the like for describing a method of manufacturing the wire grid polarizer in the light receiving device of the present disclosure.

FIG. 32 is a schematic perspective view of the quarter wavelength layer included in the photoelectric conversion element of the light receiving device of the present disclosure.

FIG. 33 is a diagram for describing behaviors of light in various polarized states entering the light receiving device of the present disclosure.

FIG. 34 is a conceptual diagram of a solid-state imaging device in a case where the light receiving device of the present disclosure is applied to the solid-state imaging device.

FIG. 35 is a conceptual diagram of an electronic apparatus (a camera) which is a solid-state imaging device to which the light receiving device of the present disclosure is applied.

FIG. 36 is a conceptual diagram for describing light or the like passing through the wire grid polarizer.

### MODES FOR CARRYING OUT THE INVENTION

In the following, the present disclosure will be described on the basis of Examples with reference to the drawings. However, the present disclosure is not limited to Examples, and various numerical values and materials included in Examples are presented by way of example. Note that the description will be given in the following order.
1. Overall Description of Light receiving Devices According to First to Third Aspects of Present Disclosure and Polarized State Measuring Method for Object of Present Disclosure
2. Example 1 (Light Receiving Device According to First Aspect of Present Disclosure and Polarized State Measuring Method for Object of Present Disclosure)
3. Example 2 (Light Receiving Device According to Second Aspect of Present Disclosure)
4. Example 3 (Light Receiving Device According to Third Aspect of Present Disclosure)
5. Others

### Overall Description of Light Receiving Devices According to First to Third Aspects of Present Disclosure and Polarized State Measuring Method for Object of Present Disclosure

In a light receiving device according to a first aspect of the present disclosure, or a light receiving of the first aspect of the present disclosure in a polarized state measuring method for an object of the present disclosure (hereinafter, for convenience, these light receiving devices will be collectively referred to as a “light receiving device or the like according to the first aspect of the present disclosure” in some cases), each of photoelectric conversion element units may include M kinds of wire grid polarizers and N kinds of quarter wavelength layers.

In the light receiving device or the like according to the first aspect of the present disclosure including the preferred embodiment described above, M=N=2a may be satisfied (where a is an integer greater than or equal to 2, and preferably, a=3, 4, or 5). In addition, in this case, polarization orientations of the M kinds of wire grid polarizers may be (180/2a)×m [degrees] (where m=0, 1, 2, 3 . . . , [2a−1]), and fast axis orientations of the N kinds of quarter wavelength layers may be (180/2a)×n [degrees] (where n=0, 1, 2, 3 . . . , [2a−1]).

An order of arrangement, in a first direction, of the M kinds of wire grid polarizers having different polarization orientations may substantially be any order, and an order of arrangement, in a second direction, of the N kinds of quarter wavelength layers having different fast axis orientations may substantially be any order. However, different image data are obtainable depending on the order of arrangement of the M kinds of wire grid polarizers in the first direction and the order of arrangement of the N kinds of quarter wavelength layers in the second direction, and therefore it is desirable that standard polarized state data be prepared in advance by determining a polarized state of a standard object. The respective M kinds of wire grid polarizers may be provided substantially continuously along the second direction. Further, the respective N kinds of quarter wavelength layers may be provided substantially continuously along the first direction.

According to the polarized state measuring method for an object of the present disclosure, an image of the object may be captured with the light receiving device by applying light having a predetermined polarized state and wavelength to the object. That is, an image of the object may be captured with the light receiving device by applying light having one kind of polarized state and one kind of wavelength (light of a single wavelength) to the object from a light source. It is sufficient that the predetermined polarized state and the predetermined wavelength are appropriately determined in advance in accordance with the object targeted for measurement of the polarized state.

According to the polarized state measuring method for an object of the present disclosure including the preferred embodiment described above, a surface state of the object may be evaluated by obtaining a comparison result. In this case, it is desirable that standard polarized state data be prepared in advance by determining a polarized state of a standard object, using an object having a desired surface state as the standard object. Alternatively, according to the polarized state measuring method for an object of the present disclosure including the preferred embodiment described above, a state of a film thickness of an object in a thin-film form may be evaluated by obtaining a comparison result on the object. In this case, it is desirable that standard polarized state data be prepared in advance by determining a polarized state of a standard object, using an object (a thin film) having a desired film thickness as the standard object. Alternatively, according to the polarized state measuring method for an object of the present disclosure including the preferred embodiment described above, the presence of a foreign substance in the object may be evaluated by obtaining a comparison result. In this case, it is desirable that standard polarized state data be prepared in advance by determining a polarized state of a standard object, using an object in a state without any foreign substance as the standard object.

In a light receiving device according to a second aspect of the present disclosure, α′=(β±45) degrees may be satisfied.

According to the light receiving device of the second aspect of the present disclosure including the preferred embodiment described above, each of the photoelectric conversion element units may include a total of 3×2 photoelectric conversion elements, with three photoelectric conversion elements in the first direction, and two photoelectric conversion elements in the second direction different from the first direction. A first photoelectric conversion element, a second photoelectric conversion element, and a fifth photoelectric conversion element may be disposed in no particular order in a first row along the first direction, and a third photoelectric conversion element, a fourth photoelectric conversion element, and a sixth photoelectric conversion element may be disposed in no particular order in a second row along the first direction.

Where the first photoelectric conversion element, the second photoelectric conversion element, the third photoelectric conversion element, and the fourth photoelectric conversion element are each referred to as a “photoelectric conversion element of a first type” for convenience, and the fifth photoelectric conversion element and the sixth photoelectric conversion element are each referred to as a “photoelectric conversion element of a second type” for convenience, two photoelectric conversion elements of the first type and one photoelectric conversion element of the second type may be disposed in no particular order in the first row along the first direction, and two photoelectric conversion elements of the first type and one photoelectric conversion element of the second type may be disposed in no particular order in the second row along the first direction, as described above. However, this is non-limiting, and also possible are an embodiment in which any one photoelectric conversion element of the first type among the four photoelectric conversion elements of the first type and two photoelectric conversion elements of the second type are disposed in no particular order in the first row along the first direction and the remaining three photoelectric conversion elements of the first type are disposed in no particular order in the second row along the first direction, and an embodiment in which any three photoelectric conversion elements of the first type among the four photoelectric conversion elements of the first type are disposed in no particular order in the first row along the first direction and the remaining one photoelectric conversion element of the first type and two photoelectric conversion elements of the second type are disposed in no particular order in the second row along the first direction.

In the light receiving device of the second aspect of the present disclosure including the preferred embodiment described above, at least light including a linearly polarized light component and light including a circularly polarized light component may enter the photoelectric conversion element unit in a mixed state.

In addition, in such an embodiment, the light receiving device may have a configuration in which:
the wire grid polarizer included in the first photoelectric conversion element passes light including a component having a polarization orientation of α degrees, of the light including the linearly polarized light component, and light including a component having the polarization orientation of α degrees, of the light including the circularly polarized light component,
the wire grid polarizer included in the second photoelectric conversion element passes light including a component having a polarization orientation of (α+45) degrees, of the light including the linearly polarized light component, and light including a component having the polarization orientation of (α+45) degrees, of the light including the circularly polarized light component,
the wire grid polarizer included in the third photoelectric conversion element passes light including a component having a polarization orientation of (α+90) degrees, of the light including the linearly polarized light component, and light including a component having the polarization orientation of (α+90) degrees, of the light including the circularly polarized light component, and
the wire grid polarizer included in the fourth photoelectric conversion element passes light including a component having a polarization orientation of (α+135) degrees, of the light including the linearly polarized light component, and light including a component having the polarization orientation of (α+135) degrees, of the light including the circularly polarized light component.

Moreover, in such a configuration, an embodiment is possible in which:
the light receiving device further includes a data processor,
where an amount of light (light intensity) obtainable by the photoelectric conversion section included in the first photoelectric conversion element is denoted by AL₁, an amount of light (light intensity) obtainable by the photoelectric conversion section included in the second photoelectric conversion element is denoted by AL₂, an amount of light (light intensity) obtainable by the photoelectric conversion section included in the third photoelectric conversion element is denoted by AL₃, an amount of light (light intensity) obtainable by the photoelectric conversion section included in the fourth photoelectric conversion element is denoted by AL₄, an amount of light (light intensity) obtainable by the photoelectric conversion section included in the fifth photoelectric conversion element is denoted by AL₅, and an amount of light (light intensity) obtainable by the photoelectric conversion section included in the sixth photoelectric conversion element is denoted by AL₆, the data processor
   determines ΔAL′=AL₅−AL₆ in a case where AL₅≥AL₆, and
   determines ΔAL′=AL₆−AL₅ in a case where AL₅<AL₆, and
the data processor further determines α degree of polarization from a difference ΔAL between a maximum value and a minimum value of a fitting curve obtainable on the basis of the amounts of light (light intensities) AL₁, AL₂, AL₃, and AL₄, and from ΔAL′. Moreover, in this case, the degree of polarization may be determined by:

degree of polarization=ΔAL/(ΔAL+ΔAL′),

and moreover, the data processor may display, of obtained image data, a region where the degree of polarization is high and a region where the degree of polarization is low in different colors. Here, ΔAL represents the amount of light (light intensity) of the polarized light component or the amount of light (light intensity) of specularly reflected light, and is a kind of fluctuation component, whereas ΔAL′ represents the amount of light (light intensity) of a non-polarized light component or the amount of light (light intensity) of diffusely reflected light, and is a kind of fixed component. The degree of polarization represents a component ratio in reflected light, and is an indicator of the state of a reflection surface. It is to be noted that the photoelectric conversion element unit may include not only the light including the linearly polarized light component and the light including the circularly polarized light component but also light of a non-polarized light component; however, it is possible to substantially eliminate an influence of the light of the non-polarized light component by determining ΔAL′.

According to the light receiving device of a third aspect of the present disclosure, α=β may be satisfied.

It is to be noted that the wording “a polarization orientation targeted for transmission by the wire grid polarizer is α degrees” includes a meaning that the polarization orientation targeted for transmission by the wire grid polarizer does not have to be exactly α degrees, and the wire grid polarizer thus transmits light with some range of angle (for example, α±5 degrees) of the polarization orientation.

According to the light receiving device of the first aspect of the present disclosure including the various preferred embodiments and configurations described above,
(1) all the photoelectric conversion element units may be constituted by the photoelectric conversion element units of the light receiving device of the first aspect of the present disclosure.

Further, according to the light receiving device of the second aspect of the present disclosure including the various preferred embodiments and configurations described above, the following embodiments are possible:
(2-1) an embodiment in which all the photoelectric conversion element units are constituted by the photoelectric conversion element units (which will be referred to as “photoelectric conversion element units-2A” for convenience) of the light receiving device of the second aspect of the present disclosure;
(2-2) an embodiment in which a partial region of the light receiving device (for example, a middle-part region of the light receiving device) is occupied by the photoelectric conversion element units-2A, and another region of the light receiving device (for example, a region surrounding the middle-part region of the light receiving device) is occupied by photoelectric conversion element units (which will be referred to as “photoelectric conversion element units-2B” for convenience) including the first photoelectric conversion element, the second photoelectric conversion element, the third photoelectric conversion element, and the fourth photoelectric conversion element, i.e., the photoelectric conversion elements excluding the fifth photoelectric conversion element and the sixth photoelectric conversion element;
(2-3) an embodiment in which the light receiving device is occupied by the photoelectric conversion element units-2B, and the photoelectric conversion element units-2A are disposed in a partial region (a desired region) of the light receiving device. That is, an embodiment in which although the light receiving device is occupied by the photoelectric conversion element units-2B, some portion of the light receiving device is without the photoelectric conversion element units-2B, and such a portion without the photoelectric conversion element units-2B is occupied by the photoelectric conversion element units-2A;
(2-4) an embodiment in which the photoelectric conversion element units-2A and the photoelectric conversion element units-2B are disposed side by side;
(2-5) an embodiment in which the photoelectric conversion element units-2A and the photoelectric conversion element units-2B are disposed at a predetermined ratio;
(2-6) an embodiment in which a partial region of the light receiving device (for example, a middle-part region of the light receiving device) is occupied by the photoelectric conversion element units-2A, and another region of the light receiving device (for example, a region surrounding the middle-part region of the light receiving device) is occupied by photoelectric conversion element units (which will be referred to as “photoelectric conversion element units-2C” for convenience) that each include a total of six photoelectric conversion elements including the first photoelectric conversion element, the second photoelectric conversion element, the third photoelectric conversion element, and the fourth photoelectric conversion element, and also the fifth photoelectric conversion element and the sixth photoelectric conversion element, the fifth and sixth photoelectric conversion elements each being provided with no quarter wavelength layer and no wire grid polarizer;
(2-7) an embodiment in which the light receiving device is occupied by the photoelectric conversion element units-2C, and the photoelectric conversion element units-2A are disposed in a partial region (a desired region) of the light receiving device. That is, an embodiment in which although the light receiving device is occupied by the photoelectric conversion element units-2C, some portion of the light receiving device is without the photoelectric conversion element units-2C, and such a portion without the photoelectric conversion element units-2C is occupied by the photoelectric conversion element units-2A;
(2-8) an embodiment in which the photoelectric conversion element units-2A and the photoelectric conversion element units-2C are disposed side by side;
(2-9) an embodiment in which the photoelectric conversion element units-2A and the photoelectric conversion element units-2C are disposed at a predetermined ratio; and
(2-10) an embodiment in which any of (2-2) to (2-5) described above and any of (2-6) to (2-9) described above are combined with each other on an as-needed basis.

Moreover, according to the light receiving device of the third aspect of the present disclosure including the various preferred embodiments and configurations described above, the following embodiments are possible:
(3-1) an embodiment in which all the photoelectric conversion element units are constituted by the photoelectric conversion element units (which will be referred to as “photoelectric conversion element units-3A” for convenience) of the light receiving device according to the third aspect of the present disclosure;
(3-2) an embodiment in which a partial region of the light receiving device (for example, a middle-part region of the light receiving device) is occupied by the photoelectric conversion element units-3A, and another region of the light receiving device (for example, a region surrounding the middle-part region of the light receiving device) is occupied by photoelectric conversion element units (which will be referred to as “photoelectric conversion element units-3B” for convenience) including the first photoelectric conversion element, the second photoelectric conversion element, the third photoelectric conversion element, and the fourth photoelectric conversion element, from each of which the first quarter wavelength layer and the second quarter wavelength layer are excluded;
(3-3) an embodiment in which the light receiving device is occupied by the photoelectric conversion element units-3B, and the photoelectric conversion element units-3A are disposed in a partial region (a desired region) of the light receiving device. That is, an embodiment in which although the light receiving device is occupied by the photoelectric conversion element units-3B, some portion of the light receiving device is without the photoelectric conversion element units-3B, and such a portion without the photoelectric conversion element units-3B is occupied by the photoelectric conversion element units-3A;
(3-4) an embodiment in which the photoelectric conversion element units-3A and the photoelectric conversion element units-3B are disposed side by side;
(3-5) an embodiment in which the photoelectric conversion element units-3A and the photoelectric conversion element units-3B are disposed at a predetermined ratio;
(3-6) an embodiment in which a partial region of the light receiving device (for example, a middle-part region of the light receiving device) is occupied by the photoelectric conversion element units-3A, and another region of the light receiving device (for example, a region surrounding the middle-part region of the light receiving device) is occupied by photoelectric conversion element units (which will be referred to as “photoelectric conversion element units-3C” for convenience) including the first photoelectric conversion element, the second photoelectric conversion element, the third photoelectric conversion element, and the fourth photoelectric conversion element, from each of which the first quarter wavelength layer, the second quarter wavelength layer, and the wire grid polarizer are excluded;
(3-7) an embodiment in which the light receiving device is occupied by the photoelectric conversion element units-3C, and the photoelectric conversion element units-3A are disposed in a partial region (a desired region) of the light receiving device. That is, an embodiment in which although the light receiving device is occupied by the photoelectric conversion element units-3C, some portion of the light receiving device is without the photoelectric conversion element units-3C, and such a portion without the photoelectric conversion element units-3C is occupied by the photoelectric conversion element units-3A;
(3-8) an embodiment in which the photoelectric conversion element units-3A and the photoelectric conversion element units-3C are disposed side by side;
(3-9) an embodiment in which the photoelectric conversion element units-3A and the photoelectric conversion element units-3C are disposed at a predetermined ratio; and
(3-10) an embodiment in which any of (3-2) to (3-5) described above and any of (3-6) to (3-9) described above are combined with each other on an as-needed basis.

The photoelectric conversion element included in the light receiving device according to any of the first to third aspects of the present disclosure including the various preferred embodiments and configurations described above, or the photoelectric conversion element included in the light receiving device according to the first aspect of the present disclosure to be used in the polarized state measuring method for an object of the present disclosure including the various preferred embodiments and configurations described above will be collectively referred to as a “photoelectric conversion element or the like of the present disclosure” in some cases, for convenience. Further, the light receiving device according to any of the first to third aspects of the present disclosure including the various preferred embodiments and configurations described above will be collectively referred to as a “light receiving device or the like of the present disclosure” in some cases, for convenience.

In the light receiving device or the like of the present disclosure, while the plurality of photoelectric conversion elements is arranged in a two-dimensional matrix, the first direction and the second direction are preferably orthogonal to each other. For example, the first direction is a so-called row direction or a so-called column direction, and the second direction is the column direction or the row direction.

As described above, the photoelectric conversion element unit may include an existing photoelectric conversion element that is provided with neither the quarter wavelength layer nor the wire grid polarizer.

The photoelectric conversion element in the light receiving device according to either of the second aspect and the third aspect of the present disclosure may include a filter layer on an as-needed basis.

That is, the light receiving device according to either of the second aspect and the third aspect of the present disclosure may include a plurality of photoelectric conversion element unit groups that is two-dimensionally arranged, and may have a configuration in which
one photoelectric conversion element unit group includes four photoelectric conversion element units disposed 2×2,
a first photoelectric conversion element unit includes a first filter layer that passes light in a first wavelength range,
a second photoelectric conversion element unit includes a second filter layer that passes light in a second wavelength range,
a third photoelectric conversion element unit includes a third filter layer that passes light in a third wavelength range, and
a fourth photoelectric conversion element unit includes a fourth filter layer that passes light in a fourth wavelength range.

As has been described, the photoelectric conversion section included in the first photoelectric conversion element unit receives light in the first wavelength range, the photoelectric conversion section included in the second photoelectric conversion element unit receives light in the second wavelength range, the photoelectric conversion section included in the third photoelectric conversion element unit receives light in the third wavelength range, and the photoelectric conversion section included in the fourth photoelectric conversion element unit receives light in the fourth wavelength range.

Here, the light in the first wavelength range may be red light, the light in the second wavelength range and the light in the third wavelength range may be green light, and the light in the fourth wavelength range may be blue light. Alternatively, the light in the first wavelength range may be red light, the light in the second wavelength range may be green light, the light in the third wavelength range may be blue light, and the light in the fourth wavelength range may be infrared light. In this case, the fourth photoelectric conversion element unit may have a configuration including a fourth filter layer that passes none of the light in the first wavelength range, the light in the second wavelength range, and the light in the third wavelength range.

Examples of the filter layer may include not only a filter layer that transmits the light in the first wavelength range such as red light, the light in the second wavelength range or the third wavelength range such as green light, and the light in the fourth wavelength range such as blue light, but also a filter layer that transmits a specific wavelength such as cyan, magenta, yellow, or the like and a filter layer that passes none of the light in the first wavelength range, the light in the second wavelength range, and the light in the third wavelength range. In addition, in a case of a purpose other than the purposes of color separation and spectral diffraction, or in a case of a photoelectric conversion element that itself has sensitivity to a specific wavelength, the filter layer may be unnecessary. In a case where a photoelectric conversion element including the filter layer and a photoelectric conversion element including no filter layer coexist, a transparent resin layer may be formed in place of the filter layer on the photoelectric conversion element including no filter layer, in order to secure flatness with the photoelectric conversion element including the filter layer. The filter layer (color filter layer) may be configured not only by an organic material-based color filter layer including an organic compound such as a pigment or a dye, but also by a photonic crystal, a wavelength selection element to which plasmon is applied (a color filter layer having a conductor grid structure including a conductor thin film provided with a grid-shaped hole structure, see Japanese Unexamined Patent Application Publication No. 2008-177191, for example), or a thin film including an inorganic material such as amorphous silicon.

In the case of a purpose other than the purposes of color separation and spectral diffraction, or in the case of a photoelectric conversion element that itself has sensitivity to a specific wavelength, the filter layer may be unnecessary. As described above, the photoelectric conversion element may include a combination of a red light photoelectric conversion element having sensitivity to red light, a green light photoelectric conversion element having sensitivity to green light, and a blue light photoelectric conversion element having sensitivity to blue light, or a combination of these photoelectric conversion elements and an infrared photoelectric conversion element having sensitivity to infrared light. The light receiving device or the like of the present disclosure may be a light receiving device (a solid-state imaging device) that obtains a monochromatic image, or a light receiving device (a solid-state imaging device) that obtains a combination of a monochromatic image and an image based on infrared light.

In addition, the light receiving device according to either of the second aspect and the third aspect of the present disclosure may have a configuration in which
a first quarter wavelength layer included in the first photoelectric conversion element unit gives a phase difference to the light in the first wavelength range,
a second quarter wavelength layer included in the second photoelectric conversion element unit gives a phase difference to the light in the second wavelength range,
a third quarter wavelength layer included in the third photoelectric conversion element unit gives a phase difference to the light in the third wavelength range, and
a fourth quarter wavelength layer included in the fourth photoelectric conversion element unit gives a phase difference to the light in the fourth wavelength range.

The light receiving device according to either of the second aspect and the third aspect of the present disclosure may have a configuration in which one photoelectric conversion element unit group (one pixel) including a plurality of photoelectric conversion element units has a Bayer arrangement. However, the arrangement of the photoelectric conversion element unit group is not limited to the Bayer arrangement, and other examples thereof may include an interline arrangement, a G-stripe RB checkered arrangement, a G-stripe RB complete checkered arrangement, a checkered complementary color arrangement, a stripe arrangement, a diagonal stripe arrangement, a primary color difference arrangement, a field color difference sequential arrangement, a frame color difference sequential arrangement, a MOS type arrangement, an improved MOS type arrangement, a frame interleave arrangement, and a field interleave arrangement.

Alternatively, in the light receiving device or the like of the present disclosure, one photoelectric conversion element unit (one pixel) may include a plurality of photoelectric conversion elements (sub-pixels). In addition, for example, each of the sub-pixels includes one photoelectric conversion element. A relationship between the pixel and the sub-pixel will be described later. The photoelectric conversion element itself or the photoelectric conversion section itself may each have a well-known configuration and structure.

In addition, the light receiving device according to either of the second aspect and the third aspect of the present disclosure may have a configuration in which the first quarter wavelength layer, the second quarter wavelength layer, the third quarter wavelength layer, and the fourth quarter wavelength layer are disposed in different layers. It is to be noted that the light receiving device or the like of the present disclosure of such an embodiment will be referred to as a “light receiving device of an A configuration of the present disclosure” for convenience. In addition, the light receiving device of the A configuration of the present disclosure may have a configuration in which
the quarter wavelength layer includes a first dielectric layer including a material having a refractive index n₁ and a second dielectric layer including a material having a refractive index n₂ (where n₁>n₂) that are alternately disposed side by side,
thicknesses (t₁₁, t₁₂) of the first dielectric layer and the second dielectric layer included in the first quarter wavelength layer, thicknesses (t₂₁, t₂₂) of the first dielectric layer and the second dielectric layer included in the second quarter wavelength layer, thicknesses (t₃₁, t₃₂) of the first dielectric layer and the second dielectric layer included in the third quarter wavelength layer, and thicknesses (t₄₁, t₄₂) of the first dielectric layer and the second dielectric layer included in the fourth quarter wavelength layer are the same, that is, t₁₁=t₂₁=t₃₁=t₄₁ and t₁₂=t₂₂=t₃₂=t₄₂, and the first quarter wavelength layer, the second quarter wavelength layer, the third quarter wavelength layer, and the fourth quarter wavelength layer have different layer thicknesses.

Alternatively, the light receiving device according to either of the second aspect and the third aspect of the present disclosure may have a configuration in which the first quarter wavelength layer, the second quarter wavelength layer and the third quarter wavelength layer, and the fourth quarter wavelength layer are disposed in the same layer. It is to be noted that the light receiving device or the like of the present disclosure of such an embodiment will be referred to as a “light receiving device of a B configuration of the present disclosure” for convenience. In addition, the light receiving device of the B configuration of the present disclosure may further have a configuration in which
the quarter wavelength layer includes a first dielectric layer including a material having a refractive index n₁ and a second dielectric layer including a material having a refractive index n₂ (where n₁>n₂) that are alternately disposed side by side,
thicknesses (t₁₁, t₁₂) of the first dielectric layer and the second dielectric layer included in the first quarter wavelength layer, thicknesses (t₂₁, t₂₂) of the first dielectric layer and the second dielectric layer included in the second quarter wavelength layer, thicknesses (t₃₁, t₃₂) of the first dielectric layer and the second dielectric layer included in the third quarter wavelength layer, and thicknesses (t₄₁, t₄₂) of the first dielectric layer and the second dielectric layer included in the fourth quarter wavelength layer are different, that is, t₁₁, t₂₁, t33, and t3 are not the same in value, and t₁₂, t₂₂, t₃₂, and t₄₂ are not the same in value, and
the first quarter wavelength layer, the second quarter wavelength layer, the third quarter wavelength layer, and the fourth quarter wavelength layer have the same layer thickness.

In the light receiving device or the like of the present disclosure, as described above, the quarter wavelength layer may include the first dielectric layer including the material having the refractive index n₁ and the second dielectric layer including the material having the refractive index n₂ that are alternately disposed side by side. In addition, where a normal line (light entrance direction) of the entire photoelectric conversion element is in a Z direction, the first dielectric layer and the second dielectric layer are included in a YZ plane. Further, the first dielectric layer and the second dielectric layer are alternately disposed side by side along an X direction, the thicknesses of the first dielectric layer and the second dielectric layer are thicknesses along the X direction, and the layer thickness of the quarter wavelength layer is a thickness along the Z direction. It is to be noted that the X direction is the fast axis, and a Y direction is a slow axis.

When the thickness of the first dielectric layer is denoted by t₁ and the thickness of the second dielectric layer is denoted by t₂, in a case where the quarter wavelength layer has a structure in which a value of (t₁+t₂) is smaller than a wavelength of light, the quarter wavelength layer has effective refractive indexes n_{TE} and n_{TM} that are different between the direction (the X direction) in which the first dielectric layer and the second dielectric layer are disposed side by side and a direction (the Y direction) orthogonal to the X direction and the Z direction, and thus behaves as if the quarter wavelength layer includes a birefringent material. The difference between these effective refractive indexes n_{TE} and n_{TM} generates a difference between propagation speeds of pieces of light in respective polarization directions, thus causing a phase difference between the pieces of light passing through the quarter wavelength layer. That is, a phase difference is given to the pieces of light passing through the quarter wavelength layer. As a result, a function as a wavelength plate is achieved. Where “f” is a filling factor, f, n_{TE}, and n_{TM} are expressed as follows.

f=t₁/(t₁+t₂)

n_{TE}={f×n₁2+(1−f)×n₂2}½

n_{TM}={f/n₁2+(1−f)/n₂2}½

Where the layer thickness (i.e., a height and a thickness in the Z direction) of the quarter wavelength layer is denoted by H and the wavelength of light passing through the quarter wavelength layer is denoted by λ, that is, the wavelength of light that passes through the quarter wavelength layer and is given a phase difference is denoted by λ (also any of λ₁, λ₂₋₃, and λ₄ to be described later), the phase difference δ is expressed as follows.

(λ/4)=δ=(n_{TE}−n_{TM})×H

Accordingly, in a case where H is fixed, a desired value of λ is obtainable by varying the value of f, that is, the values of t₁ and t₂. Further, in a case where the values of t₁ and t₂ are fixed, a desired value of λ is obtainable for the quarter wavelength layer by varying the value of H.

The layer thickness of the first quarter wavelength layer is denoted by H₁, the layer thickness of the second quarter wavelength layer is denoted by H₂, the layer thickness of the third quarter wavelength layer is denoted by H₃, and the layer thickness of the fourth quarter wavelength layer is denoted by H₄. In addition, in the first quarter wavelength layer, the thickness of the first dielectric layer is denoted by t₁₁, and the thickness of the second dielectric layer is denoted by t₁₂; in the second quarter wavelength layer, the thickness of the first dielectric layer is denoted by t₂₁, and the thickness of the second dielectric layer is denoted by t₂₂; in the third quarter wavelength layer, the thickness of the first dielectric layer is denoted by t₃₁, and the thickness of the second dielectric layer is denoted by t₃₂; and in the fourth quarter wavelength layer, the thickness of the first dielectric layer is denoted by t₄₁, and the thickness of the second dielectric layer is denoted by t₄₂.

In the light receiving device of the A configuration of the present disclosure, the first quarter wavelength layer, the second quarter wavelength layer, the third quarter wavelength layer, and the fourth quarter wavelength layer are disposed in different layers. In this case, because the values (t₁₁, t₁₂), (t₂₁, t₂₂), (t₃₁, t₃₂), and (t₄₁, t₄₂) are the same, it is sufficient that the values H₁, H₂, H₃, and H₄ are varied. Depending on cases, H₁=H₂=H₃=H₄ may be satisfied. In this case, it is sufficient that the values (t₁₁, t₁₂), (t₂₁, t₂₂), (t₃₁, t₃₂), and (t₄₁, t₄₂) are varied. In the light receiving device of the B configuration of the present disclosure, the first quarter wavelength layer, the second quarter wavelength layer, the third quarter wavelength layer, and the fourth quarter wavelength layer are disposed in the same layer. In this case, H₁=H₂=H₃=H₄, and accordingly, it is sufficient that the values (t₁₁, t₁₂), (t₂₁, t₂₂), (t₃₁, t₃₂), and (t₄₁, t₄₂) are varied.

In the photoelectric conversion element or the like of the present disclosure, examples of the material included in the first dielectric layer may include SiN, and examples of the material included in the second dielectric layer may include SiO₂; however, these examples are non-limiting.

In the photoelectric conversion element or the like of the present disclosure, the wire grid polarizer may include at least a plurality of stack structures disposed side by side with a space therebetween (i.e., may have a line-and-space structure), the stack structures each including a light reflection layer and a light absorption layer (the light absorption layer being located on a light entrance side) that have a band shape. Alternatively, the wire grid polarizer may include a plurality of stack structures disposed side by side with a space therebetween, the stack structures each including a light reflection layer, an insulating film, and a light absorption layer (the light absorption layer being located on the light entrance side) that have a band shape. It is to be noted that in this case, possible configurations include a configuration in which the light reflection layer and the light absorption layer in each of the stack structures are separated from each other by the insulating film (that is, a configuration in which the insulating film is formed on an entire top surface of the light reflection layer and the light absorption layer is formed on an entire top surface of the insulating film), and a configuration in which a portion of the insulating film is cut away to allow contact between the light reflection layer and the light absorption layer at the cut-away portion of the insulating film. In addition, in these cases, the light reflection layer may include a first electrically-conductive material, and the light absorption layer may include a second electrically-conductive material. Such a configuration makes it possible for entire regions of the light absorption layer and the light reflection layer to be electrically coupled to a region having an appropriate potential in the light receiving device. As a result, it is possible to reliably avoid the occurrence of an issue that during formation of the wire grid polarizer, the wire grid polarizer becomes electrically charged to generate a kind of discharge, which results in damage to the wire grid polarizer or the photoelectric conversion section. Alternatively, the wire grid polarizer may have a configuration including the light absorption layer and the light reflection layer that are stacked from the light entrance side, with the insulating film being omitted.

For example, the wire grid polarizer is manufacturable in accordance with the steps of:
(A) providing, after forming the photoelectric conversion section, for example, a light-reflection-layer-forming layer above the photoelectric conversion section, the light-reflection-layer-forming layer including the first electrically-conductive material and electrically coupled to a substrate or the photoelectric conversion section; thereafter,
(B) providing an insulating-film-forming layer on the light-reflection-layer-forming layer, and providing a light-absorption-layer-forming layer on the insulating-film-forming layer, the light-absorption-layer-forming layer including the second electrically-conductive material and including at least a portion in contact with the light-reflection-layer-forming layer; and thereafter,
(C) patterning the light-absorption-layer-forming layer, the insulating-film-forming layer, and the light-reflection-layer-forming layer to thereby obtain the wire grid polarizer including a plurality of line parts of the light reflection layer, the insulating film, and the light absorption layer that have a band shape, the line parts being disposed side by side with a space therebetween. It is to be noted that:
in step (B), the light-absorption-layer-forming layer including the second electrically-conductive material may be provided in a state in which the light-reflection-layer-forming layer is set to a predetermined potential via the substrate or the photoelectric conversion section; and in step (C), the light-absorption-layer-forming layer, the insulating-film-forming layer, and the light-reflection-layer-forming layer may be patterned in the state in which the light-reflection-layer-forming layer is set to a predetermined potential via the substrate or the photoelectric conversion section.

Further, an underlying film may be formed below the light reflection layer. This makes it possible to improve roughness of the light-reflection-layer-forming layer and the light reflection layer. Examples of a material included in the underlying film (a barrier metal layer) may include Ti, TiN, and a layered structure of Ti/TiN.

The wire grid polarizer in the photoelectric conversion element or the like of the present disclosure may have a configuration in which a direction of extension of the band-shaped stack structure coincides with an orientation of polarized light to be extinguished, and a direction of repetition of the band-shaped stack structure coincides with an orientation of polarized light to be transmitted. That is, the light reflection layer functions as a polarizer. Of light entering the wire grid polarizer, the light reflection layer attenuates a polarized wave (one of TE wave/S wave and TM wave/P wave) including an electric field component in a direction parallel to the direction of extension of the stack structure, and transmits a polarized wave (the other of the TE wave/S wave and TM wave/P wave) including an electric field component in a direction (the direction of repetition of the band-shaped stack structure) orthogonal to the direction of extension of the stack structure. That is, the direction of extension of the stack structure corresponds to a light absorption axis of the wire grid polarizer, while the direction orthogonal to the direction of extension of the stack structure corresponds to a light transmission axis of the wire grid polarizer. The direction of extension of the stack structure having a band shape (that is, configuring the line part of the line-and-space structure) will be referred to as a “P direction” for convenience in some cases, and the direction of repetition of the band-shaped stack structure (line part) (the direction orthogonal to the direction of extension of the band-shaped stack structure) will be referred to as a “Q direction” for convenience in some cases. The Q direction corresponds to the polarization orientation.

The Q direction may be parallel to the first direction or the second direction. An angle formed between α described above and the Q direction may substantially be any angle, and examples thereof may include 0 degrees and 90 degrees. However, this is non-limiting.

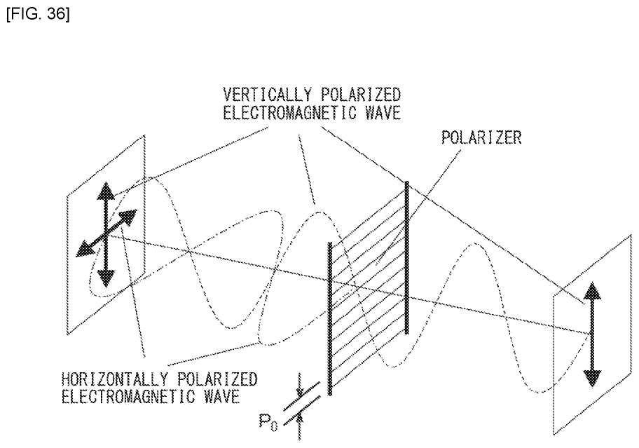

As illustrated in a conceptual diagram of FIG. 36, in a case where a formation pitch Q₀ of the wire grid polarizer is significantly smaller than a wavelength λ₀ of an entering electromagnetic wave, the electromagnetic wave oscillating in a plane parallel to a direction (the P direction) of extension of the wire grid polarizer is selectively reflected and absorbed by the wire grid polarizer. Here, assume that a distance between the line parts (a distance or length of the space part along the Q direction) is the formation pitch Q₀ of the wire grid polarizer. In this case, as illustrated in FIG. 36, although the electromagnetic wave (light) reaching the wire grid polarizer includes a vertically polarized component and a horizontally polarized component, the electromagnetic wave having passed through the wire grid polarizer becomes linearly polarized light in which the vertically polarized component is dominant. Here, if attention is focused on a visible light wavelength band, in a case where the formation pitch Q₀ of the wire grid polarizer is significantly smaller than an effective wavelength λ_{eff} of the electromagnetic wave entering the wire grid polarizer, a polarized component biased to a plane parallel to the P direction is reflected or absorbed at a front surface of the wire grid polarizer. Meanwhile, if an electromagnetic wave including a polarized component biased to a plane parallel to the Q direction enters the wire grid polarizer, an electric field propagating across the front surface of the wire grid polarizer is transmitted (outputted) from a rear surface of the wire grid polarizer while retaining the same wavelength as entering wavelength and the same polarization orientation. Here, the effective wavelength λ_{eff} is expressed as (λ₀/nₐᵥₑ), where nₐᵥₑ represents an average refractive index determined on the basis of substances present in the space part and above and below the space part. The average refractive index nₐᵥₑ is a value calculated by adding up a product of a refractive index and a volume of the substance present in the space part, a product of a refractive index and a volume of the substance present above the space part, and a product of a refractive index and a volume of the substance present below the space part, and dividing the resultant value by a sum of a volume of the space part, a volume above the space part, and a volume below the space part. In a case where the value of the wavelength λ₀ is fixed, as the value of nₐᵥₑ decreases, the value of the effective wavelength λ_{eff} increases, allowing an increase in the value of the formation pitch Q₀ accordingly. Further, as the value of nₐᵥₑ increases, a transmittance and an extinction ratio of the wire grid polarizer decrease.

In the photoelectric conversion element or the like of the present disclosure, light enters from the light absorption layer. Then, the wire grid polarizer attenuates a polarized wave (either one of TE wave/S wave and TM wave/P wave) including an electric field component parallel to the P direction, and transmits a polarized wave (the other of the TE wave/S wave and TM wave/P wave) including an electric field component parallel to the Q direction, by using four actions of light transmission, reflection, and interference, and selective light absorption of polarized waves by optical anisotropy. That is, one of the polarized waves (e.g., the TE wave) is attenuated by the selective light absorption operation on polarized waves by the optical anisotropy of the light absorption layer. The band-shaped light reflection layer functions as a polarizer, and the one of the polarized waves (e.g., the TE wave) that has passed through the light absorption layer and the insulating film is reflected by the light reflection layer. Here, if the insulating film is configured such that the phase of the one of the polarized waves (e.g., the TE wave) that has passed through the light absorption layer and has been reflected by the light reflection layer is shifted by a half wavelength, the one of the polarized waves (e.g., the TE wave) reflected by the light reflection layer is attenuated by being canceled due to interference with the one of the polarized waves (e.g., the TE wave) reflected by the light absorption layer. In this manner, it is possible to selectively attenuate one of the polarized waves (e.g., TE wave). It is to be noted that improvement in contrast is achievable even without optimization of the thickness of the insulating film, as described above. Accordingly, for practical use, it is sufficient that the thickness of the insulating film is determined on the basis of balance between a desired polarization characteristic and an actual fabrication process.

In the following description, the stack structure included in the wire grid polarizer provided above the photoelectric conversion section will be referred to as a “first stack structure” for convenience in some cases, and the stack structure surrounding the first stack structure will be referred to as a “second stack structure” for convenience in some cases. The second stack structure couples a wire grid polarizer (first stack structure) included in a certain photoelectric conversion element and a wire grid polarizer (first stack structure) included in a photoelectric conversion element adjacent to the certain photoelectric conversion element. The second stack structure may be configured by a stack structure having the same configuration as that of the stack structure included in the wire grid polarizer (i.e., the second stack structure including at least the light reflection layer and the light absorption layer, or the light reflection layer, the insulating film, and the light absorption layer, for example, and having a so-called solid film structure without being provided with a line-and-space structure). The second stack structure may be provided with a line-and-space structure like the wire grid polarizer if the second stack structure does not serve as a wire grid polarizer. That is, the second stack structure may be structured to have the wire grid formation pitch Q₀ sufficiently greater than an effective wavelength of entering electromagnetic waves. It is sufficient that a frame part to be described later also includes the second stack structure. Depending on cases, the frame part may include the first stack structure. The frame part is preferably coupled to the line part of the wire grid polarizer. The frame part may be allowed to serve as a light-blocking section.

The light reflection layer (the light-reflection-layer-forming layer) may include a metal material, an alloy material, or a semiconductor material. The light absorption layer may include a metal material, an alloy material, or a semiconductor material. Specifically, examples of an inorganic material to be included in the light reflection layer (the light-reflection-layer-forming layer) may include a metal material such as aluminum (Al), silver (Ag), gold (Au), copper (Cu), platinum (Pt), molybdenum (Mo), chrome (Cr), titanium (Ti), nickel (Ni), tungsten (W), iron (Fe), silicon (Si), germanium (Ge), or tellurium (Te), and an alloy material and a semiconductor material that include any of these metals.

The light absorption layer (or the light-absorption-layer-forming layer) may include a metal material, an alloy material, or a semiconductor material having an extinction coefficient k other than zero, that is, exhibiting a light-absorbing action, specifically, a metal material such as aluminum (Al), silver (Ag), gold (Au), copper (Cu), molybdenum (Mo), chrome (Cr), titanium (Ti), nickel (Ni), tungsten (W), iron (Fe), silicon (Si), germanium (Ge), tellurium (Te), or tin (Sn), and an alloy material and a semiconductor material that include any of these metals. In addition, a silicide-based material such as FeSi₂ (particularly β-FeSi₂), MgSi₂, NiSi₂, BaSi₂, CrSi₂, or CoSi₂ may be used. Particularly, high contrast (high extinction ratio) is achievable in a visible light region by using aluminum or an alloy thereof, or a semiconductor material including ß-FeSi₂, germanium, or tellurium as the material to be included in the light absorption layer (the light-absorption-layer-forming layer). It is to be noted that, to provide a polarization characteristic in a wavelength band other than the visible light region, such as an infrared region, it is preferable to use silver (Ag), copper (Cu), gold (Au), or the like as the material to be included in the light absorption layer (the light-absorption-layer-forming layer). One reason for this is that resonance wavelengths of these metals are close to the infrared region.

The light-reflection-layer-forming layer and the light-absorption-layer-forming layer are formable in accordance with a known method, such as any of various chemical vapor deposition methods (CVD methods), a coating method, any of various physical vapor deposition methods (PVD methods) including a sputtering method and a vacuum vapor deposition method, a sol-gel method, a plating method, an MOCVD method, or an MBE method. In addition, examples of a patterning method for the light-reflection-layer-forming layer and the light-absorption-layer-forming layer may include a combination of a lithography technique and an etching technique (e.g., an anisotropic dry etching technique using carbon tetrafluoride gas, sulfur hexafluoride gas, trifluoromethane gas, xenon difluoride gas, or the like, and a physical etching technique), a so-called lift-off technique, and a so-called self-align double patterning technique using a sidewall as a mask. Examples of the lithography technique may include photolithography techniques (a lithography technique using a g-line and an i-line of a high-pressure mercury lamp, KrF excimer laser, ArF excimer laser, EUV, or the like as a light source, and a liquid immersion lithography technique, an electron beam lithography technique, and X-ray lithography thereof). Alternatively, the light reflection layer and the light absorption layer are also formable in accordance with a fine processing technique using an ultrashort pulsed laser such as a femtosecond laser, or a nanoimprint method.

Examples of materials to be included in the insulating film (or the insulating-film-forming layer), an interlayer insulating layer, an underlying insulating layer, and a planarization layer may include insulating materials that are transparent to entering light and have no light-absorbing characteristic, specifically, SiOₓ-based materials (materials each forming a silicon-based oxide film) including silicon oxide (SiO₂), NSG (nondoped silicate glass), BPSG (boron phosphorus silicate glass), PSG, BSG, PbSG, AsSG, SbSG, and SOG (spin-on glass), SiN, silicon oxynitride (SiON), SiOC, SiOF, SiCN, low dielectric constant insulating materials (e.g., fluorocarbon, cycloperfluorocarbon polymer, benzocyclobutene, cyclic fluororesin, polytetrafluoroethylene, amorphous tetrafluoroethylene, polyarylether, arylether fluoride, fluorinated polyimide, organic SOG, parylene, fullerene fluoride, and amorphous carbon), polyimide-based resins, fluorine-based resins, Silk (which is a trademark of The Dow Chemical Co. and a coating type low dielectric constant interlayer insulating film material), Flare (which is a trademark of Honeywell Electronic Materials Co. and a polyarylether (PAE) based material). These materials may be used alone or in combination on an as-needed basis. Alternatively, examples thereof may include: polymethyl methacrylate (PMMA); polyvinyl phenol (PVP); polyvinyl alcohol (PVA); polyimide; polycarbonate (PC); polyethylene terephthalate (PET); polystyrene; silanol derivatives (silane coupling agents) including N-2(aminoethyl)3-aminopropyltrimethoxysilane (AEAPTMS), 3-mercaptopropyl trimethoxy silane (MPTMS), and octadecyltrichlorosilane (OTS); novolac type phenol resin; fluorine-based resin; and organic insulating materials (organic polymers) including, for example, straight-chain hydrocarbons having a functional group that is couplable to a control electrode at one end, such as octadecanethiol or dodecyl isocyanate. Combinations of any of these materials are also usable. The insulating-film-forming layer is formable in accordance with a known method such as any of various CVD methods, a coating method, any of various PVD methods including a sputtering method and a vacuum vapor deposition method, any of various printing methods such as a screen printing method, or a sol-gel method. The insulating film serves as an underlying layer of the light absorption layer and is formed for the purpose of adjusting phases of polarized light that has been reflected by the light absorption layer and polarized light that has passed through the light absorption layer and has been reflected by the light reflection layer, improving the extinction ratio and transmittance by an interference effect, and reducing reflectance. Accordingly, it is desirable that the insulating film have a thickness that causes a phase shift of a half wavelength in one reciprocation. However, the light absorption layer has a light absorption effect and thus absorbs reflected light. Accordingly, improvement in extinction ratio is achievable even if the thickness of the insulating film is not optimized as described above. Thus, for practical use, it is sufficient that the thickness of the insulating film is determined on the basis of balance between a desired polarization characteristic and an actual fabrication process. For example, the thickness of the insulating film may range from 1×10⁻⁹ m to 1×10⁻⁷ m, and more preferably, from 1×10⁻⁸ m to 8×10⁻⁸ m. In addition, the refractive index of the insulating film is greater than 1.0, and is preferably, but not limited to, 2.5 or smaller.

In the photoelectric conversion element or the like of the present disclosure, the space part of the wire grid polarizer may be an empty space (that is, the space part may be filled with at least air). By forming the space part of the wire grid polarizer as an empty space in this manner, it is possible to reduce the value of the average reflective index nₐᵥₑ, and as a result, it is possible for the wire grid polarizer to achieve improvement in transmittance and improvement in extinction ratio. In addition, because it is possible to increase the value of the formation pitch Q₀, improvement in manufacturing yield of the wire grid polarizer is achievable. An embodiment is also possible in which a protective film is formed on the wire grid polarizer. This makes it possible to provide a photoelectric conversion element and a light receiving device that each have high reliability. By providing the protective film, it is possible to improve reliability, such as improvement in moisture resistance of the wire grid polarizer. It is sufficient that the protective film has a thickness in a range that does not affect the polarization characteristic. A reflectance for entering light varies also depending on the optical thickness of the protective film (refractive index× film thickness of protective film). Accordingly, it is sufficient that the material and the thickness of the protective film are determined in consideration of these factors. For example, the thickness may be 15 nm or smaller. Alternatively, the thickness may be smaller than or equal to ¼ of a distance between the stack structures. As a material to be included in the protective film, it is desirable to use a material having a refractive index of 2 or lower and an extinction coefficient close to zero. Examples of the material may include an insulating material such as SiO₂ including TEOS-SiO₂, SiON, SiN, SiC, SiOC, or SiCN, and a metal oxide such as aluminum oxide (AlOₓ), hafnium oxide (HfOₓ), zirconium oxide (ZrOₓ), or tantalum oxide (TaOₓ). Alternatively, perfluorodecyltrichlorosilane or octadecyltrichlorosilane may be used. Although the protective film is formable through a known process such as any of various CVD methods, a coating method, any of various PVD methods including a sputtering method and a vacuum vapor deposition method, or a sol-gel method, it is more preferable to employ a so-called atomic layer deposition method (ALD method, Atomic Layer Deposition method) or an HDP-CVD method (a high density plasma chemical vapor deposition method). It is possible to form a thin protective film on the wire grid polarizer in a conformal manner by employing the ALD method or the HDP-CVD method. The protective film may be formed on an entire surface of the wire grid polarizer; however, the protective film may be formed only on a side surface of the wire grid polarizer and not over the underlying insulating layer located between the wire grid polarizers. In addition, by forming the protective film in such a manner as to cover the side surface where the metal material or the like included in the wire grid polarizer is exposed, it is possible to block moisture and organic matters in atmosphere to thereby reliably suppress the occurrence of an issue such as corrosion or abnormal precipitation of the metal material or the like included in the wire grid polarizer. Moreover, it is possible to achieve improvement in long-term reliability of the photoelectric conversion element, which makes it possible to provide the photoelectric conversion element that includes a highly reliable wire grid polarizer as an on-chip element.

In a case of forming the protective film on the wire grid polarizer, a second protective film may further be formed between the wire grid polarizer and the protective film, and n₁′>n₂′ may be satisfied where n₁′ represents the refractive index of the material included in the protective film and n₂′ represents a refractive index of a material included in the second protective film. By satisfying n₁′>n₂′, it is possible to reduce the value of the average refractive index nₐᵥₑ with reliability. Here, it is preferable that the protective film include SiN and the second protective film include SiO₂ or SiON.

Moreover, a third protective film may be formed at least on a side surface of the line part facing the space part of the wire grid polarizer. That is, the space part is filled with air, and additionally, the third protective film is present in the space part. Here, as a material to be included in the third protective film, it is preferable to use a material having a refractive index of 2 or lower and an extinction coefficient close to zero. Examples of the material may include an insulating material such as SiO₂ including TEOS-SiO₂, SiON, SiN, SiC, SiOC, or SiCN, and a metal oxide such as aluminum oxide (AlOₓ), hafnium oxide (HfOₓ), zirconium oxide (ZrOₓ), or tantalum oxide (TaOₓ). Alternatively, perfluorodecyltrichlorosilane or octadecyltrichlorosilane may be used. Although the third protective film is formable through a known process such as any of various CVD methods, a coating method, any of various PVD methods including a sputtering method and a vacuum vapor deposition method, or a sol-gel method, it is more preferable to employ a so-called atomic layer deposition method (ALD method, Atomic Layer Deposition method) or an HDP-CVD method (high density plasma chemical vapor deposition method). Although it is possible to form a thin third protective film on the wire grid polarizer in a conformal manner by employing the ALD method, it is more preferable to employ the HDP-CVD method from the viewpoint of forming a further thinner third protective film on the side surface of the line part. Alternatively, if the space part is filled with the material included in the third protective film and the third protective film is provided with a clearance, a hole, a void, or the like, it is possible to reduce the refractive index of the entire third protective film.

If a metal material or an alloy material included in the wire grid polarizer (hereinafter referred to as a “metal material or the like” for convenience in some cases) comes into contact with outside air, corrosion resistance of the metal material or the like can deteriorate due to adhesion of moisture or organic matters from the outside air, and this can deteriorate long-term reliability of the photoelectric conversion section. If moisture adheres to the line part (the stack structure) including the metal material or the like, the insulating material, and the metal material or the like, in particular, such moisture can act as an electrolytic solution because CO₂ and O₂ are dissolved in the moisture, and this can generate a local battery between two kinds of metals. In addition, if such a phenomenon occurs, a reduction reaction such as hydrogen generation proceeds on a cathode (positive electrode) side, whereas an oxidation reaction proceeds on an anode (negative electrode) side, and this causes abnormal precipitation of the metal material or the like or a shape change of the wire grid polarizer to occur. As a result, originally expected performance of the wire grid polarizer or the photoelectric conversion section can deteriorate. For example, in a case of using aluminum (Al) as the light reflection layer, abnormal precipitation of aluminum as expressed in the following reaction expression can occur. However, it is possible to avoid the occurrence of such an issue with reliability by forming the protective film, and also by forming the third protective film.

Al→Al³⁺+3^{e-}

Al³⁺+3OH⁻→Al(OH)₃

In the light receiving device or the like of the present disclosure, a length of the light reflection layer along the P direction may be the same as a length of a photoelectric conversion region along the P direction, the photoelectric conversion region being a region where the photoelectric conversion element practically performs photoelectric conversion, may be the same as a length of the photoelectric conversion element, or may be an integral multiple of the length of the photoelectric conversion element along the P direction. However, these examples are non-limiting.

In the photoelectric conversion element or the like of the present disclosure, an on-chip microlens may be disposed on the light entrance side relative to the quarter wavelength layer. Alternatively, the on-chip microlens (OCL) may include a main on-chip microlens provided above the quarter wavelength layer or the wire grid polarizer, or may include a sub on-chip microlens (an inner lens, OPA) provided above the quarter wavelength layer or the wire grid polarizer and a main on-chip microlens provided above the sub on-chip microlens (OPA).

In addition, in such a configuration of the light receiving device according to either of the second aspect and the third aspect of the present disclosure, a wavelength selection means (specifically, a well-known filter layer, for example) may be disposed between the wire grid polarizer and the on-chip microlens. By adopting such a configuration, it is possible to optimize the wire grid polarizer independently in a wavelength band of light to be transmitted through each wire grid polarizer, and to achieve further reduction in reflectance throughout the visible light region. A planarization film may be formed between the wire grid polarizer or the quarter wavelength layer and the wavelength selection means, and an underlying insulating layer including an inorganic material such as a silicon oxide film and serving as a base of a process in wire grid polarizer manufacturing steps may be formed below the wire grid polarizer. In a case where the main on-chip microlens is provided above the sub on-chip microlens (OPA), the wavelength selection means (a well-known filter layer) may be disposed between the sub on-chip microlens and the main on-chip microlens.

For example, a plurality of layers of various wiring lines (wiring layers) including aluminum (Al), copper (Cu), or the like is formed below the wire grid polarizer in order to drive the photoelectric conversion element. In addition, the wire grid polarizer is coupled to a substrate (specifically, a semiconductor substrate) via the various wiring lines (wiring layers) and contact hole parts. This makes it possible to apply a predetermined potential to the wire grid polarizer. Specifically, the wire grid polarizer is grounded, for example. Examples of the semiconductor substrate may include a compound semiconductor substrate such as a silicon semiconductor substrate or an InGaAs substrate.

Configurations and structures of, for example, a floating diffusion layer, an amplifier transistor, a reset transistor, and a selection transistor included in a controller for controlling driving of the photoelectric conversion element may be similar to configurations and structures of a floating diffusion layer, an amplifier transistor, a reset transistor, and a selection transistor of an existing controller. Thus, the controller may have a well-known configuration and structure, and may be provided on the substrate described above.

Between the photoelectric conversion elements in the photoelectric conversion element unit, there may be provided a waveguide structure or a light condensing tube structure. This makes it possible to achieve reduction in optical crosstalk. The waveguide structure here includes a thin film that is formed in a region (for example, a cylindrical region) located between the photoelectric conversion sections in an interlayer insulating layer covering the photoelectric conversion sections and that has a refractive index of a value greater than a value of a refractive index of a material included in the interlayer insulating layer. Light entering from above the photoelectric conversion section is totally reflected by this thin film and reaches the photoelectric conversion section. That is, an orthographic projection image of the photoelectric conversion section with respect to the substrate is located inside an orthographic projection image of the thin film included in the waveguide structure with respect to the substrate, and the orthographic projection image of the photoelectric conversion section with respect to the substrate is surrounded by the orthographic projection image of the thin film included in the waveguide structure with respect to the substrate. In addition, the light condensing tube structure includes a light-blocking thin film including a metal material or an alloy material and formed in a region (for example, a cylindrical region) located between the photoelectric conversion sections in the interlayer insulating layer covering the photoelectric conversion sections. Light entering from above the photoelectric conversion section is reflected by this thin film and reaches the photoelectric conversion section. That is, the orthographic projection image of the photoelectric conversion section with respect to the substrate is located inside an orthographic projection image of the thin film included in the light condensing tube structure with respect to the substrate, and the orthographic projection image of the photoelectric conversion section with respect to the substrate is surrounded by the orthographic projection image of the thin film included in the light condensing tube structure with respect to the substrate.

In a case of applying the light receiving device or the like of the present disclosure to a solid-state imaging device, examples of the photoelectric conversion element may include a CCD element, a CMOS image sensor, a CIS (Contact Image Sensor), and a CMD (Charge Modulation Device) type signal amplification image sensor. The photoelectric conversion element is a front-illuminated type photoelectric conversion element or a back-illuminated type photoelectric conversion element. For example, a digital still camera, a video camera, a camcorder, a monitoring camera, an on-vehicle camera, a smartphone camera, a game user interface camera, and a biometric authentication camera may be configured using the solid-state imaging device. In addition, it is possible to provide a solid-state imaging device that is able to acquire polarization information simultaneously as well as performing ordinary imaging. Further, it is also possible to provide a solid-state imaging device that captures a three-dimensional image. In a case where a solid-state imaging device is configured using the light receiving device or the like of the present disclosure, it is possible for the solid-state imaging device to configure a single-plate type color solid-state imaging device.

### EXAMPLE 1

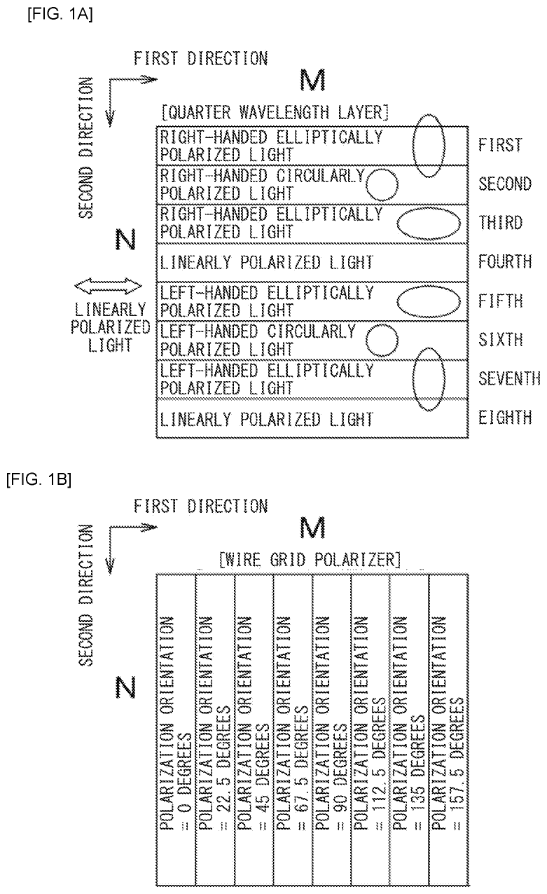

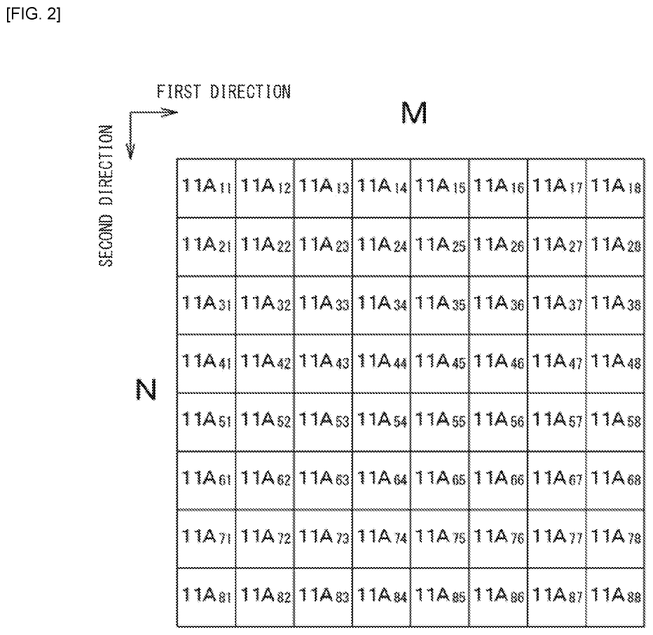

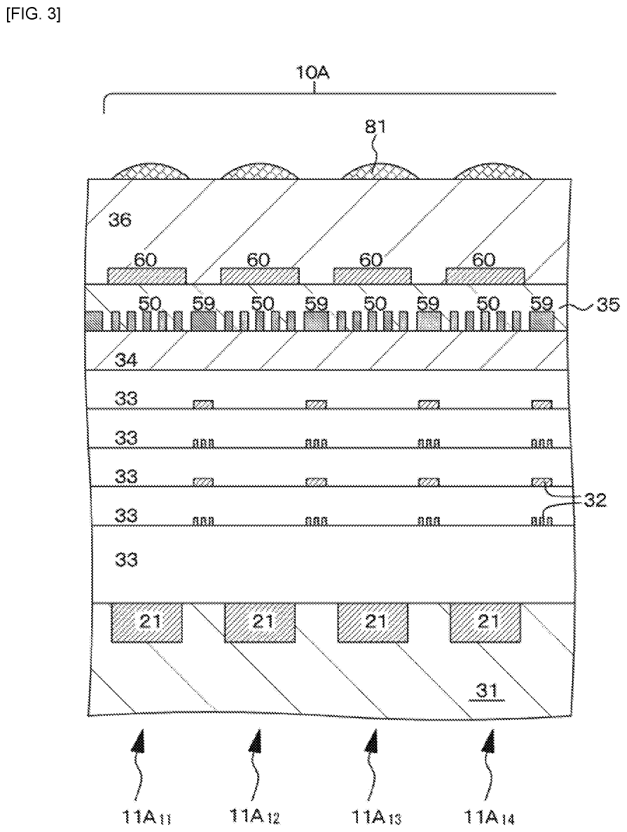

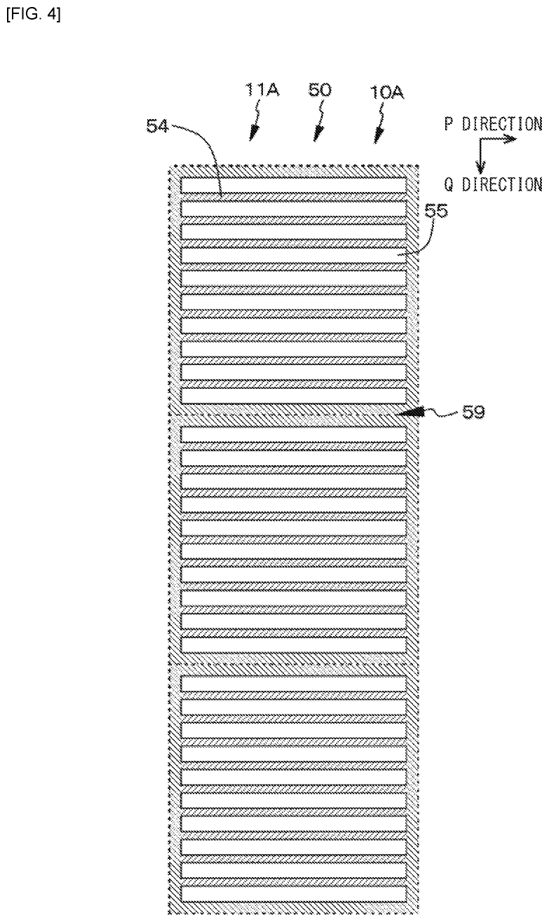

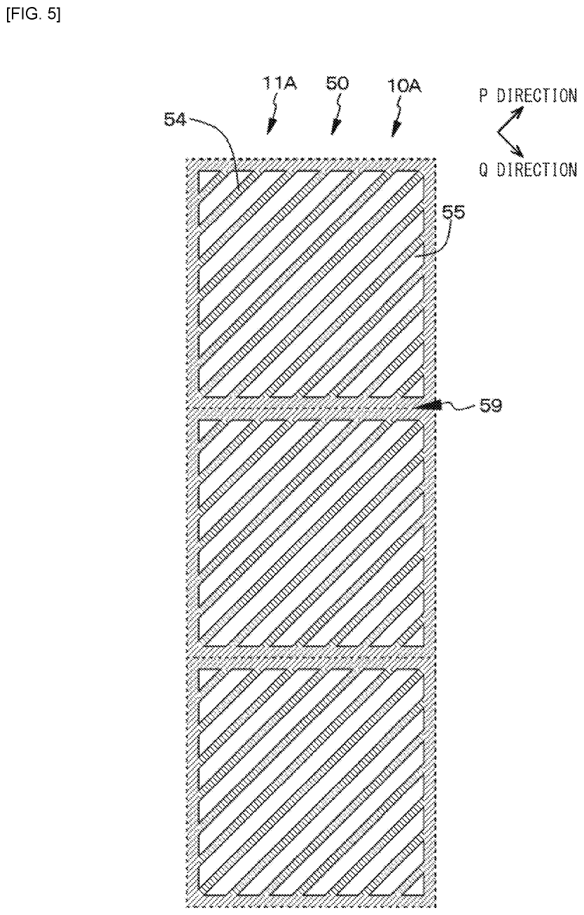

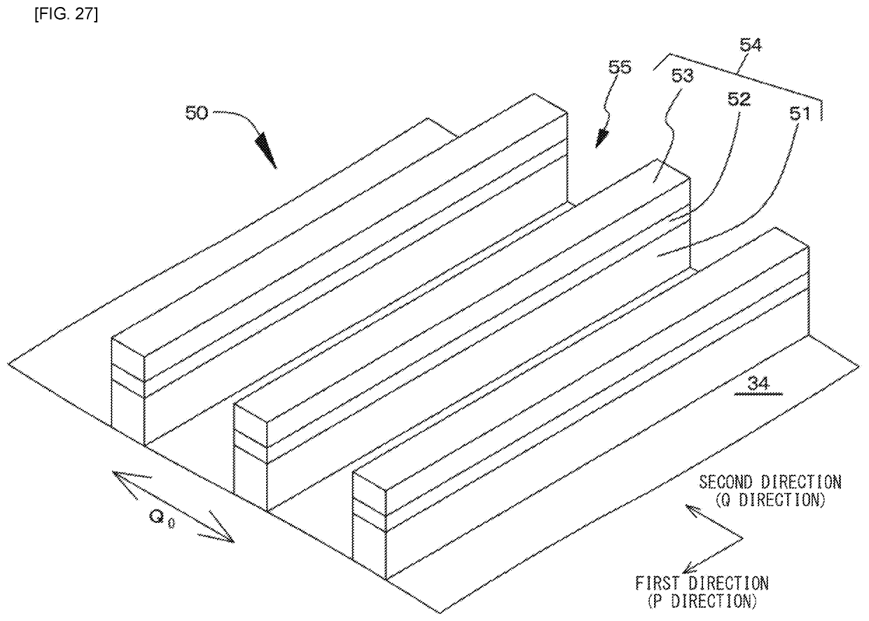

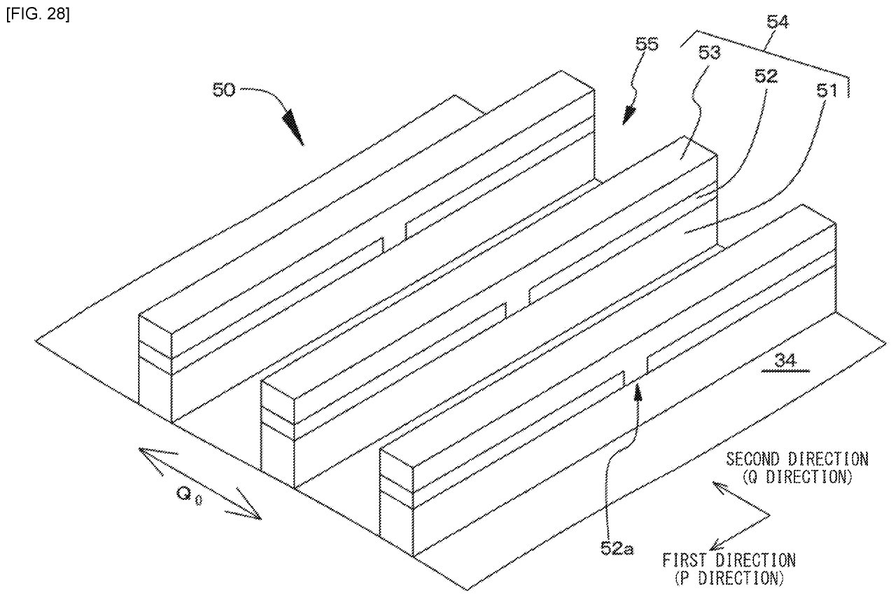

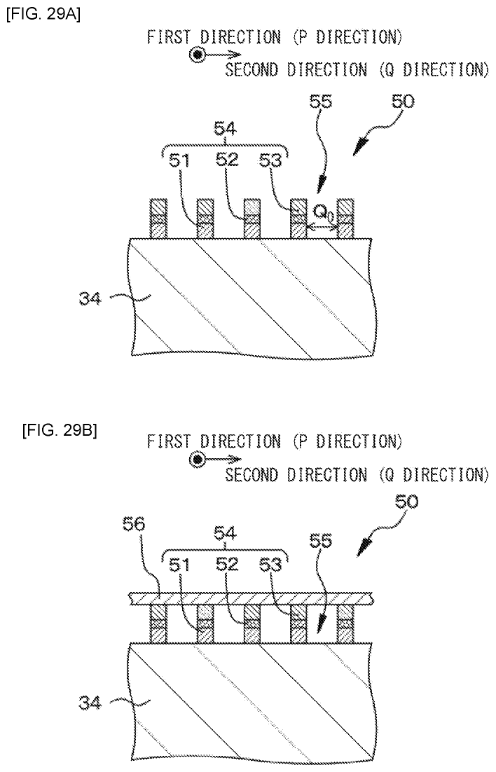

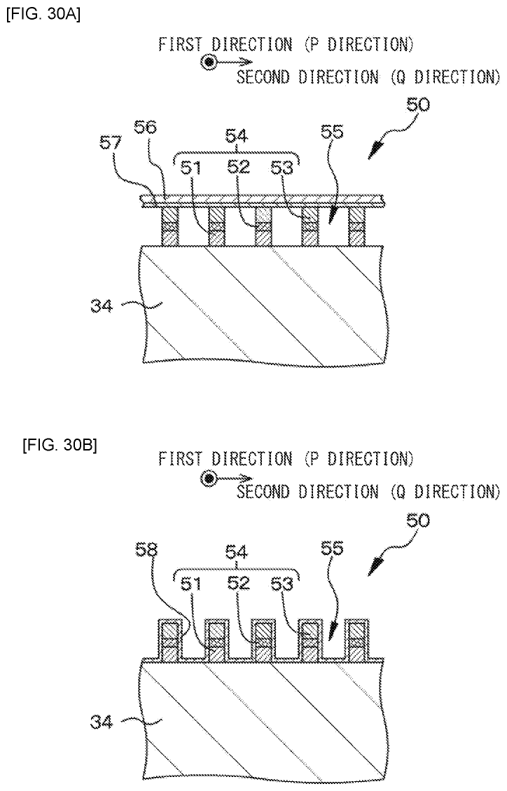

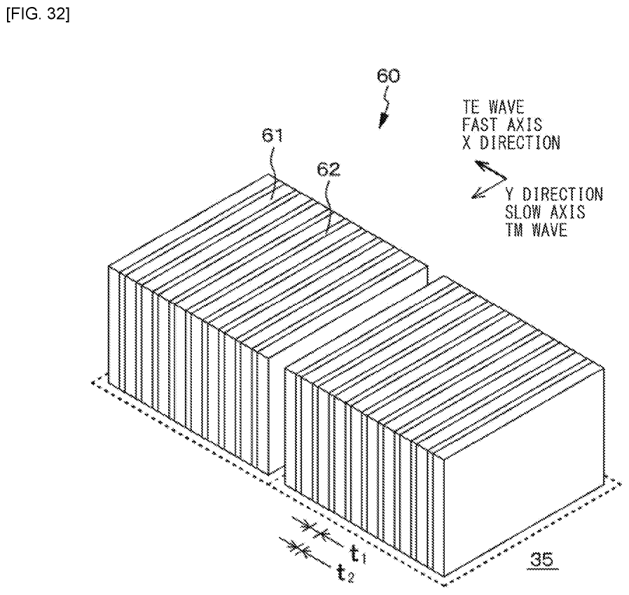

Example 1 relates to the light receiving device according to the first aspect of the present disclosure and the polarized state measuring method for an object of the present disclosure. FIG. 1A illustrates a conceptual diagram of an order of arrangement of N quarter wavelength layers included in a photoelectric conversion element unit in a light receiving device of Example 1, and FIG. 1B illustrates a conceptual diagram of an order of arrangement of M wire grid polarizers included therein. Further, FIG. 2 illustrates a conceptual diagram of an order of arrangement of 8×8 photoelectric conversion elements included in the photoelectric conversion element unit in the light receiving device of Example 1. FIG. 3 illustrates a schematic partial cross-sectional view of a portion of the photoelectric conversion element unit in the light receiving device of Example 1. FIGS. 4 and 5 each illustrate a schematic plan view of the wire grid polarizer. Moreover, FIGS. 27 and 28 each illustrate a schematic perspective view of the wire grid polarizer. FIGS. 29A, 29B, 30A, and 30B each illustrate a schematic partial cross-sectional view of the wire grid polarizer. FIG. 32 illustrates a schematic perspective view of the quarter wavelength layer.

The light receiving device of Example 1 includes a plurality of photoelectric conversion element units 10A. Each of the photoelectric conversion element units 10A includes a plurality of photoelectric conversion elements 11A (in FIG. 3, four photoelectric conversion elements 11A1, 11A2, 11A3, and 11A4 are illustrated), the photoelectric conversion elements being M×N in total number, with M photoelectric conversion elements arranged in a first direction, and N photoelectric conversion elements arranged in a second direction different from the first direction. In addition, each of the photoelectric conversion elements includes a quarter wavelength layer 60, a wire grid polarizer 50, and a photoelectric conversion section 21 that are disposed in this order from the light entrance side.

The M photoelectric conversion elements disposed side by side along the first direction include the quarter wavelength layers 60 that have the same fast axis orientation,
the N photoelectric conversion elements disposed side by side along the second direction include the quarter wavelength layers 60 that have different fast axis orientations,
the N photoelectric conversion elements disposed side by side along the second direction include the wire grid polarizers 50 that have the same polarization orientation (orientation of polarized light to be transmitted by the wire grid polarizer), and
the M photoelectric conversion elements disposed side by side along the first direction include the wire grid polarizers 50 that have different polarization orientations.

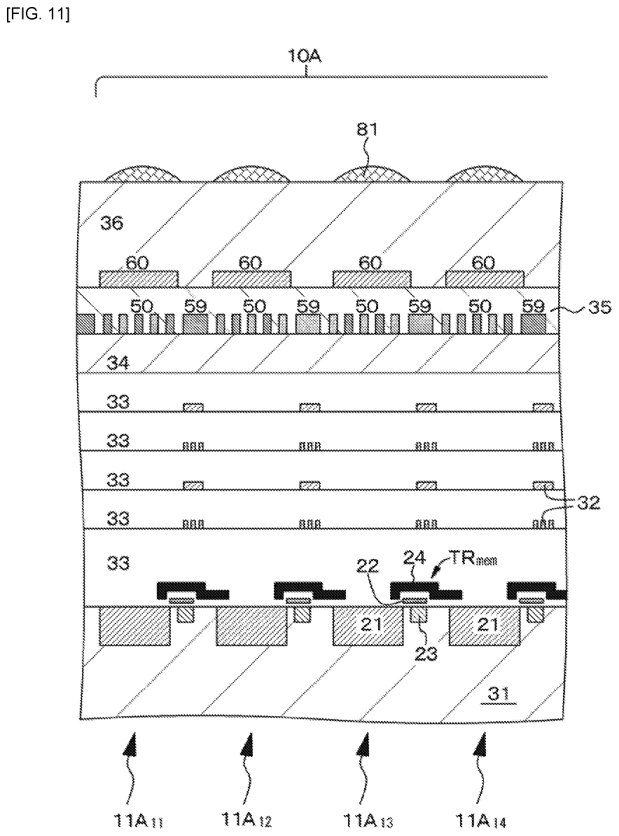

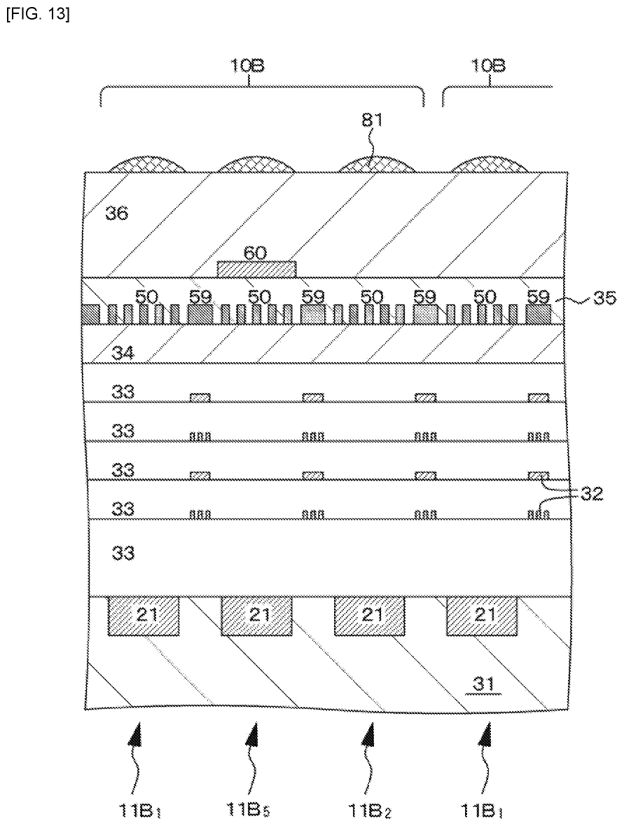

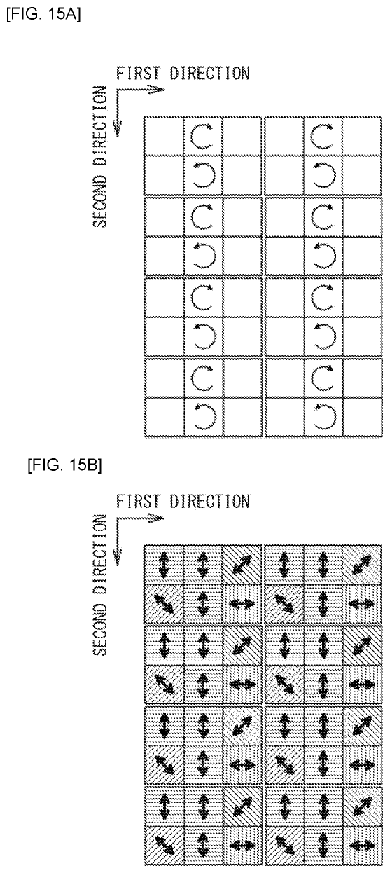

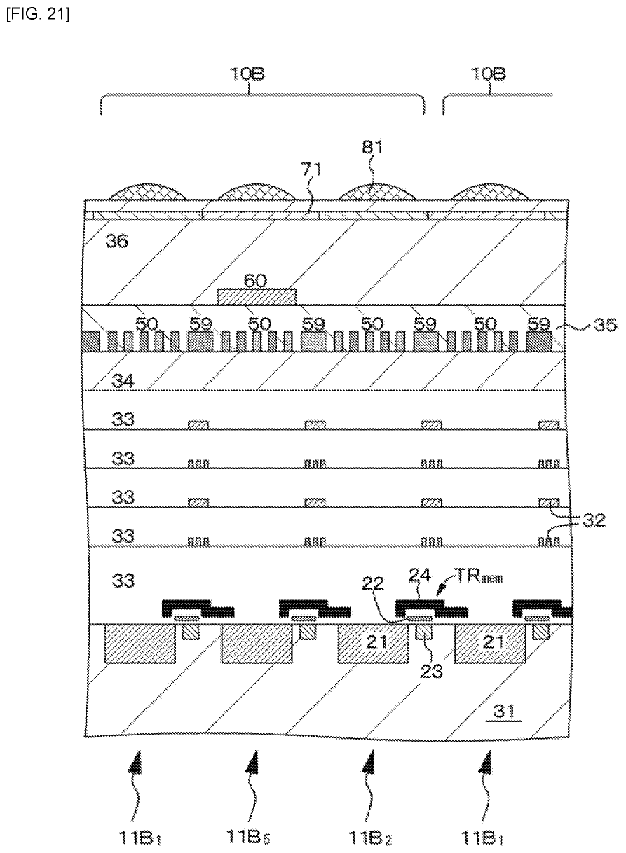

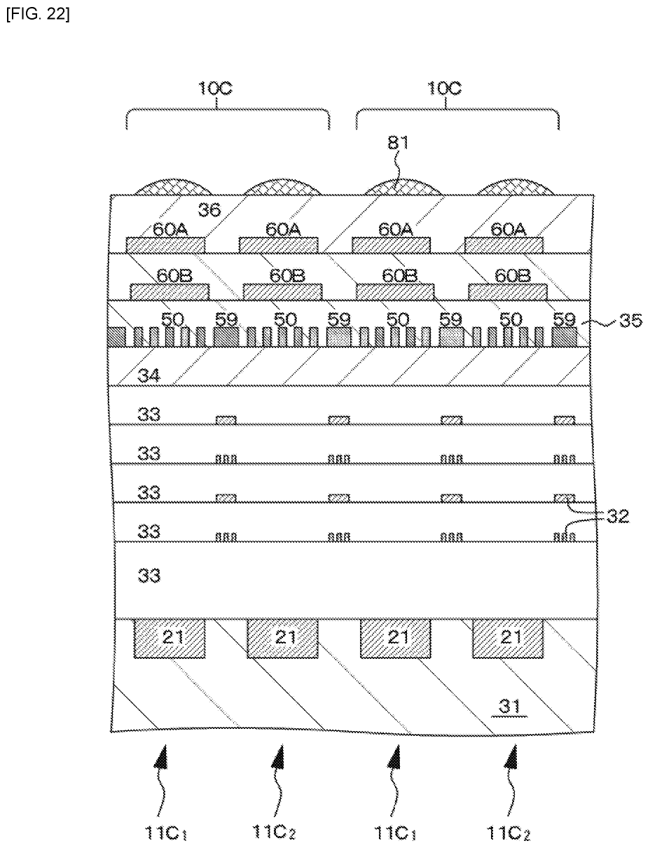

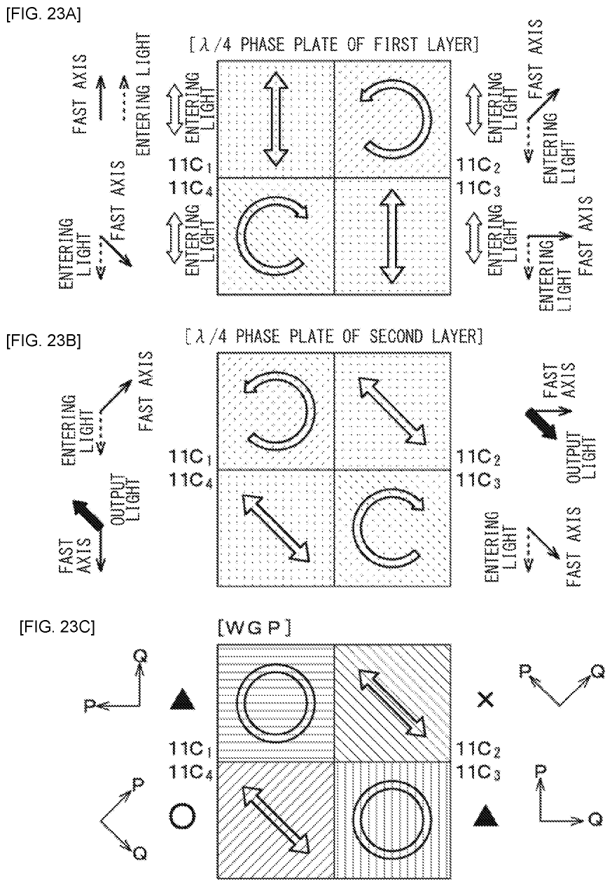

Specifically, each of the photoelectric conversion element units includes M kinds of wire grid polarizers 50 and N kinds of quarter wavelength layers 60. Here, in the light receiving device of Example 1, M=N=2a (where a is an integer greater than or equal to 2, and preferably, a=3, 4, or 5). In addition, in this case, the polarization orientations of the M kinds of wire grid polarizers 50 are (180/2a)×m [degrees] (where m=0, 1, 2, 3 . . . , [2a−1]), and the fast axis orientations of the N kinds of quarter wavelength layers 60 are (180/2a)×n [degrees] (where n=0, 1, 2, 3 . . . , [2a−1]). It is to be noted that the cross section of the wire grid polarizer 50 in each of FIGS. 3 and 11 is different from a state illustrated in FIG. 1B for simplification of illustration; the cross section of the wire grid polarizer 50 in each of FIGS. 13 and 21 is different from a state illustrated in FIG. 15B for simplification of illustration; and the cross section of the wire grid polarizer 50 in FIG. 22 is different from a state illustrated in each of FIGS. 23C, 24C, 25C, and 26C for simplification of illustration.

In the illustrated example, a=3 and M=N=8. The polarization orientations of the M kinds of wire grid polarizers 50 are set to 0 degrees, 22.5 degrees, 45.0 degrees, 67.5 degrees, 90.0 degrees, 112.5 degrees, 135.0 degrees, and 157.5 degrees. Although the P direction of the wire grid polarizer having a polarization orientation of 0 degrees is assumed to be parallel to the first direction and the Q direction is assumed to be parallel to the second direction, these are non-limiting. Further, as illustrated in FIG. 1A, the respective fast axis orientations of the quarter wavelength layers are defined so that when linearly polarized light that is polarized in the first direction enters the N kinds of quarter wavelength layers 60 from above in a direction perpendicular to the sheet plane of FIGS. 1A and 1s outputted therefrom, the light becomes as follows:
light having passed through a first quarter wavelength layer: right-handed elliptically polarized light;
light having passed through a second quarter wavelength layer: right-handed circularly polarized light;
light having passed through a third quarter wavelength layer: right-handed elliptically polarized light;
light having passed through a fourth quarter wavelength layer: linearly polarized light;
light having passed through a fifth quarter wavelength layer: left-handed elliptically polarized light;
light having passed through a sixth quarter wavelength layer: left-handed circularly polarized light;
light having passed through a seventh quarter wavelength layer: left-handed elliptically polarized light; and
light having passed through an eighth quarter wavelength layer: linearly polarized light. It is to be noted that the right-handed elliptically polarized light having passed through the first quarter wavelength layer and the right-handed elliptically polarized light having passed through the third quarter wavelength layer are different in elliptically polarized state. Further, the left-handed elliptically polarized light having passed through the fifth quarter wavelength layer and the left-handed elliptically polarized light having passed through the seventh quarter wavelength layer are different in elliptically polarized state. Although the X direction (the fast axis orientation) in the fourth quarter wavelength layer is assumed to be parallel to the first direction and the X direction in the eighth quarter wavelength layer is assumed to be parallel to the second direction, this is non-limiting. Further, the polarized state of light when outputted from an n-th photoelectric conversion element depends on the polarized state of the light when entering the n-th photoelectric conversion element.

FIG. 2 illustrates a state in which the photoelectric conversion elements 11 Amn (where m=1, 2, . . . , 8, and n=1, 2, . . . , 8) including the quarter wavelength layers 60 and the wire grid polarizers 50 illustrated in FIGS. 1A and 1B are disposed. One photoelectric conversion element unit constitutes one pixel (a pixel).

The order of arrangement, in the first direction, of the M kinds of wire grid polarizers 50 having different polarization orientations may substantially be any order, and is not limited to the state illustrated in FIG. 1B. The order of arrangement, in the second direction, of the N kinds of quarter wavelength layers 60 having different fast axis orientations may also substantially be any order, and is not limited to the state illustrated in FIG. 1A. However, different image data are obtainable depending on the order of arrangement of the M kinds of wire grid polarizers 50 in the first direction and the order of arrangement of the N kinds of quarter wavelength layers 60 in the second direction, and therefore it is necessary to prepare standard polarized state data in advance by determining a polarized state of a standard object. The respective M kinds of wire grid polarizers 50 are provided substantially continuously along the second direction, and the respective N kinds of quarter wavelength layers 60 are provided substantially continuously along the first direction.

In addition, in each of the photoelectric conversion elements 11, an on-chip microlens 81 is disposed on the light entrance side relative to the quarter wavelength layer 60. This also applies to Examples 2 and 3.

In the light receiving device of Example 1, all the photoelectric conversion element units are constituted by the plurality of photoelectric conversion element units 10A. The light receiving device of Example 1 is applicable to, for example, a light receiving device (e.g., a sensor) that is not intended for color separation or spectral diffraction, and the photoelectric conversion element itself has sensitivity to a specific wavelength (monochromatic light), which makes it unnecessary to provide a filter layer.

As illustrated in a schematic perspective diagram in FIG. 32, the quarter wavelength layer 60 includes a first dielectric layer 61 including a material having a refractive index n₁ and a thickness t₁, and a second dielectric layer 62 including a material having a refractive index n₂ (where n₁>n₂) and a thickness t₂, the first dielectric layer 61 and the second dielectric layer 62 being alternately disposed side by side. Here, the first dielectric layer 61 specifically includes SiN (n₁=2.0), and the second dielectric layer 62 specifically includes SiO₂ (n₂=1.5). This may also apply to subsequent Examples.

In Example 1, if
t₁=150 nm and
t₂=150 nm, then
f=150/(150+150)=0.5,
n_{TE}=1.77, and
n_{TM}=0.59.

If H=125 nm,
then the wavelength λ of light that passes through the quarter wavelength layer 60 and is given a phase difference is:
λ=600 nm.

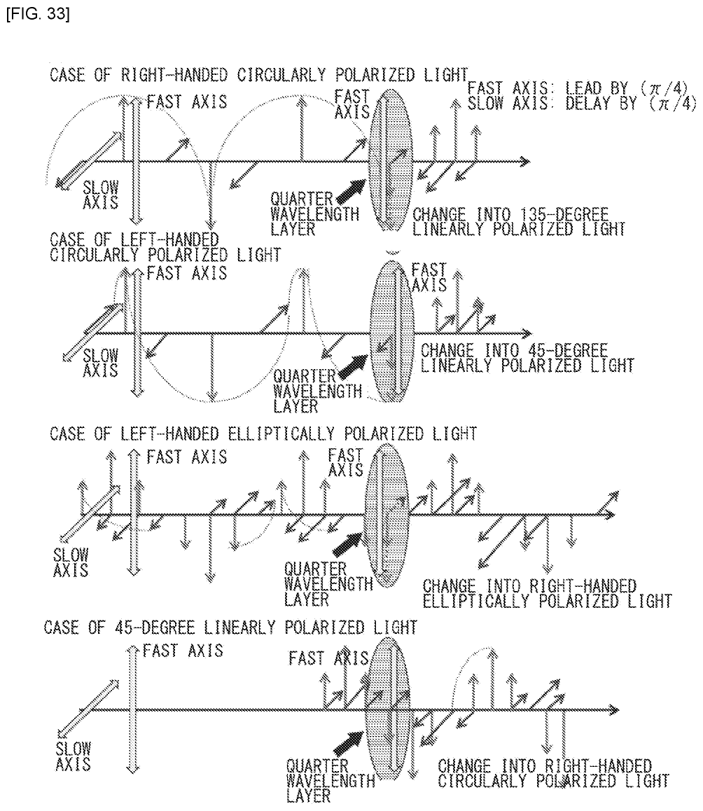

FIG. 33 illustrates behaviors of light in various polarized states entering the light receiving device of the present disclosure. Light having entered the quarter wavelength layer in a right-handed circularly polarized state leads in phase by (π/4) in a fast axis direction and delays in phase by (π/4) in a slow axis direction, and as a result, changes its polarized state into a 135-degree linearly polarized state. Light having entered the quarter wavelength layer in a left-handed circularly polarized state changes its polarized state into a 45-degree linearly polarized state. Further, light having entered the quarter wavelength layer in a left-handed elliptically polarized state changes its polarized state into a right-handed elliptically polarized state, and light having entered the quarter wavelength layer in the right-handed elliptically polarized state changes its polarized state into the left-handed elliptically polarized state. Light having entered the quarter wavelength layer in the 45-degree linearly polarized state changes its polarized state into the right-handed circularly polarized state.

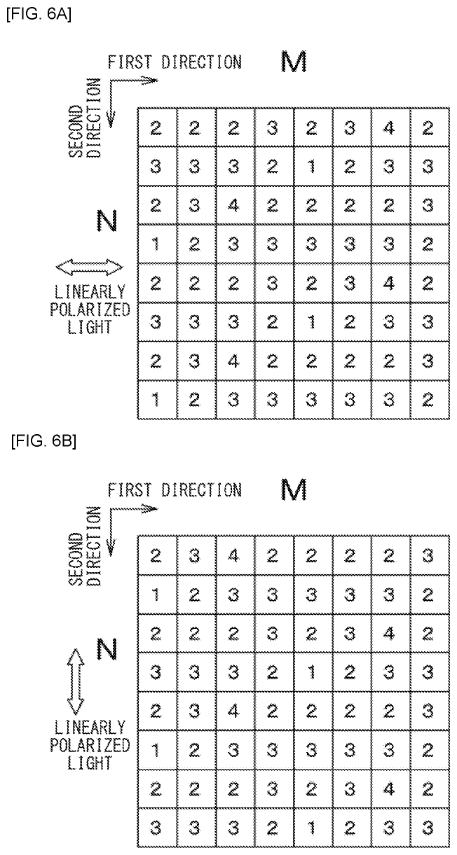

Schematic diagrams of FIGS. 6A, 6B, 7A, 7B, 8A, and 8B each qualitatively illustrate amounts of light (light intensities) at the photoelectric conversion sections, the light being received by the 8×8 photoelectric conversion elements (see FIGS. 1A and 1B for the state in which the quarter wavelength layers 60 and the wire grid polarizers 50 are disposed) included in the photoelectric conversion element unit. It is to be noted that in these drawings, the numerical values each indicate a relative amount of light (light intensity). The smaller the numerical value the photoelectric conversion element has, the greater amount of light the photoelectric conversion element receives.

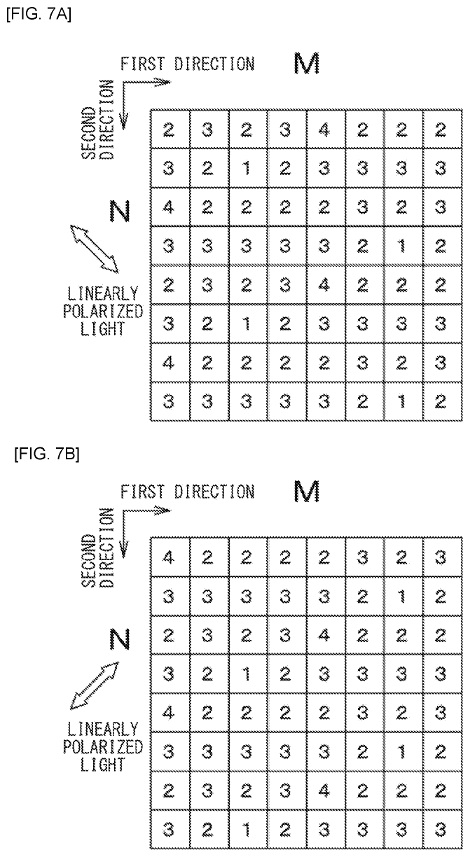

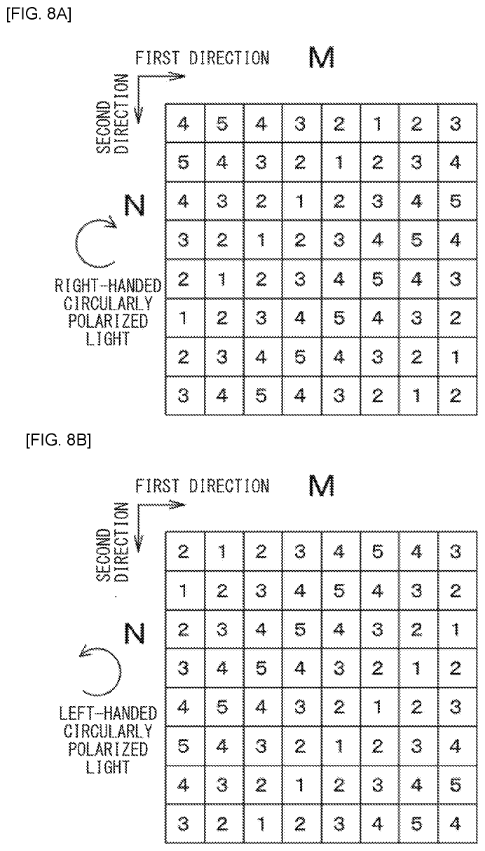

Here, in an example illustrated in FIG. 6A, linearly polarized light that is polarized in the first direction enters the N kinds of quarter wavelength layers 60 from above in the direction perpendicular to the sheet plane of FIG. 1A. Further, in an example illustrated in FIG. 6B, linearly polarized light that is polarized in the second direction enters the N kinds of quarter wavelength layers 60 from above in the direction perpendicular to the sheet plane of FIG. 1A. Moreover, in an example illustrated in FIG. 7A, linearly polarized light that is polarized in a direction at +45 degrees with respect to the first direction enters the N kinds of quarter wavelength layers 60 from above in the direction perpendicular to the sheet plane of FIG. 1A. In addition, in an example illustrated in FIG. 7B, linearly polarized light that is polarized in a direction at +135 degrees with respect to the first direction enters the N kinds of quarter wavelength layers 60 from above in the direction perpendicular to the sheet plane of FIG. 1A. Moreover, in an example illustrated in FIG. 8A, right-handed circularly polarized light enters the N kinds of quarter wavelength layers 60 from above in the direction perpendicular to the sheet plane of FIG. 1A. In addition, in an example illustrated in FIG. 8B, left-handed circularly polarized light enters the N kinds of quarter wavelength layers 60 from above in the direction perpendicular to the sheet plane of FIG. 1A.

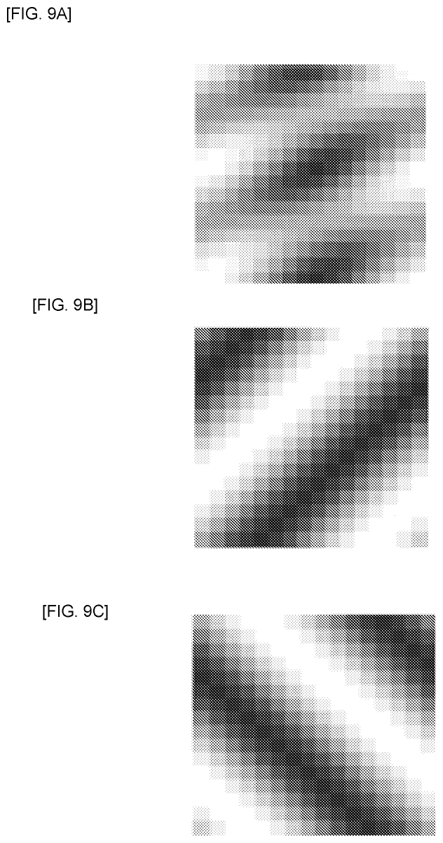

An image obtainable in a state similar to that in FIG. 6A is presented in FIG. 9A, an image obtainable in a state similar to that in FIG. 8A is presented in FIG. 9B, and an image obtainable in a state similar to that in FIG. 8B is presented in FIG. 9C. It is to be noted that FIGS. 9A, 9B, and 9C are images obtained by a light receiving device including a photoelectric conversion element unit similar to that in FIGS. 1A and 1B (however, including 16×16 photoelectric conversion elements). A change along the second direction of a diagonally extending stripe pattern in a gray scale is, in a case where the entering light is circularly polarized light, a change with the photoelectric conversion element unit as one period (see FIGS. 9B and 9C), and is, in a case where the entering light is linearly polarized light, a change with the photoelectric conversion element unit as a (½) period (see FIG. 9A). In addition, a pitch of the change along the second direction of the diagonally extending stripe pattern in the gray scale becomes longer as the number of the photoelectric conversion elements included in the photoelectric conversion element unit increases. That is, in the photoelectric conversion element unit including 16×16 photoelectric conversion elements, the pitch of the change along the second direction of the diagonally extending stripe pattern in the gray scale is twice that in the photoelectric conversion element unit including 8×8 photoelectric conversion elements. In addition, by detecting the direction of extension of the stripe pattern, the pitch of the stripe pattern, and the like in this way, it is possible to easily know the polarized state of entering light.

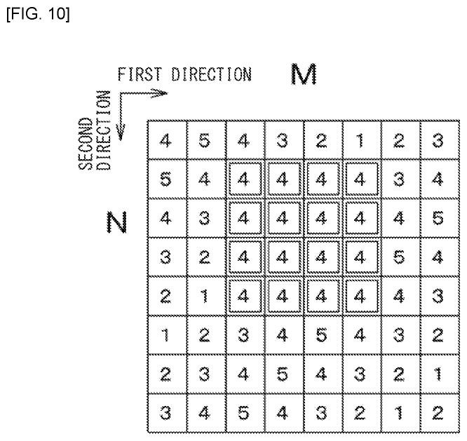

FIG. 10 illustrates an example of a schematic diagram that qualitatively illustrates the amounts of light (light intensities) received by the photoelectric conversion sections of the photoelectric conversion elements included in the photoelectric conversion element unit when an abnormality is found in the light receiving device of Example 1, in which double-enclosed photoelectric conversion elements each represent a photoelectric conversion element in which an abnormal state is detected. It is to be noted that the state illustrated in FIG. 10 is an example of a state where an abnormality is found in the state illustrated in FIG. 8A.

In the light receiving device of Example 1, or in the light receiving device of each of Examples 2 and 3 to be described later, the photoelectric conversion sections 21 having a well-known configuration and structure are formed in a silicon semiconductor substrate 31 by a well-known method. The photoelectric conversion sections 21 are covered with lower interlayer insulating layers 33, an underlying insulating layer 34 is formed on the lower interlayer insulating layers 33, and the wire grid polarizers 50 are formed on the underlying insulating layer 34. The wire grid polarizers 50 and the underlying insulating layer 34 are covered with a planarization film 35, and the quarter wavelength layers 60 are formed on the planarization film 35. An upper interlayer insulating layer 36 is formed on the quarter wavelength layers 60 and the planarization film 35, and the on-chip microlenses 81 are disposed on the upper interlayer insulating layer 36. In the illustrated example, the lower interlayer insulating layers 33 are in a five-layered arrangement and the wiring layers 32 are in a four-layered arrangement; however, this is non-limiting, and the lower interlayer insulating layers 33 and the wiring layers 32 may be provided in any number of layers. In FIG. 3 or in FIGS. 11, 13, 21, and 22 to be described later, hatching on the lower interlayer insulating layers 33 is omitted.

As illustrated in a schematic perspective view in FIG. 27, the wire grid polarizer 50 has a line-and-space structure. As illustrated in a schematic partial end view in FIG. 29A, a line part 54 of the wire grid polarizer 50 includes a stack structure (a first stack structure) in which a light reflection layer 51 including a first electrically-conductive material (specifically, aluminum (Al)), an insulating film 52 including SiO₂, and a light absorption layer 53 including a second electrically-conductive material (specifically, tungsten (W)) are stacked from a side (the photoelectric conversion section side in Example 1) opposite to the light entrance side. The insulating film 52 is formed on the entire top surface of the light reflection layer 51, and the light absorption layer 53 is formed on the entire top surface of the insulating film 52. Specifically, the light reflection layer 51 includes aluminum (Al) with a thickness of 150 nm, the insulating film 52 includes SiO₂ with a thickness of 25 nm or 50 nm, and the light absorption layer 53 includes tungsten (W) with a thickness of 25 nm. The light reflection layer 51 functions as a polarizer. Of light entering the wire grid polarizer 50, the light reflection layer 51 attenuates polarized waves including an electric field component in a direction parallel to a direction of extension (the P direction) of the light reflection layer 51, and transmits polarized waves including an electric field component in a direction (the Q direction) orthogonal to the direction of extension of the light reflection layer 51. The P direction is a light absorption axis of the wire grid polarizer 50, and the Q direction is a light transmission axis (the polarization orientation) of the wire grid polarizer 50. While an underlying film including Ti, TiN, or a layered structure of Ti/TiN is formed between the underlying insulating layer 34 and the light reflection layer 51, illustration of the underlying film is omitted.

The light reflection layer 51, the insulating film 52, and the light absorption layer 53 are common to the photoelectric conversion elements 11. As illustrated in FIGS. 4 and 5, a frame part 59 is configured by a stack structure (a second stack structure) including the light reflection layer 51, the insulating film 52, and the light absorption layer 53, except that a space part 55 is not provided therein. That is, the frame part 59 surrounding the wire grid polarizer 50 is provided, and the frame part 59 and the line part 54 of the wire grid polarizer 50 are coupled to each other. In this way, the frame part 59 has the same structure as the line part 54 of the wire grid polarizer 50, and also serves as a light-blocking section. The P direction and the Q direction are different between FIGS. 4 and 5.

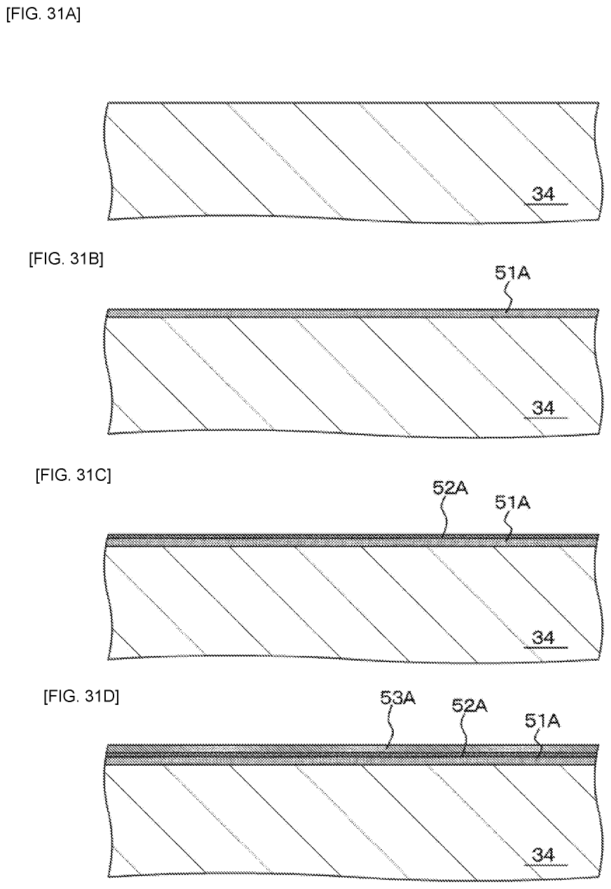

It is possible to fabricate the wire grid polarizer 50 by the following method. That is, an underlying film (not illustrated) including Ti, TiN, or a layered structure of Ti/TiN, and a light-reflection-layer-forming layer 51A including the first electrically-conductive material (specifically, aluminum) are provided on the underlying insulating layer 34 in accordance with a vacuum vapor deposition method (see FIG. 31A and FIG. 31B). Subsequently, an insulating-film-forming layer 52A is provided on the light-reflection-layer-forming layer 51A, and a light-absorption-layer-forming layer 53A including the second electrically-conductive material is provided on the insulating-film-forming layer 52A. Specifically, the insulating-film-forming layer 52A including SiO₂ is formed on the light-reflection-layer-forming layer 51A in accordance with a CVD method (see FIG. 31C). Then, the light-absorption-layer-forming layer 53A including tungsten (W) is formed on the insulating-film-forming layer 52A by a sputtering method. In this way, it is possible to obtain the structure illustrated in FIG. 31D.

Thereafter, the light-absorption-layer-forming layer 53A, the insulating-film-forming layer 52A, the light-reflection-layer-forming layer 51A, and moreover, the underlying film are patterned in accordance with a lithography technique and a dry etching technique. This makes it possible to obtain the wire grid polarizer 50 having the line-and-space structure including a plurality of line parts (stack structures) 54 disposed side by side with a space therebetween, the line parts 54 each including the light reflection layer 51, the insulating film 52, and the light absorption layer 53 that have a band shape. Thereafter, it is sufficient that the planarization film 35 is formed to cover the wire grid polarizer 50 in accordance with a CVD method. The wire grid polarizer 50 is surrounded by the frame part 59 including the light reflection layer 51, the insulating film 52, and the light absorption layer 53.

As a modification example of the wire grid polarizer 50, a configuration may be adopted in which, as illustrated in a partial end view in FIG. 29B, a protective film 56 formed on the wire grid polarizer 50 is provided and the space part 55 of the wire grid polarizer 50 is an empty space. That is, a portion or all of the space part 55 is filled with air.

Further, as illustrated in a partial end view in FIG. 30A, a second protective film 57 may be formed between the wire grid polarizer 50 and the protective film 56. Where a refractive index of a material included in the protective film 56 is denoted by n₁′ and a refractive index of a material included in the second protective film 57 is denoted by n₂′, n₁′>n₂′ is satisfied. Here, for example, the protective film 56 includes SiN (n₁′=2.0), and the second protective film 57 includes SiO₂ (n₂′=1.5). Although a bottom surface (a surface opposed to the underlying insulating layer 34) of the second protective film 57 is illustrated in a flat state in the figure, the bottom surface of the second protective film 57 may have a shape protruding toward the space part 55. Alternatively, the bottom surface of the second protective film 57 may have a shape recessed toward the protective film 56, or may be recessed in a wedge shape.

Such a structure is obtained by producing the wire grid polarizer 50 having the line-and-space structure and thereafter forming the second protective film 57 including SiO₂ and having an average thickness of 0.01 μm to 10 μm over the entire surface in accordance with a CVD method. A top of the space part 55 located between the line parts 54 is closed with the second protective film 57. Subsequently, the protective film 56 including SiN and having an average thickness of 0.1 μm to 10 μm is formed on the second protective film 57 in accordance with a CVD method. By forming the protective film 56 including SiN, it is possible to obtain the wire grid polarizer 50 that is high in reliability. However, SiN has a relatively high dielectric constant. Accordingly, a reduction in average refractive index nₐᵥₑ is achieved by forming the second protective film 57 including SiO₂.

In this way, forming the space part of the wire grid polarizer as an empty space (specifically, filling the space part with air) makes it possible to reduce the value of the average refractive index nₐᵥₑ, and consequently makes it possible to achieve improvements in transmittance and extinction ratio of the wire grid polarizer. In addition, because it is possible to increase the value of the formation pitch Q₀, improvement in manufacturing yield of the wire grid polarizer is achievable. Moreover, by forming the protective film on the wire grid polarizer, it is possible to provide the photoelectric conversion section and the light receiving device that each have high reliability. In addition, by coupling the frame part and the line part of the wire grid polarizer to each other and forming the frame part into the same structure as that of the line part of the wire grid polarizer, it is possible to form a homogeneous and uniform wire grid polarizer with stability. Accordingly, it is possible to resolve an issue of peeling occurring at portions in a peripheral part of the wire grid polarizer corresponding to four corners of the photoelectric conversion section, an issue of performance deterioration of the wire grid polarizer itself caused by a difference between a structure of the peripheral part of the wire grid polarizer and a structure of a middle part of the wire grid polarizer, and an issue of easy leakage of light having entered the peripheral part of the wire grid polarizer into the adjacent photoelectric conversion section having a different polarization direction, and it is thus possible to provide the photoelectric conversion section and the light receiving device that each have high reliability.

The wire grid polarizer may have a configuration without the insulating film, that is, a configuration in which the light reflection layer (including aluminum, for example) and the light absorption layer (including tungsten, for example) are stacked from the side opposite to the light entrance side. Alternatively, the wire grid polarizer may include a single electrically-conductive and light-blocking material layer. Examples of a material included in the electrically-conductive and light-blocking material layer may include an electrically-conductive material that has a low complex refractive index in a wavelength region to which the photoelectric conversion section has sensitivity, such as aluminum (Al), copper (Cu), gold (Au), silver (Ag), platinum (Pt), tungsten (W), or an alloy containing any of these metals.

Depending on cases, a third protective film 58 including SiO₂, for example, may be formed on a side surface of the line part 54 facing the space part 55, as illustrated in a schematic partial end view of the wire grid polarizer in FIG. 30B. That is, the space part 55 is filled with air, and in addition, the third protective film 58 is present in the space part. The third protective film 58 is formed in accordance with an HDP-CVD method, for example. This makes it possible to form the third protective film 58 having a further smaller thickness on the side surface of the line part 54 in a conformal manner.

Depending on cases, a portion of the insulating film 52 may be cut away to allow the light reflection layer 51 and the light absorption layer 53 to be in contact with each other at a cut-away portion 52a of the insulating film 52, as illustrated in a schematic perspective view of a modification example of the wire grid polarizer in FIG. 28.

The quarter wavelength layer 60 illustrated in a schematic perspective diagram in FIG. 32 may be fabricated by the following method. Specifically, the first dielectric layer 61 is provided on the planarization film 35 in accordance with a CVD method. Thereafter, the first dielectric layer 61 is patterned in accordance with a lithography technique and a dry etching technique. It is thereby possible to obtain a line-and-space structure in which a plurality of first dielectric layers 61 having a band shape is disposed side by side with a space therebetween. Thereafter, the second dielectric layer 62 is formed on an entire surface in accordance with an ALD method, following which the second dielectric layer 62 is subjected to a planarization process. It is thereby possible to obtain the quarter wavelength layer 60.

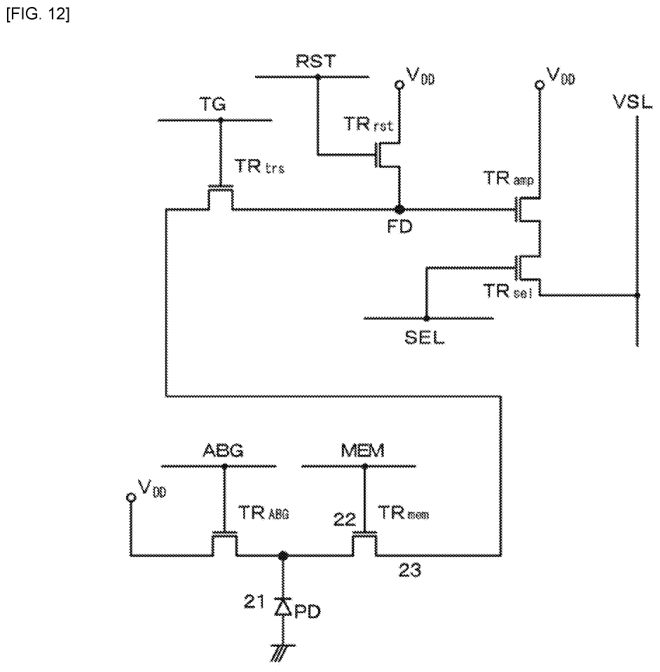

The photoelectric conversion section 21 having a well-known configuration and structure is formed in the silicon semiconductor substrate 31 by a well-known method. In the semiconductor substrate 31, a memory section TRₘₑₘ that is coupled to the photoelectric conversion section 21 and temporarily holds electric charge generated at the photoelectric conversion section 21 may be formed as illustrated in FIGS. 11 and 12. FIG. 11 illustrates a schematic partial cross-sectional view of a portion of a modification example of the photoelectric conversion element unit in the light receiving device of Example 1, and FIG. 12 illustrates an equivalent circuit diagram of the photoelectric conversion section. It is to be noted that the following description also applies to Examples 2 and 3.

The memory section TRₘₑₘ includes the photoelectric conversion section 21, a gate section 22, a channel formation region, and a high-concentration impurity region 23. The gate section 22 is coupled to a memory selection line MEM. In addition, the high-concentration impurity region 23 is formed in the silicon semiconductor substrate 31 at a distance from the photoelectric conversion section 21 by a well-known method. A light-blocking film 24 is formed above the high-concentration impurity region 23. That is, the high-concentration impurity region 23 is covered with the light-blocking film 24. This prevents light from entering the high-concentration impurity region 23. By providing the memory section TRₘₑₘ that temporarily holds electric charge, it is possible to easily implement a so-called global shutter function. Examples of a material included in the light-blocking film 24 may include chromium (Cr), copper (Cu), aluminum (Al), tungsten (W), and a resin that does not allow light to pass therethrough (e.g., polyimide resin).

A transfer transistor TRₜᵣₛ illustrated only in FIG. 12 includes a gate section coupled to a transfer gate line TG, a channel formation region, one source/drain region coupled to the high-concentration impurity region 23 (or sharing a region with the high-concentration impurity region 23), and another source/drain region included in a floating diffusion layer FD.

A reset transistor TRᵣₛₜ illustrated only in FIG. 12 includes a gate section, a channel formation region, and source/drain regions. The gate section of the reset transistor TRᵣₛₜ is coupled to a reset line RST, one of the source/drain regions of the reset transistor TRᵣₛₜ is coupled to a power source V_{DD}, and another of the source/drain regions also serves as the floating diffusion layer FD.

An amplifier transistor TRₐₘₚ illustrated only in FIG. 12 includes a gate section, a channel formation region, and source/drain regions. The gate section is coupled to the other of the source/drain regions (the floating diffusion layer FD) of the reset transistor TRᵣₛₜ via a wiring layer. In addition, one of the source/drain regions is coupled to the power source V_{DD}.

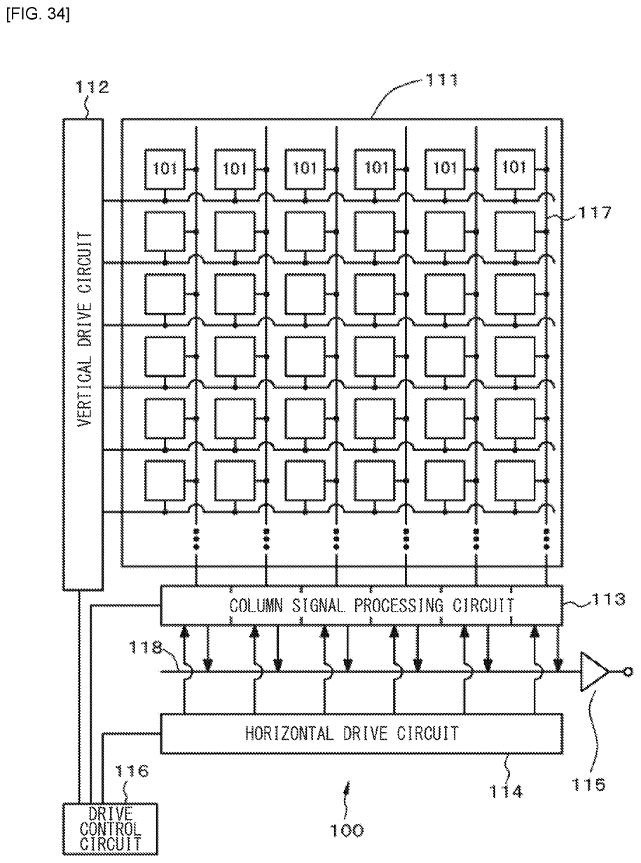

A selection transistor TRₛₑₜ illustrated only in FIG. 12 includes a gate section, a channel formation region, and source/drain regions. The gate section is coupled to a selection line SEL. In addition, one of the source/drain regions shares a region with the other of the source/drain regions included in the amplifier transistor TRₐₘₚ, and another of the source/drain regions is coupled to a signal line (a data output line) VSL (117) (see FIG. 34).

The photoelectric conversion section 21 is also coupled to one source/drain region of an electric charge discharging control transistor TR_{ABG}. A gate section of the electric charge discharging control transistor TR_{ABG} is coupled to an electric charge discharging control transistor control line ABG, and another source/drain region is coupled to the power source V_{DD}.

A series of operations including electric charge accumulation, reset operation, and electric charge transfer to be performed by the photoelectric conversion section 21 is similar to a series of operations including electric charge accumulation, reset operation, and electric charge transfer to be performed by an existing photoelectric conversion section. Accordingly, a detailed description thereof is omitted.

The photoelectric conversion section 21, the memory section TRₘₑₘ, the transfer transistor TRₜᵣₛ, the reset transistor TRᵣₛₜ, the amplifier transistor TRₐₘₚ, the selection transistor TRₛₑₗ, and the electric charge discharging control transistor TR_{ABG} are covered with the lower interlayer insulating layer 33.

FIG. 34 illustrates a conceptual diagram of a solid-state imaging device where the light receiving device of any of Examples 1 to 3 is applied to the solid-state imaging device. The solid-state imaging device 100 includes an imaging region (an effective pixel region) 111 in which photoelectric conversion elements 101 are arranged in a two-dimensional array, and a vertical drive circuit 112, a column signal processing circuit 113, a horizontal drive circuit 114, an output circuit 115, a drive control circuit 116, and the like that are provided in a peripheral region and serve as drive circuits (peripheral circuits) thereof. Needless to say, these circuits may be configured by well-known circuits or by using another circuit configuration (e.g., various circuits for use with an existing CCD imaging device or an existing CMOS imaging device). In FIG. 34, a reference number “101” indicating the photoelectric conversion element 101 is given in only one row.

The drive control circuit 116 generates a clock signal and a control signal serving as references for operations of the vertical drive circuit 112, the column signal processing circuit 113, and the horizontal drive circuit 114, on the basis of a vertical synchronized signal, a horizontal synchronized signal, and a master clock. Thereafter, the clock signal and the control signal thus generated are inputted to the vertical drive circuit 112, the column signal processing circuit 113, and the horizontal drive circuit 114.

The vertical drive circuit 112 includes, for example, a shift register, and selectively scans the photoelectric conversion elements 101 in the imaging region 111 row by row sequentially in the vertical direction. Thereafter, a pixel signal (an image signals) based on a current (signal) generated in accordance with an amount of light received at each of the photoelectric conversion elements 101 is transmitted to the column signal processing circuit 113 via signal lines (data output lines) 117 and VSL.

The column signal processing circuit 113 is provided, for example, for each column of the photoelectric conversion elements 101 and performs signal processing for noise removal or signal amplification on the image signals outputted from one row of the photoelectric conversion elements 101 in accordance with a signal from a black reference pixel (formed around the effective pixel region, although not illustrated) for each of the photoelectric conversion sections. A horizontal selection switch (not illustrated) is provided in an output stage of the column signal processing circuit 113 and coupled between the column signal processing circuit 113 and a horizontal signal line 118.

The horizontal drive circuit 114 includes, for example, a shift register, and sequentially selects the column signal processing circuits 113 by sequentially outputting horizontal scanning pulses, and outputs signals from the respective column signal processing circuits 113 to the horizontal signal line 118.

The output circuit 115 performs signal processing on signals sequentially supplied from the respective column signal processing circuits 113 via the horizontal signal line 118, and outputs the processed signals.

The photoelectric conversion element unit in the light receiving device of Example 1 includes combinations of photoelectric conversion elements in each of which the quarter wavelength layer having a desired fast axis orientation, the wire grid polarizer having a desired polarization orientation, and the photoelectric conversion section are disposed in this order from the light entrance side. Accordingly, it is possible to easily recognize the polarized state of light entering the photoelectric conversion elements, and to easily know what polarized light component is included in a large amount in the light. It is therefore possible to provide a light receiving device (for example, a small-sized sensor) for determining a state of polarized light. With an existing light receiving device in which only a wire grid polarizer having a desired polarization orientation and a photoelectric conversion section are disposed in this order, it is difficult to know whether an entire image is polarized in a certain direction, and it is also difficult to know the polarized state in a narrow region of an image. In contrast, with the light receiving device of Example 1, it is possible to easily know whether the entire image is polarized in a certain direction, and it is also possible to know the polarized state in a narrow region of an image with accuracy. In addition, it is possible for an operator to know that an abnormality has occurred in a subject (an object) upon looking at the image, and it is possible to automatically detect the occurrence of an abnormality by performing image processing.

In a polarized state measuring method for an object (a subject) of Example 1,
a plurality of photoelectric conversion element units 10A is provided, and
each of the photoelectric conversion element units 10A includes the photoelectric conversion element unit of Example 1 described above.

The polarized state measuring method includes
acquiring image data by capturing an image of the object (the subject) with the light receiving device, and
obtaining a comparison result by comparing, at the light receiving device, the image data acquired that indicates a polarized state with standard polarized state data of a standard object.

According to the polarized state measuring method for an object of Example 1, it is sufficient that light having a predetermined polarized state (for example, any of the polarized states described with reference to FIGS. 6A, 6B, 7A, 7B, 8A, and 8B) and a predetermined wavelength (for example, 600 nm) is applied to the object (the subject) to thereby capture an image of the object (the subject) (for example, see FIGS. 9A, 9B, and 9C).

In addition, according to the polarized state measuring method for an object of Example 1, it is possible to evaluate a surface state of the object (the subject) by obtaining the comparison result. Specifically, it is possible to measure birefringence of the object (the subject) and, as one example, it is possible to grasp a molded state of a lens which is the object (the subject). Alternatively, by obtaining the comparison result on the object that is in a thin-film form, it is possible to evaluate a state of a film thickness of the object (the subject). Specifically, it is possible to perform measurements of the film thickness by using the light receiving device of Example 1 in an ellipsometer. Alternatively, the presence of a foreign substance in the object (the subject) may be evaluated by obtaining the comparison result.

### EXAMPLE 2

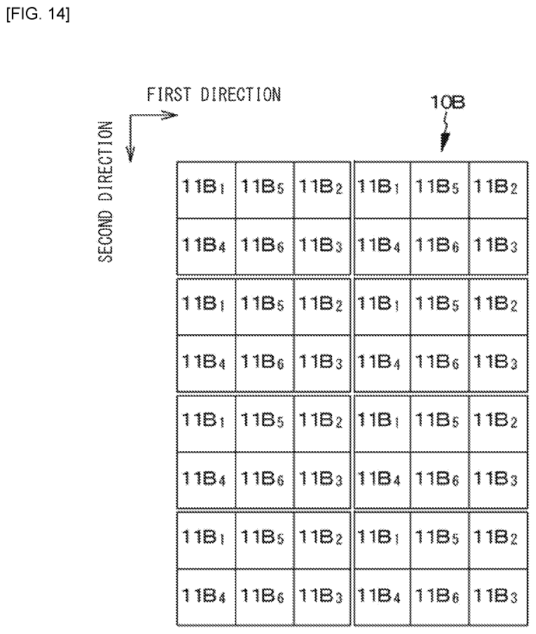

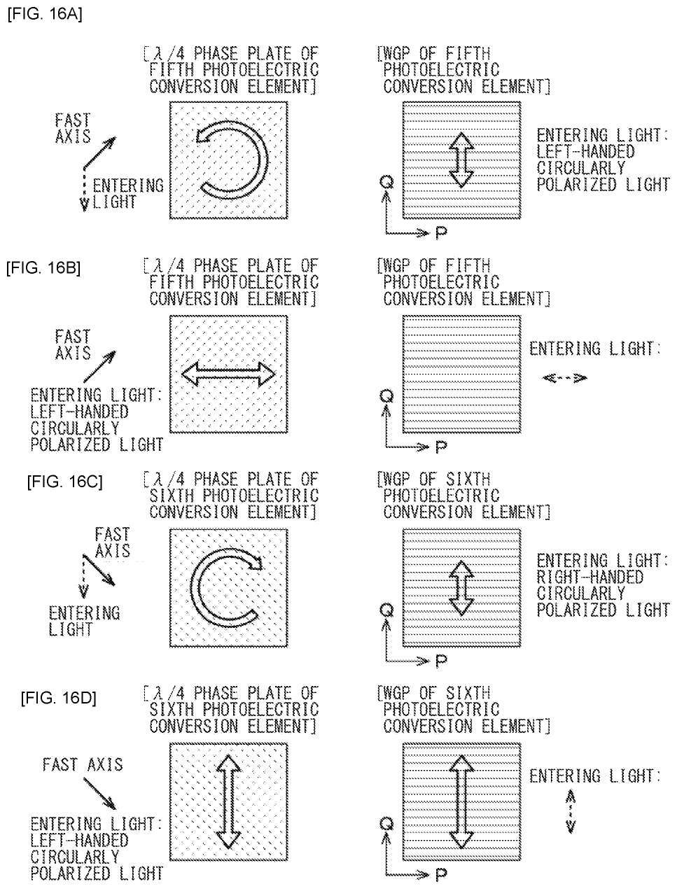

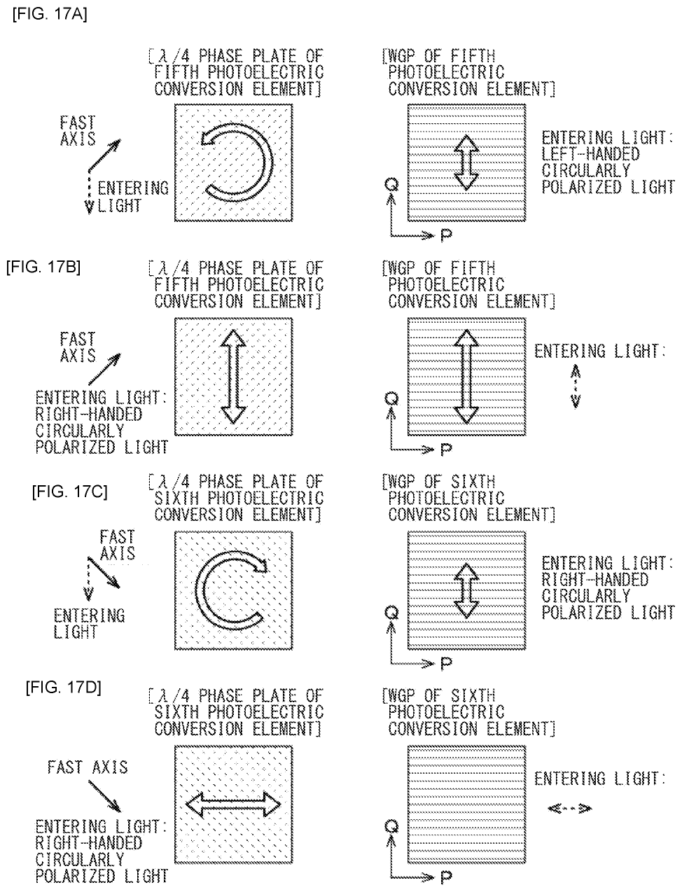

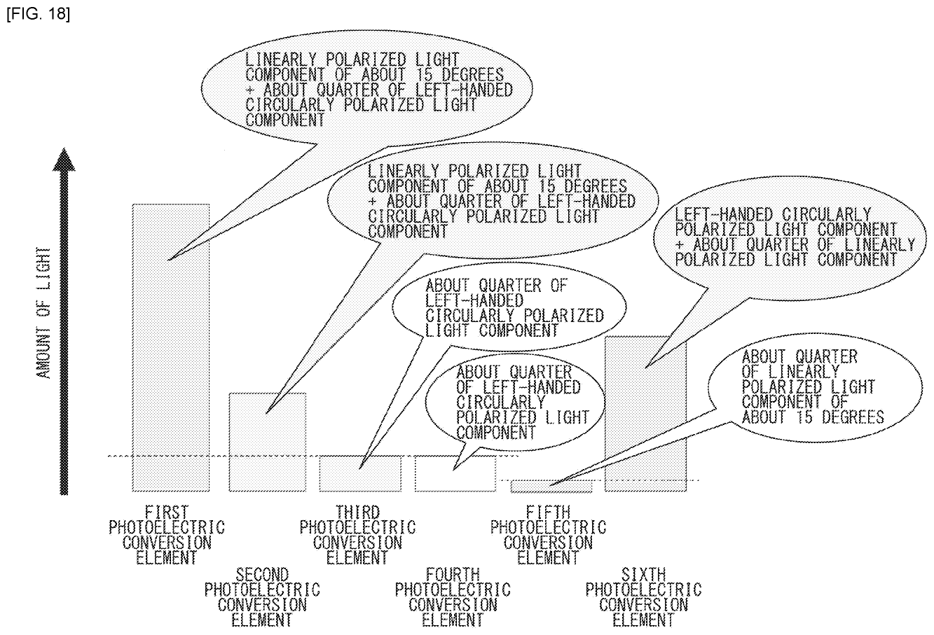

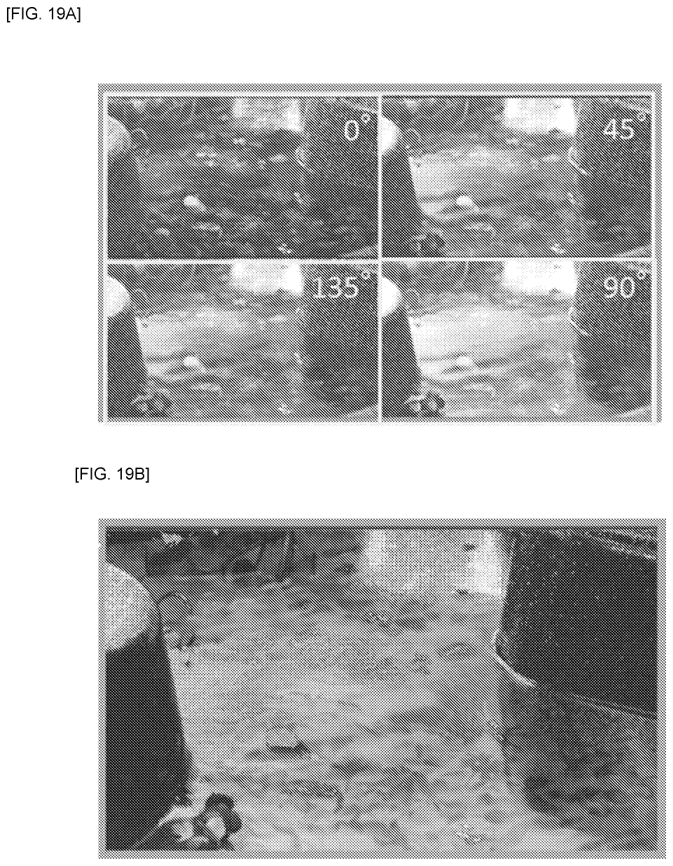

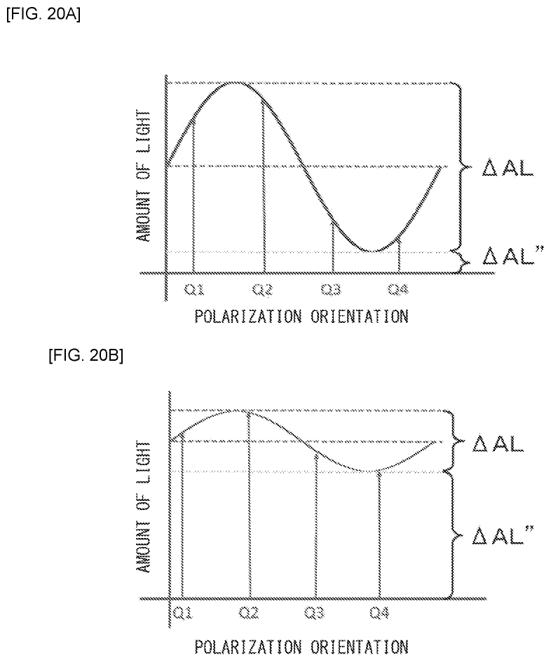

Example 2 relates to the light receiving device according to the second aspect of the present disclosure. FIG. 13 illustrates a schematic partial cross-sectional view of the photoelectric conversion element unit in the light receiving device of Example 2. FIG. 14 illustrates a conceptual diagram of the order of arrangement of 3×2 photoelectric conversion elements included in the photoelectric conversion element unit in the light receiving device of Example 2. FIG. 15A illustrates polarized states of light passing through the quarter wavelength layers included in the photoelectric conversion element unit in the light receiving device of Example 2, and FIG. 15B schematically illustrates states of light passing through the wire grid polarizers included therein. FIGS. 16A and 16B and FIGS. 17A and 17B schematically illustrate a fast axis orientation of a quarter wavelength layer included in a fifth photoelectric conversion element in the light receiving device of Example 2, a polarization orientation of a wire grid polarizer included therein, a polarized state of light having passed through the quarter wavelength layer, and a state of the light having passed through the wire grid polarizer. FIGS. 16C and 16D and FIGS. 17C and 17D schematically illustrate a fast axis orientation of a quarter wavelength layer included in a sixth photoelectric conversion element in the light receiving device of Example 2, a polarization orientation of a wire grid polarizer included therein, a polarized state of light having passed through the quarter wavelength layer, and a state of the light having passed through the wire grid polarizer. Moreover, FIG. 18 schematically illustrates amounts of light (light intensities) received by the photoelectric conversion sections of 3×2 photoelectric conversion elements included in the photoelectric conversion element unit in the light receiving device of Example 2. FIGS. 19A and 19B illustrate imaging states of the light receiving device of Example 2. FIGS. 20A and 20B illustrate diagrams for describing a so-called degree of polarization.

The light receiving device of Example 2 includes a plurality of photoelectric conversion element units 10B.

Each of the photoelectric conversion element units 10B includes a first photoelectric conversion element 11B₁, a second photoelectric conversion element 11B₂, a third photoelectric conversion element 11B₃, a fourth photoelectric conversion element 11B₄, a fifth photoelectric conversion element 11B₅, and a sixth photoelectric conversion element 11B₆,
the first photoelectric conversion element 11B₁, the second photoelectric conversion element 11B₂, the third photoelectric conversion element 11B₃, and the fourth photoelectric conversion element 11B₄ each include the wire grid polarizer 50 and the photoelectric conversion section 21 that are disposed in this order from the light entrance side, and
the fifth photoelectric conversion element 11B₅ and the sixth photoelectric conversion element 11B₆ each include the quarter wavelength layer 60, the wire grid polarizer 50, and the photoelectric conversion section 21 that are disposed in this order from the light entrance side.

In addition,
a polarization orientation targeted for transmission by the wire grid polarizer 50 included in the first photoelectric conversion element 11B₁ is α degrees,
a polarization orientation targeted for transmission by the wire grid polarizer 50 included in the second photoelectric conversion element 11B₂ is (α+45) degrees,
a polarization orientation targeted for transmission by the wire grid polarizer 50 included in the third photoelectric conversion element 11B₃ is (α+90) degrees,
a polarization orientation targeted for transmission by the wire grid polarizer 50 included in the fourth photoelectric conversion element 11B₄ is (α+135) degrees,
a polarization orientation targeted for transmission by the wire grid polarizer 50 included in the fifth photoelectric conversion element 11B₅ is α′ degrees,
a polarization orientation targeted for transmission by the wire grid polarizer 50 included in the sixth photoelectric conversion element 11B₆ is α′ degrees, and
where the fast axis orientation of the quarter wavelength layer 60 included in the fifth photoelectric conversion element 11B₅ is β degrees, the fast axis orientation of the quarter wavelength layer 60 included in the sixth photoelectric conversion element 11B₆ is ((β±90) degrees.

Here, an angle formed between α and the second direction may substantially be any angle, and examples of the angle may include 0 degrees and 90 degrees. In Example 2, α=0 degrees. Further, an angle formed between R and the second direction may substantially be any angle, and examples of the angle may include 45 degrees and 135 degrees. In Example 2, β=45 degrees. That is, the angle formed between R and the second direction is 45 degrees. Accordingly, a relationship that β=(a±45) degrees is satisfied. Moreover, an angle formed between β and α′ satisfies α′=(β±45) degrees. In Example 2, α′=(β−45). That is, with respect to the second direction,
α=0 degrees,
β=45 degrees, and
α′=0 degrees.

It is to be noted that in FIGS. 15B, 16A, 16B, 16C, 16D, 17A, 17B, 17C, and 17D, and in FIGS. 23C, 24C, 25C, and 26C to be described later, thin solid lines indicate the P direction. A direction orthogonal to the thin solid lines is the Q direction. In addition, in FIGS. 16A, 16B, 16C, 16D, 17A, 17B, 17C, and 17D, and in FIGS. 23A, 23B, 24A, 24B, 25A, 25B, 26A, and 26B to be described later, thin dotted lines indicate the fast axis orientation. Moreover, in FIG. 15B, arrows indicate the Q direction, and also represent light including a linearly polarized light component that is able to pass through the wire grid polarizers.

In addition, in the light receiving device of Example 2,
each of the photoelectric conversion element units 10B includes a total of 3×2 photoelectric conversion elements, with three photoelectric conversion elements in the first direction, and two photoelectric conversion elements in the second direction different from the first direction, and
the first photoelectric conversion element 11B₁, the second photoelectric conversion element 11B₂, and the fifth photoelectric conversion element 11B₅ are disposed in no particular order in a first row along the first direction, and the third photoelectric conversion element 11B₃, the fourth photoelectric conversion element 11B₄, and the sixth photoelectric conversion element 11B₆ are disposed in no particular order in a second row along the first direction. In the illustrated example, the first photoelectric conversion element 11B₁, the fifth photoelectric conversion element 11B₅, and the second photoelectric conversion element 11B₂ are disposed in this order in the first row along the first direction, and the fourth photoelectric conversion element 11B₄, the sixth photoelectric conversion element 11B₆, and the third photoelectric conversion element 11B₃ are disposed in this order in the second row along the first direction.

Moreover, in the light receiving device of Example 2, at least light including a linearly polarized light component and light including a circularly polarized light component enter the photoelectric conversion element unit 10B in a mixed state. In an example illustrated in FIG. 16, light including a left-handed circularly polarized light component enters. In an example illustrated in FIG. 17, light including a right-handed circularly polarized light component enters.

A relationship between a polarization orientation of α′ degrees and a fast axis orientation of β degrees is, in a broad sense, preferably set to:
(a) a relationship in which in a case where, when either light including the right-handed circularly polarized light component or light including the left-handed circularly polarized light component enters the fifth photoelectric conversion element 11B₅ having a fast axis orientation of β degrees and is outputted as linearly polarized light to enter the wire grid polarizer, this entering light is outputted without being blocked by the wire grid polarizer,
   when either light including the right-handed circularly polarized light component or light including the left-handed circularly polarized light component enters the sixth photoelectric conversion element 11B₆ having a fast axis orientation of (β±90) degrees and is outputted as linearly polarized light to enter the wire grid polarizer, this entering light is blocked by the wire grid polarizer; or
(b) a relationship in which in a case where, when either light including the right-handed circularly polarized light component or light including the left-handed circularly polarized light component enters the fifth photoelectric conversion element 11B₅ having the fast axis orientation of 3 degrees and is outputted as linearly polarized light to enter the wire grid polarizer, this entering light is blocked by the wire grid polarizer,
when either light including the right-handed circularly polarized light component or light including the left-handed circularly polarized light component enters the sixth photoelectric conversion element 11B₆ having the fast axis orientation of (β±90) degrees and is outputted as linearly polarized light to enter the wire grid polarizer, this entering light is outputted without being blocked by the wire grid polarizer.

Alternatively, the relationship between the polarization orientation of α′ degrees and the fast axis orientation of β degrees satisfies, for example, α′=(β+45) degrees. Therefore,
(c-1) when light including the right-handed circularly polarized light component enters the fifth photoelectric conversion element 11B₅ having the fast axis orientation of β degrees, linearly polarized light at 135 degrees with respect to the fast axis orientation β is outputted from the fifth photoelectric conversion element 11B₅. Then, this linearly polarized light enters the wire grid polarizer of the fifth photoelectric conversion element 11B₅ having a polarization orientation of (P+45) degrees, and is blocked by the wire grid polarizer because an angle formed between this linearly polarized light and the Q direction is 90 degrees.
(c-2) In contrast, when light including the right-handed circularly polarized light component enters the sixth photoelectric conversion element 11B₆ having a fast axis orientation of (3+90) degrees, linearly polarized light at 135 degrees with respect to the fast axis orientation (β+90) (linearly polarized light at 45 degrees with respect to the fast axis orientation β) is outputted from the sixth photoelectric conversion element 11B₆. Then, this linearly polarized light enters the wire grid polarizer of the sixth photoelectric conversion element 11B₆ having a polarization orientation of (β+45) degrees, and passes through the wire grid polarizer because an angle formed between this linearly polarized light and the Q direction is 0 degrees.
(d-1) When light including the left-handed circularly polarized light component enters the fifth photoelectric conversion element 11B₅ having the fast axis orientation of β degrees, linearly polarized light at 45 degrees with respect to the fast axis orientation β is outputted from the fifth photoelectric conversion element 11B₅. Then, this linearly polarized light enters the wire grid polarizer of the fifth photoelectric conversion element 11B₅ having the polarization orientation of (β+45) degrees, and passes through the wire grid polarizer because an angle formed between this linearly polarized light and the Q direction is 0 degrees.
(d-2) In contrast, when light including the left-handed circularly polarized light component enters the sixth photoelectric conversion element 11B₆ having the fast axis orientation of (β+90) degrees, linearly polarized light at 45 degrees with respect to the fast axis orientation (β+90) (linearly polarized light at 135 degrees with respect to the fast axis orientation β) is outputted from the sixth photoelectric conversion element 11B₆. Then, this linearly polarized light enters the wire grid polarizer of the sixth photoelectric conversion element 11B₆ having the polarization orientation of (β+45) degrees, and is blocked by the wire grid polarizer because an angle formed between this linearly polarized light and the Q direction is 90 degrees.

Moreover, in the light receiving device of Example 2,
the wire grid polarizer 50 included in the first photoelectric conversion element 11B₁ passes light including a component having a polarization orientation of α degrees, of light including a linearly polarized light component, and light including a component having the polarization orientation of α degrees, of light including a circularly polarized light component,
the wire grid polarizer 50 included in the second photoelectric conversion element 11B₂ passes light including a component having a polarization orientation of (α+45) degrees, of the light including the linearly polarized light component, and light including a component having the polarization orientation of (α+45) degrees, of the light including the circularly polarized light component,
the wire grid polarizer 50 included in the third photoelectric conversion element 11B₃ passes light including a component having a polarization orientation of (α+90) degrees, of the light including the linearly polarized light component, and light including a component having the polarization orientation of (α+90) degrees, of the light including the circularly polarized light component, and
the wire grid polarizer 50 included in the fourth photoelectric conversion element 11B₄ passes light including a component having a polarization orientation of (α+135) degrees, of the light including the linearly polarized light component, and light including a component having the polarization orientation of (α+135) degrees, of the light including the circularly polarized light component.

By way of example, suppose that light which is a mixture of linearly polarized light (which will hereinafter be referred to as “linearly polarized light of about 15 degrees” for convenience) that forms an angle of 15 degrees with respect to the second direction (an angle of 75 degrees with respect to the first direction) and left-handed circularly polarized light enters each of the photoelectric conversion element units 10B in the light receiving device of Example 2. In the light receiving device of Example 2, each of the photoelectric conversion elements has sensitivity to a specific wavelength (monochromatic light), which makes it unnecessary to provide a filter layer. One photoelectric conversion element unit 10B constitutes one pixel (a pixel). The light receiving device of Example 2 displays a monochromatic image.

In addition, in this case, the wire grid polarizer 50 included in the first photoelectric conversion element 11B₁ passes light including a component having a polarization orientation of α degrees (0 degrees with respect to the second direction), of the light including the linearly polarized light component, and light including a component having the polarization orientation of α degrees, of the light including the circularly polarized light component. Specifically, the wire grid polarizer 50 included in the first photoelectric conversion element 11B₁ passes light (amount of light: AL₁₋₁) including the component having the polarization orientation of α degrees, of the linearly polarized light of about 15 degrees, and light (amount of light: AL_{CP}) of about (¼) of the left-handed circularly polarized light. That is, the first photoelectric conversion element 11B₁, or the second photoelectric conversion element 11B₂, the third photoelectric conversion element 11B₃, and the fourth photoelectric conversion element 11B₄ to be described later are able to extract about (¼) of the light including the left-handed circularly polarized light component.
Amount of light based on the linearly polarized light of about 15 degrees: AL₁₋₁
Amount of light based on the left-handed circularly polarized light: AL_{CP}

In addition, the wire grid polarizer 50 included in the second photoelectric conversion element 11B₂ passes light including a component having the polarization orientation of (α+45) degrees (45 degrees with respect to the second direction), of the light including the linearly polarized light component, and light including a component having the polarization orientation of (α+45) degrees, of the light including the circularly polarized light component. Specifically, the wire grid polarizer 50 included in the second photoelectric conversion element 11B₂ passes light (amount of light: AL₁₋₂) including the component having the polarization orientation of (α+45) degrees, of the linearly polarized light of about 15 degrees, and light (amount of light: AL_{CP}) of about (¼) of the left-handed circularly polarized light.
Amount of light based on the linearly polarized light of about 15 degrees: AL₁₋₂
Amount of light based on the left-handed circularly polarized light: AL_{CP}

Moreover, the wire grid polarizer 50 included in the third photoelectric conversion element 11B₃ passes light including a component having the polarization orientation of (α+90) degrees (90 degrees with respect to the second direction), of the light including the linearly polarized light component, and light including a component having the polarization orientation of (α+90) degrees, of the light including the circularly polarized light component. Specifically, the wire grid polarizer 50 included in the third photoelectric conversion element 11B₃ passes light including the component having the polarization orientation of (α+90) degrees, of the linearly polarized light of about 15 degrees, and light (amount of light: AL_{CP}) of about (¼) of the left-handed circularly polarized light. It is to be noted that the light including the component having the polarization orientation of (α+90) degrees, of the linearly polarized light of about 15 degrees, is substantially blocked by the wire grid polarizer 50 included in the third photoelectric conversion element 11B₃.
Amount of light based on the linearly polarized light of about 15 degrees: 0
Amount of light based on the left-handed circularly polarized light: AL_{CP}

In addition, the wire grid polarizer 50 included in the fourth photoelectric conversion element 11B₄ passes light including a component having the polarization orientation of (α+135) degrees (135 degrees with respect to the second direction), of the light including the linearly polarized light component, and light including a component having the polarization orientation of (α+135) degrees, of the light including the circularly polarized light component. Specifically, the wire grid polarizer 50 included in the fourth photoelectric conversion element 11B₄ passes light including the component having the polarization orientation of (α+135) degrees, of the linearly polarized light of about 15 degrees, and light (amount of light: AL_{CP}) of about (¼) of the left-handed circularly polarized light. It is to be noted that the light including the component having the polarization orientation of (α+135) degrees, of the linearly polarized light of about 15 degrees, is substantially blocked by the wire grid polarizer 50 included in the fourth photoelectric conversion element 11B₄.
Amount of light based on the linearly polarized light of about 15 degrees: 0
Amount of light based on the left-handed circularly polarized light: AL_{CP}

In the quarter wavelength layer 60 included in the fifth photoelectric conversion element 11B₅, the fast axis orientation β with respect to the second direction is 45 degrees. Further, an angle formed between the linearly polarized light of about 15 degrees and the fast axis orientation p is about 120 degrees. Accordingly, the quarter wavelength layer 60 outputs left-handed circularly polarized light on the basis of entry of the linearly polarized light of about 15 degrees (see the left figure in FIG. 16A). In addition, because the polarization orientation α′ of the wire grid polarizer 50 included in the fifth photoelectric conversion element 11B₅ is 0 degrees, the wire grid polarizer 50 passes light (amount of light: AL_{CP}) of about (¼) of the outputted left-handed circularly polarized light (see the right figure in FIG. 16A).

Further, the quarter wavelength layer 60 included in the fifth photoelectric conversion element 11B₅ outputs linearly polarized light inclined at 45 degrees with respect to the fast axis orientation (linearly polarized light parallel to the first direction) on the basis of entry of left-handed circularly polarized light (see the left figure in FIG. 16B). In addition, because the polarization orientation α′ of the wire grid polarizer 50 included in the fifth photoelectric conversion element 11B₅ is 0 degrees, the wire grid polarizer 50 blocks the outputted linearly polarized light (see the right figure in FIG. 16B).
Amounts of light obtainable by the photoelectric conversion section of the fifth photoelectric conversion element 11B₅ are as follows.
Amount of light based on the linearly polarized light of about 15 degrees: AL_{LP′}
Amount of light based on the left-handed circularly polarized light: 0

In the quarter wavelength layer 60 included in the sixth photoelectric conversion element 11B₆, the fast axis orientation (β+90) with respect to the second direction is 135 degrees. Further, the angle formed between the linearly polarized light of about 15 degrees and the fast axis orientation β is about 30 degrees. Accordingly, the quarter wavelength layer 60 outputs right-handed circularly polarized light on the basis of entry of the linearly polarized light of about 15 degrees (see the left figure in FIG. 16C). In addition, because the polarization orientation α′ of the wire grid polarizer 50 included in the sixth photoelectric conversion element 11B₆ is 0 degrees, the wire grid polarizer 50 passes light (amount of light: AL_{LP′}) of about (¼) of the outputted right-handed circularly polarized light (see the right figure in FIG. 16C).

Further, the quarter wavelength layer 60 included in the sixth photoelectric conversion element 11B₆ outputs linearly polarized light inclined at 45 degrees with respect to the fast axis orientation (linearly polarized light parallel to the second direction) on the basis of entry of left-handed circularly polarized light (see the left figure in FIG. 16D). In addition, because the polarization orientation α′ of the wire grid polarizer 50 included in the sixth photoelectric conversion element 11B₆ is 0 degrees, the wire grid polarizer 50 passes the outputted linearly polarized light (amount of light: AL_{CP′}) (see the right figure in FIG. 16D).

Amounts of light obtainable by the photoelectric conversion section of the sixth photoelectric conversion element 11B₆ are as follows.
Amount of light based on the linearly polarized light of about 15 degrees: AL_{LP′}
Amount of light based on the left-handed circularly polarized light: AL_{CP′}

Also in case where right-handed circularly polarized light enters the quarter wavelength layers included in the fifth photoelectric conversion element 11B₅ and the sixth photoelectric conversion element 11B₆, the following results are obtainable (see FIGS. 17A, 17B, 17C, and 17D) on the basis of similar discussions. That is, amounts of light obtainable by the photoelectric conversion section of the fifth photoelectric conversion element 11B₅ are as follows.
Amount of light based on the linearly polarized light of about 15 degrees: AL_{LP′}
Amount of light based on the right-handed circularly polarized light: AL_{CP′}

Further, amounts of light obtainable by the photoelectric conversion section of the sixth photoelectric conversion element 11B₆ are as follows.
Amount of light based on the linearly polarized light of about 15 degrees: AL_{LP′}
Amount of light based on the right-handed circularly polarized light: 0

In this way, it is possible to find whether the circularly polarized light component is large or small in amount and whether the right-handed circularly polarized light component is large in amount or the left-handed circularly polarized light component is large in amount, on the basis of the fifth photoelectric conversion element 11B₅ and the sixth photoelectric conversion element 11B₆.

The above-described situations are schematically illustrated in FIG. 18.

Moreover, the light receiving device of Example 2 further includes a data processor. Where:
the amount of light (light intensity) obtainable by the photoelectric conversion section 21 included in the first photoelectric conversion element 11B₁ is denoted by AL₁;
the amount of light (light intensity) obtainable by the photoelectric conversion section 21 included in the second photoelectric conversion element 11B₂ is denoted by AL₂;
the amount of light (light intensity) obtainable by the photoelectric conversion section 21 included in the third photoelectric conversion element 11B₃ is denoted by AL₃;
the amount of light (light intensity) obtainable by the photoelectric conversion section 21 included in the fourth photoelectric conversion element 11B₄ is denoted by AL₄;
the amount of light (light intensity) obtainable by the photoelectric conversion section 21 included in the fifth photoelectric conversion element 11B₅ is denoted by AL₅; and
the amount of light (light intensity) obtainable by the photoelectric conversion section 21 included in the sixth photoelectric conversion element 11B₆ is denoted by AL₆,
the data processor
   determines ΔAL′=AL₅−AL₆ in a case where AL₅≥AL₆, and
   determines ΔAL′=AL₆−AL₅ in a case where AL₅<AL₆, and
the data processor further determines α degree of polarization from a difference ΔAL between a maximum value and a minimum value of a fitting curve obtainable on the basis of the amounts of light (light intensities) AL₁, AL₂, AL₃, and AL₄, and from ΔAL′. Specifically, the degree of polarization is determined by:

degree of polarization=ΔAL/(ΔAL+ΔAL′).

Moreover, the data processor displays, of obtained image data, a region where the degree of polarization is high and a region where the degree of polarization is low in different colors.

FIGS. 20A and 20B schematically illustrate the amount of light (light intensity) obtainable at the photoelectric conversion section of each photoelectric conversion element when light including a linearly polarized light component in a certain direction and light including a circularly polarized light component enter, in a mixed state, an existing photoelectric conversion element unit including four existing photoelectric conversion elements: a first photoelectric conversion element Q1; a second photoelectric conversion element Q2; a third photoelectric conversion element Q3; and a fourth photoelectric conversion element Q4. From FIGS. 20A and 20B, it is seen that the linearly polarized light in a polarization orientation of about 30 degrees is present in a large amount. In an example illustrated in FIG. 20A, ΔAL is large in value, ΔAL″ is small in value, and

the degree of polarization=ΔAL/(ΔAL+ΔAL″)
has a large value close to “1”. It can thus be said that the degree of polarization is high. In contrast, in an example illustrated in FIG. 20B, ΔAL is small in value, ΔAL″ is large in value, and

the degree of polarization=ΔAL/(ΔAL+ΔAL″)
has a small value. It can thus be said that the degree of polarization is low. ΔAL″ represents a value resulting from subtracting a reference amount of light (light intensity) from the minimum value of the fitting curve. In FIGS. 20A and 20B, the first photoelectric conversion element Q1 is an existing photoelectric conversion element in which the polarization orientation targeted for transmission by the wire grid polarizer is 0 degrees, the second photoelectric conversion element Q2 is an existing photoelectric conversion element in which the polarization orientation targeted for transmission by the wire grid polarizer is 45 degrees, the third photoelectric conversion element Q3 is an existing photoelectric conversion element in which the polarization orientation targeted for transmission by the wire grid polarizer is 90 degrees, and the fourth photoelectric conversion element Q4 is an existing photoelectric conversion element in which the polarization orientation targeted for transmission by the wire grid polarizer is 135 degrees.

The amounts of received light (light intensities) at the photoelectric conversion elements 11B₁, 11B₂, 11B₃, 11B₄, 11B₅, and 11B₆ in the light receiving device of Example 2 described above are summarized as follows.

### First Photoelectric Conversion Element 11B₁

Amount of light based on the linearly polarized light of about 15 degrees: AL₁₋₁

Amount of light based on the left-handed circularly polarized light: AL_{CP}

### Second Photoelectric Conversion Element 11B₂

Amount of light based on the linearly polarized light of about 15 degrees: AL₁₋₂

Amount of light based on the left-handed circularly polarized light: AL_{CP}

### Third Photoelectric Conversion Element 11B₃

Amount of light based on the linearly polarized light of about 15 degrees: 0

Amount of light based on the left-handed circularly polarized light: AL_{CP}

### Fourth Photoelectric Conversion Element 11B₄

Amount of light based on the linearly polarized light of about 15 degrees: 0

Amount of light based on the left-handed circularly polarized light: AL_{CP}

### Fifth Photoelectric Conversion Element 11B₅

Amount of light based on the linearly polarized light of about 15 degrees: AL_{LP′}

Amount of light based on the left-handed circularly polarized light: 0.

### Sixth Photoelectric Conversion Element 11B₆

Amount of light based on the linearly polarized light of about 15 degrees: AL_{LP′}

Amount of light based on the left-handed circularly polarized light: AL_{CP′}

Here, because AL₅<AL₆,

ΔAL′=AL₆−AL₅=AL_{CP}′.

In addition,

AL_{CP}≈AL_{CP′}/4.

Therefore, by subtracting (ΔAL′/4) from the respective amounts of light received by the first photoelectric conversion elements 11B₁, 11B₂, 11B₃, and 11B₄, it is possible to determine the respective amounts of light AL_{LP-1}, AL_{LP-2}, AL_{LP-3}, and AL_{LP-4} of the linearly polarized light received by the first photoelectric conversion elements 11B₁, 11B₂, 11B₃, and 11B₄. That is, according to the light receiving device of Example 2, it is possible to separate the linearly polarized light component and the circularly polarized light component from each other.

In addition, on the basis of the respective amounts of light AL₁, AL₂, AL₃, and AL₄ (specifically, the amounts of light AL_{LP-1}, AL_{LP-2}, AL_{LP-3}, and AL_{LP-4} of the linearly polarized light) received by the first photoelectric conversion elements 11B₁, 11B₂, 11B₃, and 11B₄ determined in such a manner, it is possible to determine, as described above,

the degree of polarization=ΔAL/(ΔAL+ΔAL′),

and moreover, an image may be displayed on the basis of these amounts of light. An image obtained on the basis of the first photoelectric conversion element 11B₁ in each photoelectric conversion element unit is presented as “0°” in FIG. 19A, an image obtained on the basis of the second photoelectric conversion element 11B₂ is presented as “45°” in FIG. 19A, an image obtained on the basis of the third photoelectric conversion element 11B₃ is presented as “90°” in FIG. 19A, and an image obtained on the basis of the fourth photoelectric conversion element 11B₄ is presented as “135°” in FIG. 19A.

In these images, regions where the amounts of light AL_{LP-1}, AL_{LP-2}, AL_{LP-3}, and AL_{LP-4} are large are indicated in a “light” color. Such regions are high in the degree of polarization. In contrast, regions where the amounts of light AL_{LP-1}, AL_{LP-2}, AL_{LP-3}, and AL_{LP-4} are small are indicated in a “dark” color. Such regions are low in the degree of polarization. In addition, an image resulting from combining the four images of FIG. 19A is presented in FIG. 19B. A region where the degree of polarization is high is easily identifiable as a region where no polarization information has been acquired (a region lacking in polarization information), because of so-called “clipped whites”. It is to be noted that such a region where no polarization information has been acquired is a region where output from the photoelectric conversion element is excessively high, that is, a region where the photoelectric conversion section included in the photoelectric conversion element is saturated with respect to inputted light.

According to the light receiving device of Example 2, it is possible to color and thereby display such a region where no polarization information has been acquired. This makes it possible to appropriately obtain polarization information from regions other than such a region where no polarization information has been acquired (a region lacking in polarization information). That is, according to the light receiving device of Example 2, it is possible to easily know the so-called degree of polarization, and a person who views the image is able to easily identify a region in the image where no polarization information has been acquired. In addition, by using the circularly polarized light component in calculating the degree of polarization, it is possible to achieve improvement in substantial resolution of the entire image. Moreover, by performing desired processing on, for example, a portion of a captured image of the sky or a window pane, a portion of a captured image of a water surface, or the like, it is possible to emphasize or reduce the polarized light component or to separate various polarized light components from each other. It is thus possible to improve image contrast and delete unwanted information.

In the light receiving device of Example 2, all the photoelectric conversion element units are constituted by the photoelectric conversion element units-2A of the foregoing case (2-1). It is to be noted that in this case, the photoelectric conversion elements in the photoelectric conversion element unit-2A may have the same configuration and structure. Alternatively, the light receiving device of Example 2 may be in any of the embodiments of the foregoing cases (2-2) to (2-10).

In addition, a modification example of the light receiving device of Example 2 may include a plurality of photoelectric conversion element unit groups that is two-dimensionally arranged, and may have a configuration in which
one photoelectric conversion element unit group includes four photoelectric conversion element units disposed 2×2,
a first photoelectric conversion element unit includes a first filter layer that passes light in a first wavelength range,
a second photoelectric conversion element unit includes a second filter layer that passes light in a second wavelength range,
a third photoelectric conversion element unit includes a third filter layer that passes light in a third wavelength range, and
a fourth photoelectric conversion element unit includes a fourth filter layer that passes light in a fourth wavelength range. In addition, in this case, it is sufficient that the quarter wavelength layer and the wire grid polarizer in each of the photoelectric conversion elements included in the first photoelectric conversion element unit, the second photoelectric conversion element unit, the third photoelectric conversion element unit, and the fourth photoelectric conversion element unit are optimized in specification in accordance with the wavelength of inputted light, as described above. FIG. 21 illustrates a schematic partial cross-sectional view of an example of such a modification example of the light receiving device of Example 2, in which a filter layer 71 is provided above the quarter wavelength layer 60. One photoelectric conversion element unit group constitutes one pixel (a pixel), and the four photoelectric conversion element units disposed 2×2 constitute one sub-pixel (a sub-pixel). Such a configuration makes it possible to display a color image.

Specifically, one photoelectric conversion element unit group includes four photoelectric conversion element units disposed in the Bayer arrangement, for example. The light in the first wavelength range may be red light, the light in the second wavelength range and the light in the third wavelength range may be green light, and the light in the fourth wavelength range may be blue light. Alternatively, the light in the first wavelength range may be red light, the light in the second wavelength range may be green light, the light in the third wavelength range may be blue light, and the light in the fourth wavelength range may be infrared light. In this case, the fourth photoelectric conversion element unit may have a configuration including a fourth filter layer that passes none of the light in the first wavelength range, the light in the second wavelength range, and the light in the third wavelength range. Alternatively, the arrangement of the photoelectric conversion element units may include various kinds of arrangements described above. In addition, a configuration may be adopted in which
a first quarter wavelength layer included in the first photoelectric conversion element unit gives a phase difference to the light in the first wavelength range,
a second quarter wavelength layer included in the second photoelectric conversion element unit gives a phase difference to the light in the second wavelength range,
a third quarter wavelength layer included in the third photoelectric conversion element unit gives a phase difference to the light in the third wavelength range, and
a fourth quarter wavelength layer included in the fourth photoelectric conversion element unit gives a phase difference to the light in the fourth wavelength range.

In addition, in the modification example of the light receiving device of Example 2, the first quarter wavelength layer, the second quarter wavelength layer and the third quarter wavelength layer, and the fourth quarter wavelength layer are disposed in the same layer. Moreover,
the quarter wavelength layer 60 includes the first dielectric layer 61 including a material having the refractive index n₁ and the second dielectric layer 62 including a material having the refractive index n₂ (where n₁>n₂) that are alternately disposed side by side,
the thicknesses (t₁₁, t₁₂) of the first dielectric layer 61 and the second dielectric layer 62 included in the first quarter wavelength layer, the thicknesses (t₂₁, t₂₂) of the first dielectric layer 61 and the second dielectric layer 62 included in the second quarter wavelength layer, the thicknesses (t₃₁, t₃₂) of the first dielectric layer 61 and the second dielectric layer 62 included in the third quarter wavelength layer, and the thicknesses (t₄₁, t₄₂) of the first dielectric layer 61 and the second dielectric layer 62 included in the fourth quarter wavelength layer are different, that is, t₁₁, t₂₁, t₃₁, and t₄₁ are not the same in value, and t₁₂, t₂₂, t₃₂, and t₄₂ are not the same in value, and
the first quarter wavelength layer, the second quarter wavelength layer, the third quarter wavelength layer, and the fourth quarter wavelength layer have the same layer thickness (H₁=H₂=H₃=H₄).

In Example 2, as described above, one photoelectric conversion element unit group includes four photoelectric conversion element units disposed in the Bayer arrangement, for example. Therefore, t₂₁=t₃₁, and t₂₂=t₃₂. Further, H₁=H₂=H₃=H₄=115 nm.

Regarding the first quarter wavelength layer,
t₁₁=210 nm,
t₁₂=90 nm,
f=210/(210+90)=0.7,
n_{TE}=1.86,
n_{TM}=0.56,
and a wavelength λ₁ of light that passes through the first quarter wavelength layer and is given a phase difference is as follows:
λ₁=600 nm.

Further, regarding the second quarter wavelength layer and the third wavelength layer,
t₂₁=t₃₁=150 nm,
t₂₂=t₃₂=150 nm,
f=150/(150+150)=0.5,
n_{TE}=1.77,
n_{TM}=0.59,
and a wavelength λ₂₋₃ of light that passes through the second quarter wavelength layer and the third quarter wavelength layer and is given a phase difference is as follows:
λ₂₋₃=550 nm.

Moreover, regarding the fourth quarter wavelength layer,
t₄₁=60 nm,
t₄₂=240 nm,
f=60/(60+240)=0.2,
n_{TE}=1.61,
n_{TM}=0.64,
and a wavelength λ₄ of light that passes through the fourth quarter wavelength layer and is given a phase difference is as follows:
λ₄=450 nm.

Alternatively, in the modification example of the light receiving device of Example 2, the first quarter wavelength layer, the second quarter wavelength layer, the third quarter wavelength layer, and the fourth quarter wavelength layer are disposed in different layers. In addition, a configuration may be adopted in which
the quarter wavelength layer 60 includes the first dielectric layer 61 including a material having a refractive index n₁ and the second dielectric layer 62 including a material having a refractive index n₂ (where n₁>n₂) that are alternately disposed side by side,
the thicknesses (t₁₁, t₁₂) of the first dielectric layer 61 and the second dielectric layer 62 included in the first quarter wavelength layer, the thicknesses (t₂₁, t₂₂) of the first dielectric layer 61 and the second dielectric layer 62 included in the second quarter wavelength layer, the thicknesses (t₃₁, t₃₂) of the first dielectric layer 61 and the second dielectric layer 62 included in the third quarter wavelength layer, and the thicknesses (t₄₁, t₄₂) of the first dielectric layer 61 and the second dielectric layer 62 included in the fourth quarter wavelength layer are the same, that is, t₁₁=t₂₁=t₃₁=t₄₁ and t₁₂=t₂₂=t₃₂=t₄₂, and
the first quarter wavelength layer, the second quarter wavelength layer, the third quarter wavelength layer, and the fourth quarter wavelength layer have different layer thicknesses.

Note that because one photoelectric conversion element unit group includes, for example, four photoelectric conversion element units disposed in the Bayer arrangement, H₂=H₃. The first quarter wavelength layer occupies, for example, a first layer, the second quarter wavelength layer and the third quarter wavelength layer occupy, for example, a second layer, and the fourth quarter wavelength layer occupies, for example, a third layer; however, such a state is non-limiting, and the order of the layer occupied by the first quarter wavelength layer, the layer occupied by the second quarter wavelength layer and the third wavelength layer, and the layer occupied by the fourth wavelength layer may substantially be any order.

Here,
t₁₁=t₂₁=t₃₁=t₄₁=150 nm, and
t₁₂=t₂₂=t₃₂=t₄₂=150 nm.

In addition, regarding the first quarter wavelength layer, if:
f=150/(150+150)=0.5,
n_{TE}=1.77, and
n_{TM}=0.59,
and if H=125 nm,
then the wavelength λ₁ of the light that passes through the first quarter wavelength layer and is given a phase difference is as follows:
λ₁=600 nm.

Further, regarding the second quarter wavelength layer and the third wavelength layer, if:
f=150/(150+150)=0.5,
n_{TE}=1.77, and
n_{TM}=0.59,
and if H=115 nm,
then the wavelength λ₂₃₋₃ of the light that passes through the second quarter wavelength layer and the third quarter wavelength layer and is given a phase difference is as follows:
λ₂₋₃=550 nm.

Moreover, regarding the fourth quarter wavelength layer, if:
f=1501(150+150)=0.5,
n_{TE}=1.77, and
n_{TM}=0.59,
and if H=95 nm,
then the wavelength λ₄ of the light that passes through the fourth quarter wavelength layer and is given a phase difference is as follows:
λ₄=450 nm.

The description of the modification example of the light receiving device of Example 2 above also applies to a light receiving device of Example 3.

### EXAMPLE 3

Example 3 relates to the light receiving device according to the third aspect of the present disclosure. FIG. 22 illustrates a schematic partial cross-sectional view of a portion of the photoelectric conversion element unit in the light receiving device of Example 3. In addition, FIGS. 23A, 24A, 25A, and 26A each illustrate a polarized state of light passing through the first quarter wavelength layer (which is referred to as “λ/4 phase plate of first layer”, and the same applies hereinafter) included in the photoelectric conversion element unit in the light receiving device of Example 3. FIGS. 23B, 24B, 25B, and 26B each illustrate a polarized state of the light passing through the second quarter wavelength layer (which is referred to as “λ/4 phase plate of second layer”, and the same applies hereinafter). FIGS. 23C, 24C, 25C, and 26C each schematically illustrate a state of the light passing through the wire grid polarizer (which is referred to as “WGP”, and the same applies hereinafter).

The light receiving device of Example 3 includes a plurality of photoelectric conversion element units 10C.

Each of the photoelectric conversion element units 10C includes a first photoelectric conversion element 11C₁, a second photoelectric conversion element 11C₂, a third photoelectric conversion element 11C₃, and a fourth photoelectric conversion element 11C₄,
the first photoelectric conversion element 11C₁, the second photoelectric conversion element 11C₂, the third photoelectric conversion element 11C₃, and the fourth photoelectric conversion element 11C₄ each include a first quarter wavelength layer 60A, a second quarter wavelength layer 60B, the wire grid polarizer 50, and the photoelectric conversion section 21 that are disposed in this order from the light entrance side,
a polarization orientation targeted for transmission by the wire grid polarizer 50 included in the first photoelectric conversion element 11C₁ is α degrees,
a polarization orientation targeted for transmission by the wire grid polarizer 50 included in the second photoelectric conversion element 11C₂ is (α+45) degrees,
a polarization orientation targeted for transmission by the wire grid polarizer 50 included in the third photoelectric conversion element 11C₃ is (α+90) degrees,
a polarization orientation targeted for transmission by the wire grid polarizer 50 included in the fourth photoelectric conversion element 11C₄ is (α+135) degrees,
a fast axis orientation of the first quarter wavelength layer 60A included in the first photoelectric conversion element 11C₁ is β degrees,
a fast axis orientation of the first quarter wavelength layer 60A included in the second photoelectric conversion element 11C₂ is (β+45) degrees,
a fast axis orientation of the first quarter wavelength layer 60A included in the third photoelectric conversion element 11C₃ is (β+90) degrees,
a fast axis orientation of the first quarter wavelength layer 60A included in the fourth photoelectric conversion element 11C₄ is (β+135) degrees, and
in each of the photoelectric conversion elements, an angle formed between a fast axis orientation of the second quarter wavelength layer 60B and the fast axis orientation of the first quarter wavelength layer 60A is ±45 degrees.

In addition, one photoelectric conversion element unit 10C constitutes one pixel (a pixel). The light receiving device of Example 3 displays a monochromatic image. It is to be noted that, as described in the modification example of the light receiving device of Example 2, the modification example of the light receiving device of Example 2 is applicable to the light receiving device of Example 3. In this case, one photoelectric conversion element unit group constitutes one pixel (a pixel), and the four photoelectric conversion element units disposed 2×2 constitute one sub-pixel (a sub-pixel). Such a configuration makes it possible to display a color image.

Here, although not limited thereto, α=β may be satisfied. An angle formed between α and the second direction may substantially be any angle, and examples of the angle may include 0 degrees and 90 degrees. In Example 3, α=0 degrees. That is, an angle formed between α and the Q direction is set to 0 degrees, and an angle formed between α and the P direction is set to 90 degrees. In addition, an angle formed between R and the second direction may substantially be any angle, and examples of the angle may include 0 degrees and 90 degrees. In Example 3, β=0 degrees. That is, the angle formed between R and the second direction is set to 0 degrees.

In the following, a description is given first of a state when, in the photoelectric conversion element unit in the light receiving device of Example 3, linearly polarized light that is polarized in the second direction enters the first quarter wavelength layer 60A from above in the direction perpendicular to the sheet plane of FIG. 23A and passes through the wire grid polarizer 50. Here, FIG. 23A illustrates a polarized state of the light passing through the first quarter wavelength layer 60A, FIG. 23B illustrates a polarized state of the light passing through the second quarter wavelength layer 60B, and FIG. 23C schematically illustrates a state of the light having passed through the wire grid polarizer 50.

In the first photoelectric conversion element 11C₁ located in the second quadrant of FIGS. 23A, 23B, and 23C, the linearly polarized light having entered the first quarter wavelength layer 60A is outputted from the first quarter wavelength layer 60A in a state of the linearly polarized light polarized in the second direction, because an angle formed with the fast axis of the first quarter wavelength layer 60A is 0 degrees. Then, the linearly polarized light having entered the second quarter wavelength layer 60B is outputted from the second quarter wavelength layer 60B in a state of left-handed circularly polarized light, because an angle formed with the fast axis of the second quarter wavelength layer 60B is 135 degrees. Then, a portion of the left-handed circularly polarized light having entered the wire grid polarizer 50 passes through the wire grid polarizer 50. It is to be noted that the remainder of the left-handed circularly polarized light having entered the wire grid polarizer 50 is unable to pass through the wire grid polarizer 50. Such a passing state of light is indicated with a “solid black triangle” mark (▴).

In the second photoelectric conversion element 11C₂ located in the first quadrant of FIGS. 23A, 23B, and 23C, the linearly polarized light having entered the first quarter wavelength layer 60A is outputted from the first quarter wavelength layer 60A in a state of left-handed circularly polarized light, because an angle formed with the fast axis of the first quarter wavelength layer 60A is 135 degrees. Then, the left-handed circularly polarized light having entered the second quarter wavelength layer 60B is outputted from the second quarter wavelength layer 60B in a state of linearly polarized light forming an angle of 45 degrees with the fast axis (forming an angle of 135 degrees with the second direction). Then, the linearly polarized light having entered the wire grid polarizer 50 is unable to pass through the wire grid polarizer 50. It is to be noted that such a passing state of light is indicated with a “cross” mark (×).

In the third photoelectric conversion element 11C₃ located in the fourth quadrant of FIGS. 23A, 23B, and 23C, the linearly polarized light having entered the first quarter wavelength layer 60A is outputted from the first quarter wavelength layer 60A in a state of the linearly polarized light polarized in the second direction, because an angle formed with the fast axis of the first quarter wavelength layer 60A is 90 degrees. Then, the linearly polarized light having entered the second quarter wavelength layer 60B is outputted from the second quarter wavelength layer 60B in a state of right-handed circularly polarized light, because an angle formed with the fast axis of the second quarter wavelength layer 60B is 45 degrees. Then, a portion of the right-handed circularly polarized light having entered the wire grid polarizer 50 passes through the wire grid polarizer 50.

In the fourth photoelectric conversion element 11C₄ located in the third quadrant of FIGS. 23A, 23B, and 23C, the linearly polarized light having entered the first quarter wavelength layer 60A is outputted from the first quarter wavelength layer 60A in a state of right-handed circularly polarized light, because an angle formed with the fast axis of the first quarter wavelength layer 60A is 45 degrees. Then, the right-handed circularly polarized light having entered the second quarter wavelength layer 60B is outputted from the second quarter wavelength layer 60B in a state of linearly polarized light forming an angle of 135 degrees with the fast axis (forming an angle of 135 degrees with the second direction). Then, the linearly polarized light having entered the wire grid polarizer 50 passes through the wire grid polarizer 50. It is to be noted that such a passing state of light is indicated with an “open white circle” mark (∘).

As has been described, when the linearly polarized light that is polarized in the second direction enters the first quarter wavelength layer 60A from above in the direction perpendicular to the sheet plane of FIG. 23A, the passing states of the light through the wire grid polarizers are as follows.
Wire grid polarizer in the first photoelectric conversion element located in the second quadrant: ▴.
Wire grid polarizer in the second photoelectric conversion element located in the first quadrant: ×
Wire grid polarizer in the third photoelectric conversion element located in the fourth quadrant: ▴
Wire grid polarizer in the fourth photoelectric conversion element located in the third quadrant: ∘

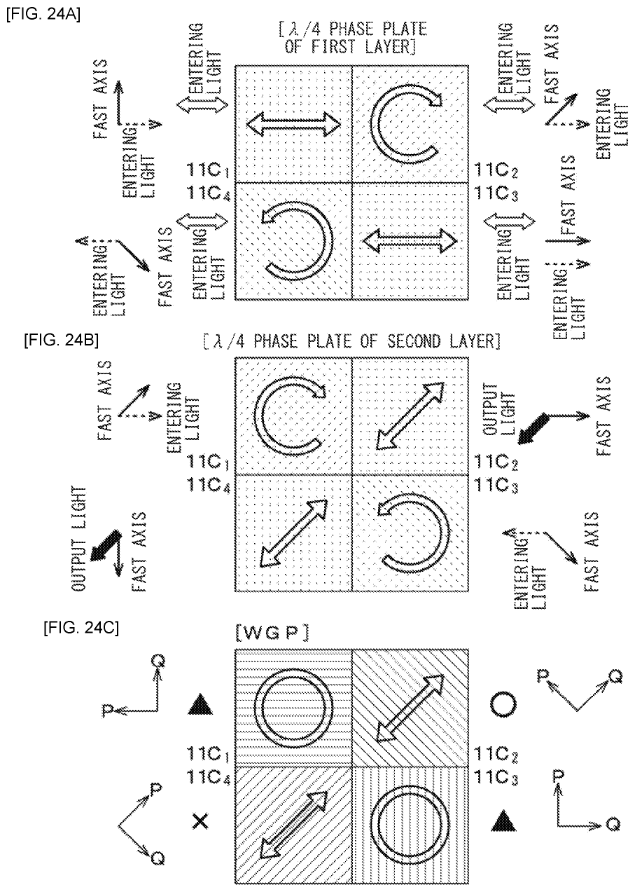

Next, a description is given of a state when, in the photoelectric conversion element unit in the light receiving device of Example 3, linearly polarized light that is polarized in the first direction enters the first quarter wavelength layer 60A from above in a direction perpendicular to the sheet plane of FIG. 24A and passes through the wire grid polarizer 50. Here, FIG. 24A illustrates a polarized state of the light passing through the first quarter wavelength layer 60A, FIG. 24B illustrates a polarized state of the light passing through the second quarter wavelength layer 60B, and FIG. 24C schematically illustrates a state of the light having passed through the wire grid polarizer 50.

In the first photoelectric conversion element 11C₁ located in the second quadrant of FIGS. 24A, 24B, and 24C, the linearly polarized light having entered the first quarter wavelength layer 60A is outputted from the first quarter wavelength layer 60A in a state of the linearly polarized light polarized in the first direction, because an angle formed with the fast axis of the first quarter wavelength layer 60A is 90 degrees. Then, the linearly polarized light having entered the second quarter wavelength layer 60B is outputted from the second quarter wavelength layer 60B in a state of right-handed circularly polarized light, because an angle formed with the fast axis of the second quarter wavelength layer 60B is 45 degrees. Then, a portion of the right-handed circularly polarized light having entered the wire grid polarizer 50 passes through the wire grid polarizer 50.

In the second photoelectric conversion element 11C₂ located in the first quadrant of FIGS. 24A, 24B, and 24C, the linearly polarized light having entered the first quarter wavelength layer 60A is outputted from the first quarter wavelength layer 60A in a state of right-handed circularly polarized light, because an angle formed with the fast axis of the first quarter wavelength layer 60A is 45 degrees. Then, the right-handed circularly polarized light having entered the second quarter wavelength layer 60B is outputted from the second quarter wavelength layer 60B in a state of linearly polarized light forming an angle of 135 degrees with the fast axis (forming an angle of 45 degrees with the second direction). Then, the linearly polarized light having entered the wire grid polarizer 50 passes through the wire grid polarizer 50.

In the third photoelectric conversion element 11C₃ located in the fourth quadrant of FIGS. 24A, 24B, and 24C, the linearly polarized light having entered the first quarter wavelength layer 60A is outputted from the first quarter wavelength layer 60A in a state of linearly polarized light polarized in the first direction, because an angle formed with the fast axis of the first quarter wavelength layer 60A is 0 degrees. Then, the linearly polarized light having entered the second quarter wavelength layer 60B is outputted from the second quarter wavelength layer 60B in a state of left-handed circularly polarized light, because an angle formed with the fast axis of the second quarter wavelength layer 60B is 135 degrees. Then, a portion of the left-handed circularly polarized light having entered the wire grid polarizer 50 passes through the wire grid polarizer 50.

In the fourth photoelectric conversion element 11C₄ located in the third quadrant of FIGS. 24A, 24B, and 24C, the linearly polarized light having entered the first quarter wavelength layer 60A is outputted from the first quarter wavelength layer 60A in a state of left-handed circularly polarized light, because an angle formed with the fast axis of the first quarter wavelength layer 60A is 135 degrees. Then, the left-handed circularly polarized light having entered the second quarter wavelength layer 60B is outputted from the second quarter wavelength layer 60B in a state of linearly polarized light forming an angle of 45 degrees with the fast axis (forming an angle of 45 degrees with the second direction). Then, the linearly polarized light having entered the wire grid polarizer 50 is unable to pass through the wire grid polarizer 50.

As has been described, when the linearly polarized light that is polarized in the first direction enters the first quarter wavelength layer 60A from above in the direction perpendicular to the sheet plane of FIG. 24A, the passing states of the light through the wire grid polarizers are as follows.
Wire grid polarizer in the first photoelectric conversion element located in the second quadrant: ▴
Wire grid polarizer in the second photoelectric conversion element located in the first quadrant: ∘
Wire grid polarizer in the third photoelectric conversion element located in the fourth quadrant: ▴
Wire grid polarizer in the fourth photoelectric conversion element located in the third quadrant: ×

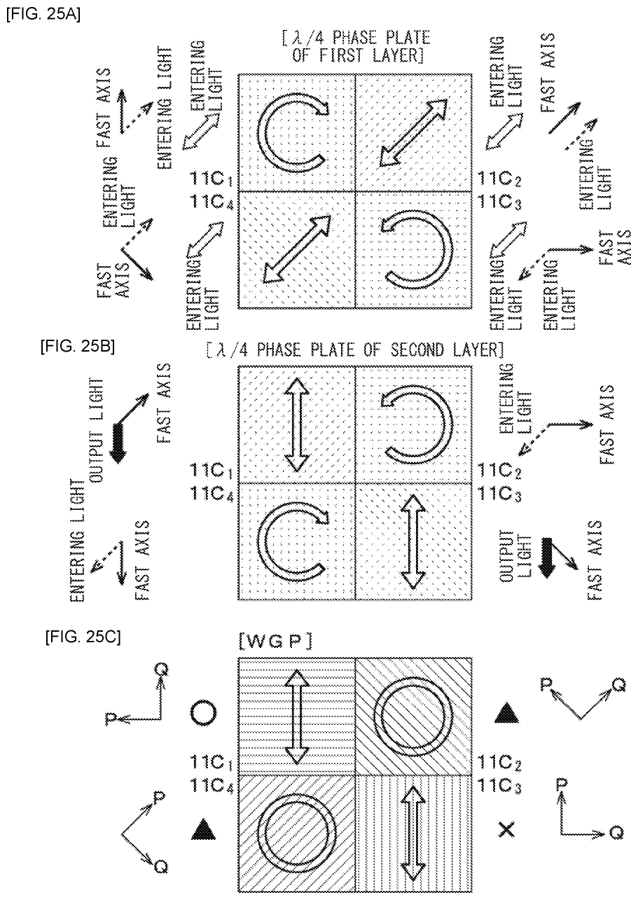

Next, a description is given of a state when, in the photoelectric conversion element unit in the light receiving device of Example 3, linearly polarized light that is polarized at −45 degrees with respect to the first direction enters the first quarter wavelength layer 60A from above in a direction perpendicular to the sheet plane of FIG. 25A and passes through the wire grid polarizer 50. Here, FIG. 25A illustrates a polarized state of the light passing through the first quarter wavelength layer 60A, FIG. 25B illustrates a polarized state of the light passing through the second quarter wavelength layer 60B, and FIG. 25C schematically illustrates a state of the light having passed through the wire grid polarizer 50.

In the first photoelectric conversion element 11C₁ located in the second quadrant of FIGS. 25A, 25B, and 25C, the linearly polarized light having entered the first quarter wavelength layer 60A is outputted from the first quarter wavelength layer 60A in a state of right-handed circularly polarized light, because an angle formed with the fast axis of the first quarter wavelength layer 60A is 45 degrees. Then, the right-handed circularly polarized light having entered the second quarter wavelength layer 60B is outputted from the second quarter wavelength layer 60B in a state of linearly polarized light forming an angle of 135 degrees with the fast axis (forming an angle of 0 degrees with the second direction). Then, the linearly polarized light having entered the wire grid polarizer 50 passes through the wire grid polarizer 50.

In the second photoelectric conversion element 11C₂ located in the first quadrant of FIGS. 25A, 25B, and 25C, the linearly polarized light having entered the first quarter wavelength layer 60A is outputted from the first quarter wavelength layer 60A in a state of the linearly-polarized light, because an angle formed with the fast axis of the first quarter wavelength layer 60A is 0 degrees. Then, the linearly polarized light having entered the second quarter wavelength layer 60B is outputted from the second quarter wavelength layer 60B in a state of left-handed circularly polarized light, because an angle formed with the fast axis of the second quarter wavelength layer 60B is 135 degrees. Then, a portion of the left-handed circularly polarized light having entered the wire grid polarizer 50 passes through the wire grid polarizer 50.

In the third photoelectric conversion element 11C₃ located in the fourth quadrant of FIGS. 25A, 25B, and 25C, the linearly polarized light having entered the first quarter wavelength layer 60A is outputted from the first quarter wavelength layer 60A in a state of left-handed circularly polarized light, because an angle formed with the fast axis of the first quarter wavelength layer 60A is 135 degrees. Then, the left-handed circularly polarized light having entered the second quarter wavelength layer 60B is outputted from the second quarter wavelength layer 60B in a state of linearly polarized light forming an angle of 45 degrees with the fast axis (forming an angle of 0 degrees with the second direction). Then, the linearly polarized light having entered the wire grid polarizer 50 is unable to pass through the wire grid polarizer 50.

In the fourth photoelectric conversion element 11C₄ located in the third quadrant of FIGS. 25A, 25B, and 25C, the linearly polarized light having entered the first quarter wavelength layer 60A is outputted from the first quarter wavelength layer 60A in a state of the linearly polarized light, because an angle formed with the fast axis of the first quarter wavelength layer 60A is 90 degrees. Then, the linearly polarized light having entered the second quarter wavelength layer 60B is outputted from the second quarter wavelength layer 60B in a state of right-handed circularly polarized light, because an angle formed with the fast axis of the second quarter wavelength layer 60B is 45 degrees. Then, a portion of the right-handed circularly polarized light having entered the wire grid polarizer 50 passes through the wire grid polarizer 50.

As has been described, when the linearly polarized light that is polarized at −45 degrees with respect to the first direction enters the first quarter wavelength layer 60A from above in the direction perpendicular to the sheet plane of FIG. 25A, the passing states of the light through the wire grid polarizers are as follows.
Wire grid polarizer in the first photoelectric conversion element located in the second quadrant: ∘
Wire grid polarizer in the second photoelectric conversion element located in the first quadrant: ▴
Wire grid polarizer in the third photoelectric conversion element located in the fourth quadrant: ×
Wire grid polarizer in the fourth photoelectric conversion element located in the third quadrant: ▴

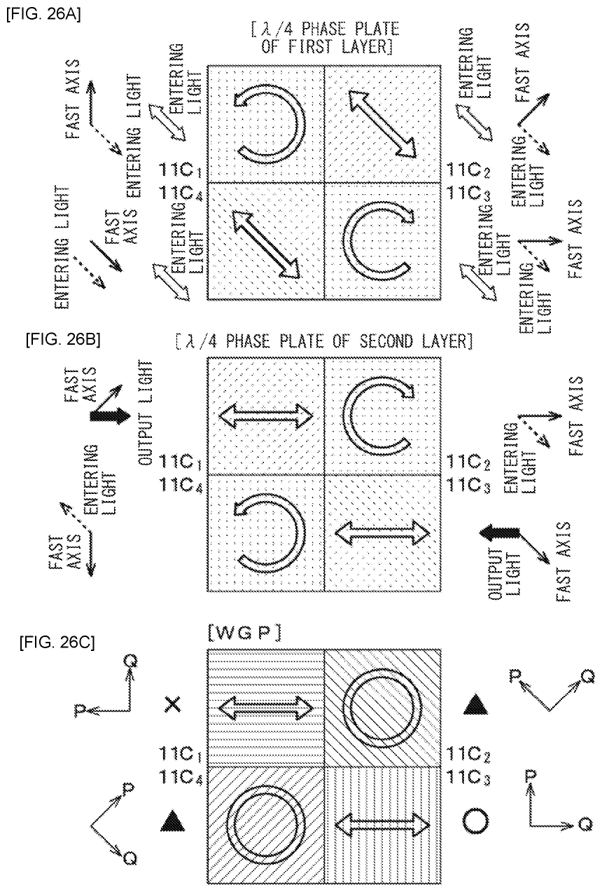

Next, a description is given of a state when, in the photoelectric conversion element unit in the light receiving device of Example 3, linearly polarized light that is polarized at +45 degrees with respect to the first direction enters the first quarter wavelength layer 60A from above in a direction perpendicular to the sheet plane of FIG. 26A and passes through the wire grid polarizer 50. Here, FIG. 26A illustrates a polarized state of the light passing through the first quarter wavelength layer 60A, FIG. 26B illustrates a polarized state of the light passing through the second quarter wavelength layer 60B, and FIG. 26C schematically illustrates a state of the light having passed through the wire grid polarizer 50.

In the first photoelectric conversion element 11C₁ located in the second quadrant of FIGS. 26A, 26B, and 26C, the linearly polarized light having entered the first quarter wavelength layer 60A is outputted from the first quarter wavelength layer 60A in a state of left-handed circularly polarized light, because an angle formed with the fast axis of the first quarter wavelength layer 60A is 135 degrees. Then, the left-handed circularly polarized light having entered the second quarter wavelength layer 60B is outputted from the second quarter wavelength layer 60B in a state of linearly polarized light forming an angle of 45 degrees with the fast axis (forming an angle of 90 degrees with the second direction). Then, the linearly polarized light having entered the wire grid polarizer 50 is unable to pass through the wire grid polarizer 50.

In the second photoelectric conversion element 11C₂ located in the first quadrant of FIGS. 26A, 26B, and 26C, the linearly polarized light having entered the first quarter wavelength layer 60A is outputted from the first quarter wavelength layer 60A in a state of the linearly-polarized light, because an angle formed with the fast axis of the first quarter wavelength layer 60A is 90 degrees. Then, the linearly polarized light having entered the second quarter wavelength layer 60B is outputted from the second quarter wavelength layer 60B in a state of right-handed circularly polarized light, because an angle formed with the fast axis of the second quarter wavelength layer 60B is 45 degrees. Then, a portion of the right-handed circularly polarized light having entered the wire grid polarizer 50 passes through the wire grid polarizer 50.

In the third photoelectric conversion element 11C₃ located in the fourth quadrant of FIGS. 26A, 26B, and 26C, the linearly polarized light having entered the first quarter wavelength layer 60A is outputted from the first quarter wavelength layer 60A in a state of right-handed circularly polarized light, because an angle formed with the fast axis of the first quarter wavelength layer 60A is 45 degrees. Then, the right-handed circularly polarized light having entered the second quarter wavelength layer 60B is outputted from the second quarter wavelength layer 60B in a state of linearly polarized light forming an angle of 135 degrees with the fast axis (forming an angle of 90 degrees with the second direction). Then, the linearly polarized light having entered the wire grid polarizer 50 passes through the wire grid polarizer 50.

In the fourth photoelectric conversion element 11C₄ located in the third quadrant of FIGS. 26A, 26B, and 26C, the linearly polarized light having entered the first quarter wavelength layer 60A is outputted from the first quarter wavelength layer 60A in a state of the linearly polarized light, because an angle formed with the fast axis of the first quarter wavelength layer 60A is 0 degrees. Then, the linearly polarized light having entered the second quarter wavelength layer 60B is outputted from the second quarter wavelength layer 60B in a state of left-handed circularly polarized light, because an angle formed with the fast axis of the second quarter wavelength layer 60B is 135 degrees. Then, a portion of the left-handed circularly polarized light having entered the wire grid polarizer 50 passes through the wire grid polarizer 50.

As has been described, when the linearly polarized light that is polarized at +45 degrees with respect to the first direction enters the first quarter wavelength layer 60A from above in the direction perpendicular to the sheet plane of FIG. 26A, the passing states of the light through the wire grid polarizers are as follows.
Wire grid polarizer in the first photoelectric conversion element located in the second quadrant: ×
Wire grid polarizer in the second photoelectric conversion element located in the first quadrant: ▴
Wire grid polarizer in the third photoelectric conversion element located in the fourth quadrant: ∘
Wire grid polarizer in the fourth photoelectric conversion element located in the third quadrant: ▴

The description has been given above of the passing states, through the wire grid polarizers, of the linearly polarized light polarized at −45 degrees, 0 degrees, +45 degrees, and +90 degrees with respect to the first direction, upon entering the first quarter wavelength layer 60A. When linearly polarized light that is polarized at “a certain angle” with respect to the first direction enters the first quarter wavelength layer 60A, the certain angle is determinable by analyzing the amounts of light (light intensities) received by the wire grid polarizer in the first photoelectric conversion element, the wire grid polarizer in the second photoelectric conversion element, the wire grid polarizer in the third photoelectric conversion element, and the fourth photoelectric conversion element.

As described above, according to the light receiving device of Example 3, it is possible to easily know the polarized state of light entering the photoelectric conversion element unit in the light receiving device by determining the amount of light (light intensity) received at each of the first photoelectric conversion element, the second photoelectric conversion element, the third photoelectric conversion element, and the fourth photoelectric conversion element. It is also possible to easily extract light having specific linear polarization on the basis of each of the first photoelectric conversion element, the second photoelectric conversion element, the third photoelectric conversion element, and the fourth photoelectric conversion element, and it is also possible to provide a function as a PL filter or a CPL filter.

In addition, according to any of the light receiving devices described in Examples 1 to 3, it is possible to obtain light intensity, polarized light component intensity, and polarization direction at each of the photoelectric conversion elements (imaging elements). Accordingly, it is possible to process image data on the basis of polarization information after imaging, for example. By performing desired processing on, for example, a portion of a captured image of the sky or a window pane, a portion of a captured image of a water surface, or the like, it is possible to emphasize or reduce the polarized light component or to separate various polarized light components from each other. It is thus possible to improve image contrast and delete unwanted information. It is to be noted that, specifically, such processing is achievable by defining an imaging mode in performing imaging with use of a solid-state imaging device, for example. Moreover, with use of the solid-state imaging device, it is possible to remove reflected glare on a window pane and to achieve sharpening of boundaries (outlines) of a plurality of objects by adding polarization information to image information. Alternatively, it is possible to detect a state of a road surface and to detect an obstacle on the road surface. Moreover, application to or practical use in various fields is possible, examples of which include imaging of patterns reflecting birefringence of an object, measurement of retardation distribution, acquisition of a polarizing microscopic image, acquisition of a surface shape of an object and measurement of surface properties of the object, detection of a moving body (a vehicle or the like), and weather observation such as measurement of cloud distribution or the like. Further, it is also possible to provide a solid-state imaging device for capturing a three-dimensional image.

Although the description has been given above of the present disclosure on the basis of preferred examples, the present disclosure is not limited to these examples. The structures and configurations, manufacturing methods, and materials used of the photoelectric conversion elements (light receiving elements and imaging elements), the light receiving devices, and the solid-state imaging devices described in Examples are merely illustrative, and are modifiable on an as-needed basis. It is possible to shoot a moving image and perform sensing with use of a solid-state imaging device based on the light receiving device of the present disclosure.

Further, in Examples described above, the wire grid polarizer is used only for acquisition of polarization information at the photoelectric conversion section having sensitivity to a visible light wavelength band; however, in a case where the photoelectric conversion section has sensitivity to infrared light or ultraviolet light, implementation as a wire grid polarizer functioning in any wavelength band is possible by increasing or decreasing the formation pitch Q₀ of the line section accordingly.

Depending on cases, a trench (a kind of element separation region) extending from the substrate to a position below the wire grid polarizer and filled with an insulating material or a light-blocking material may be formed at an edge part of the photoelectric conversion section. Examples of the insulating material may include the material included in the insulating film (insulating-film-forming layer) or the interlayer insulating layer. Examples of the light-blocking material may include the material included in the light-blocking film 24 described above. By forming such a trench, it is possible to prevent reduction in sensitivity, occurrence of polarization crosstalk, and reduction in extinction ratio.

A waveguide structure may be provided between the photoelectric conversion sections 21. The waveguide structure includes a thin film that is formed in a region (e.g., a cylindrical region) located between the photoelectric conversion sections 21 in the lower interlayer insulating layer 33 (specifically, a portion of the lower interlayer insulating layer 33) covering the photoelectric conversion sections 21 and has a refractive index of a value greater than a value of a refractive index of the material included in the lower interlayer insulating layer 33. Light entering from above the photoelectric conversion sections 21 is totally reflected by this thin film and reaches the photoelectric conversion sections 21. An orthographic projection image of the photoelectric conversion sections 21 with respect to the semiconductor substrate 31 is located inside an orthographic projection image of the thin film included in the waveguide structure with respect to the semiconductor substrate 31. The orthographic projection image of the photoelectric conversion sections 21 with respect to the semiconductor substrate 31 is surrounded by the orthographic projection image of the thin film included in the waveguide structure with respect to the semiconductor substrate.

Alternatively, a light-condensing tube structure may be provided between the photoelectric conversion sections 21. The light-condensing tube structure includes a light-blocking thin film including a metal material or an alloy material and formed in a region (e.g., a cylindrical region) located between the photoelectric conversion sections 21 in the lower interlayer insulating layer 33 covering the photoelectric conversion sections 21. Light entering from above the photoelectric conversion sections 21 is reflected by this thin film and reaches the photoelectric conversion sections 21. That is, the orthographic projection image of the photoelectric conversion sections 21 with respect to the semiconductor substrate 31 is located inside an orthographic projection image of the thin film included in the light-condensing tube structure with respect to the semiconductor substrate 31. In addition, the orthographic projection image of the photoelectric conversion sections 21 with respect to the semiconductor substrate 31 is surrounded by the orthographic projection image of the thin film included in the light-condensing tube structure with respect to the semiconductor substrate 31. For example, the thin film is obtainable by forming an annular trench in the lower interlayer insulating layer 33 after forming all of the lower interlayer insulating layer 33, and filling the trench with a metal material or an alloy material.

A 2×2 pixel sharing method is adoptable in which a selection transistor, a reset transistor, and an amplifier transistor are shared among 2×2 photoelectric conversion sections. In an imaging mode involving no pixel addition, it is possible to perform imaging including polarization information, whereas in a mode involving FD addition of accumulated electric charge in 2×2 sub-pixel regions, it is possible to provide an ordinary captured image in which all polarized components have been integrated.

In addition, in Examples, the description has been given of an example case of application to a CMOS type solid-state imaging device including unit pixels arranged in a matrix form, the unit pixels detecting signal electric charge corresponding to the amount of entering light as a physical quantity; however, possible applications are not limited to the CMOS type solid-state imaging device and may include a CCD type solid-state imaging device. In the latter case, the signal electric charge is transferred in a vertical direction by a vertical transfer register having a CCD type structure and is transferred in a horizontal direction by a horizontal transfer register. The transferred signal electric charge is amplified and is thereby outputted as a pixel signal (image signal). Further, the applications are not limited to a column type solid-state imaging device in general that includes pixels arranged in a two-dimensional matrix form with a column signal processing circuit provided for each pixel column. Moreover, depending on cases, the selection transistor may be omitted.

Moreover, the photoelectric conversion element (imaging element) of the present disclosure is applicable not only to a solid-state imaging device that detects a distribution of entering light amounts of visible light and captures the distribution as an image, but also to a solid-state imaging device that captures a distribution of amounts of entry of infrared light, X-rays, particles, or the like as an image. In addition, in a broad sense, the photoelectric conversion element of the present disclosure is applicable to a solid-state imaging device (physical quantity distribution detection device) in general, such as a fingerprint detection sensor, that detects a distribution of any of other physical quantities including pressure and electrostatic capacitance.

Moreover, the application is not limited to a solid-state imaging device that sequentially scans unit pixels in an imaging region on a row-by-row basis and reads respective pixel signals from the unit pixels. Possible applications also include an X-Y address type solid-state imaging device that selects any pixels on a pixel-by-pixel basis and reads pixel signals from the selected pixels on a pixel-by-pixel basis. The solid-state imaging device may be formed as one chip, or may be in a module form with an imaging function in which an imaging region and a drive circuit or an optical system are integrated into a package.

In addition, the possible applications are not limited to the solid-state imaging device, and may include an imaging device. The imaging device here refers to a camera system such as a digital still camera or a video camera, and an electronic apparatus having an imaging function, such as a cellular phone. In some cases, the imaging device may be in a module form to be mounted on an electronic apparatus, that is, the imaging device may be a camera module.

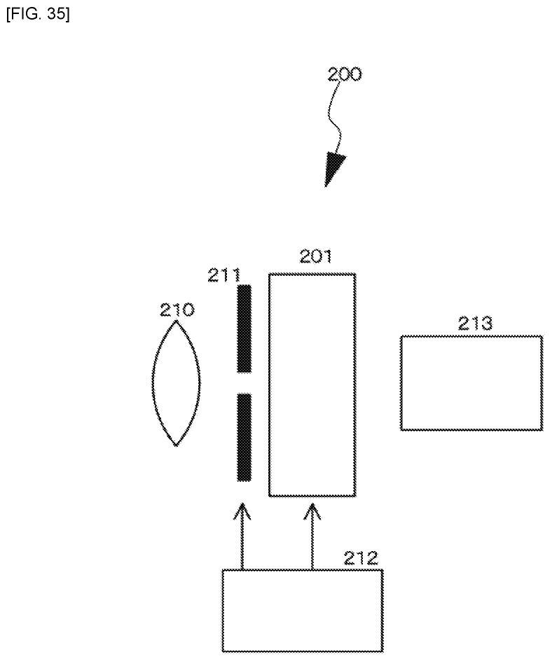

An example in which a solid-state imaging device 201 of the present disclosure is used in an electronic apparatus (a camera) 200 is illustrated in FIG. 35 as a conceptual diagram. The electronic apparatus 200 includes the solid-state imaging device 201, an optical lens 210, a shutter device 211, a drive circuit 212, and a signal processing circuit 213. The optical lens 210 causes an image light (entering light) from a subject to form an image on an imaging plane of the solid-state imaging device 201. Accordingly, signal electric charge is accumulated in the solid-state imaging device 201 for a certain period of time. The shutter device 211 controls a period during which the solid-state imaging device 201 is to be irradiated with light and a period during which the light to the solid-state imaging device 201 is to be blocked. The drive circuit 212 supplies a drive signal for controlling a transfer operation and the like of the solid-state imaging device 201 and a shutter operation of the shutter device 211. Signal transfer of the solid-state imaging device 201 is performed in accordance with the drive signal (timing signal) supplied from the drive circuit 212. The signal processing circuit 213 performs various kinds of signal processing. A video signal having undergone signal processing is stored in a storage medium such as a memory, or is outputted to a monitor. According to such an electronic apparatus 200, it is possible to achieve finer pixel size and improved transfer efficiency in the solid-state imaging device 201. This makes it possible to obtain the electronic apparatus 200 that achieves an improved pixel characteristic. The electronic apparatus 200 to which the solid-state imaging device 201 is applicable is not limited to a camera, and possible applications include an imaging device such as a digital still camera or a camera module for a mobile apparatus such as a cellular phone.

It is to be noted that the present disclosure may have the following configurations.

### [A01]<<Light Receiving Device . . . First Aspect>>

A light receiving device including a plurality of photoelectric conversion element units, in which
each of the photoelectric conversion element units includes a plurality of photoelectric conversion elements, the photoelectric conversion elements being M×N in total number, with M photoelectric conversion elements arranged in a first direction, and N photoelectric conversion elements arranged in a second direction different from the first direction,
each of the photoelectric conversion elements includes a quarter wavelength layer, a wire grid polarizer, and a photoelectric conversion section that are disposed in this order from a light entrance side,
the M photoelectric conversion elements disposed side by side along the first direction include the quarter wavelength layers that have the same fast axis orientation,
the N photoelectric conversion elements disposed side by side along the second direction include the quarter wavelength layers that have different fast axis orientations,
the N photoelectric conversion elements disposed side by side along the second direction include the wire grid polarizers that have the same polarization orientation, and
the M photoelectric conversion elements disposed side by side along the first direction include the wire grid polarizers that have different polarization orientations.

### [A02]

The light receiving device according to [A01], in which each of the photoelectric conversion element units includes M kinds of wire grid polarizers and N kinds of quarter wavelength layers.

### [A03]

The light receiving device according to [A01] or [A02], in which M=N=2a (where a is an integer greater than or equal to 2).

### [A04]

The light receiving device according to [A03], in which polarization orientations of the M kinds of wire grid polarizers are (180/2a)×m [degrees] (where m=0, 1, 2, 3 . . . , [2a−1]), and fast axis orientations of the N kinds of quarter wavelength layers are (180/2a)×n [degrees] (where n=0, 1, 2, 3 . . . , [2a−1]).

### [B01] <<Light Receiving Device . . . Second Aspect Method of Measuring Polarized State of Object>>

A polarized state measuring method for an object using a light receiving device, in which
the light receiving device includes a plurality of photoelectric conversion element units,
each of the photoelectric conversion element units includes a plurality of photoelectric conversion elements, the photoelectric conversion elements being M×N in total number, with M photoelectric conversion elements arranged in a first direction, and N photoelectric conversion elements arranged in a second direction different from the first direction,
each of the photoelectric conversion elements includes a quarter wavelength layer, a wire grid polarizer, and a photoelectric conversion section that are disposed in this order from a light entrance side,
the M photoelectric conversion elements disposed side by side along the first direction include the quarter wavelength layers that have the same fast axis orientation,
the N photoelectric conversion elements disposed side by side along the second direction include the quarter wavelength layers that have different fast axis orientations,
the N photoelectric conversion elements disposed side by side along the second direction include the wire grid polarizers that have the same polarization orientation, and
the M photoelectric conversion elements disposed side by side along the first direction include the wire grid polarizers that have different polarization orientations,
the polarized state measuring method including
   acquiring image data by capturing an image of the object with the light receiving device, and
   obtaining a comparison result by comparing, at the light receiving device, the image data acquired that indicates a polarized state with standard polarized state data of a standard object.

### [B02]

The polarized state measuring method for an object according to [B01], including applying light having a predetermined polarized state and wavelength to the object to thereby capture an image of the object with the light receiving device.

### [B03]

The polarized state measuring method for an object according to [B01] or [B02], including evaluating a surface state of the object by obtaining the comparison result.

### [B04]

The polarized state measuring method for an object according to [B01] or [B02], including evaluating a state of a film thickness of the object that is in a thin-film form, by obtaining the comparison result on the object.

### [B05]

The polarized state measuring method for an object according to [B01] or [B02], including evaluating presence of a foreign substance in the object by obtaining the comparison result.

### [C01]<<Light Receiving Device . . . Second Aspect>>

A light receiving device including a plurality of photoelectric conversion element units, in which
each of the photoelectric conversion element units includes a first photoelectric conversion element, a second photoelectric conversion element, a third photoelectric conversion element, a fourth photoelectric conversion element, a fifth photoelectric conversion element, and a sixth photoelectric conversion element,
the first photoelectric conversion element, the second photoelectric conversion element, the third photoelectric conversion element, and the fourth photoelectric conversion element each include a wire grid polarizer and a photoelectric conversion section that are disposed in this order from a light entrance side,
the fifth photoelectric conversion element and the sixth photoelectric conversion element each include a quarter wavelength layer, a wire grid polarizer, and a photoelectric conversion section that are disposed in this order from the light entrance side,
a polarization orientation targeted for transmission by the wire grid polarizer included in the first photoelectric conversion element is α degrees,
a polarization orientation targeted for transmission by the wire grid polarizer included in the second photoelectric conversion element is (α+45) degrees,
a polarization orientation targeted for transmission by the wire grid polarizer included in the third photoelectric conversion element is (α+90) degrees,
a polarization orientation targeted for transmission by the wire grid polarizer included in the fourth photoelectric conversion element is (α+135) degrees,
a polarization orientation targeted for transmission by the wire grid polarizer included in the fifth photoelectric conversion element is α′ degrees,
a polarization orientation targeted for transmission by the wire grid polarizer included in the sixth photoelectric conversion element is α′ degrees, and
where a fast axis orientation of the quarter wavelength layer included in the fifth photoelectric conversion element is β degrees, a fast axis orientation of the quarter wavelength layer included in the sixth photoelectric conversion element is (β±90) degrees.

### [C02]

The light receiving device according to [C01], in which α′=(β±45) degrees is satisfied.

### [C03]

The light receiving device according to [C01] or [C02], in which
each of the photoelectric conversion element units includes a total of 3×2 photoelectric conversion elements, with three photoelectric conversion elements in a first direction, and two photoelectric conversion elements in a second direction different from the first direction, and
the first photoelectric conversion element, the second photoelectric conversion element, and the fifth photoelectric conversion element are disposed in no particular order in a first row along the first direction, and the third photoelectric conversion element, the fourth photoelectric conversion element, and the sixth photoelectric conversion element are disposed in no particular order in a second row along the first direction.

### [C04]

The light receiving device according to any one of [C01] to [C03], in which at least light including a linearly polarized light component and light including a circularly polarized light component enter the photoelectric conversion element units in a mixed state.

### [C05]

The light receiving device according to [C04], in which
the wire grid polarizer included in the first photoelectric conversion element passes light including a component having a polarization orientation of α degrees, of the light including the linearly polarized light component, and light including a component having the polarization orientation of α degrees, of the light including the circularly polarized light component,
the wire grid polarizer included in the second photoelectric conversion element passes light including a component having a polarization orientation of (α+45) degrees, of the light including the linearly polarized light component, and light including a component having the polarization orientation of (α+45) degrees, of the light including the circularly polarized light component,
the wire grid polarizer included in the third photoelectric conversion element passes light including a component having a polarization orientation of (α+90) degrees, of the light including the linearly polarized light component, and light including a component having the polarization orientation of (α+90) degrees, of the light including the circularly polarized light component, and
the wire grid polarizer included in the fourth photoelectric conversion element passes light including a component having a polarization orientation of (α+135) degrees, of the light including the linearly polarized light component, and light including a component having the polarization orientation of (α+135) degrees, of the light including the circularly polarized light component.

### [C06]

The light receiving device according to [C05], further including a data processor, in which
where an amount of light obtainable by the photoelectric conversion section included in the first photoelectric conversion element is denoted by AL₁, an amount of light obtainable by the photoelectric conversion section included in the second photoelectric conversion element is denoted by AL₂, an amount of light obtainable by the photoelectric conversion section included in the third photoelectric conversion element is denoted by AL₃, an amount of light obtainable by the photoelectric conversion section included in the fourth photoelectric conversion element is denoted by AL₄, an amount of light obtainable by the photoelectric conversion section included in the fifth photoelectric conversion element is denoted by AL₅, and an amount of light obtainable by the photoelectric conversion section included in the sixth photoelectric conversion element is denoted by AL₆, the data processor
   determines ΔAL′=AL₅− AL₆ in a case where AL₅≥AL₆, and
   determines ΔAL′=AL₆− AL₅ in a case where AL₅<AL₆, and
the data processor further determines α degree of polarization from a difference ΔAL between a maximum value and a minimum value of a fitting curve obtainable on the basis of the amounts of light AL₁, AL₂, AL₃, and AL₄, and from ΔAL′.

### [C07]

The light receiving device according to [C06], in which the degree of polarization is determined by:
degree of polarization=ΔAL/(ΔAL+ΔAL′).

### [C08]

The light receiving device according to [C07], in which the data processor displays, of obtained image data, a region where the degree of polarization is high and a region where the degree of polarization is low in different colors.

### [D01]<<Light Receiving Device . . . Third Aspect>>

A light receiving device including a plurality of photoelectric conversion element units, in which
each of the photoelectric conversion element units includes a first photoelectric conversion element, a second photoelectric conversion element, a third photoelectric conversion element, and a fourth photoelectric conversion element,
the first photoelectric conversion element, the second photoelectric conversion element, the third photoelectric conversion element, and the fourth photoelectric conversion element each include a first quarter wavelength layer, a second quarter wavelength layer, a wire grid polarizer, and a photoelectric conversion section that are disposed in this order from a light entrance side,
a polarization orientation targeted for transmission by the wire grid polarizer included in the first photoelectric conversion element is α degrees,
a polarization orientation targeted for transmission by the wire grid polarizer included in the second photoelectric conversion element is (α+45) degrees,
a polarization orientation targeted for transmission by the wire grid polarizer included in the third photoelectric conversion element is (α+90) degrees,
a polarization orientation targeted for transmission by the wire grid polarizer included in the fourth photoelectric conversion element is (α+135) degrees,
a fast axis orientation of the first quarter wavelength layer included in the first photoelectric conversion element is β degrees,
a fast axis orientation of the first quarter wavelength layer included in the second photoelectric conversion element is (β+45) degrees,
a fast axis orientation of the first quarter wavelength layer included in the third photoelectric conversion element is (β+90) degrees,
a fast axis orientation of the first quarter wavelength layer included in the fourth photoelectric conversion element is (β+135) degrees, and
in each of the photoelectric conversion elements, an angle formed between a fast axis orientation of the second quarter wavelength layer and the fast axis orientation of the first quarter wavelength layer is ±45 degrees.

### [D02]

The light receiving device according to [D01], in which α=β.

### [E01]

The light receiving device according to any one of [C01] to [D02], including a plurality of photoelectric conversion element unit groups that is two-dimensionally arranged, in which
one photoelectric conversion element unit group includes four photoelectric conversion element units disposed 2×2,
a first photoelectric conversion element unit includes a first filter layer that passes light in a first wavelength range,
a second photoelectric conversion element unit includes a second filter layer that passes light in a second wavelength range,
a third photoelectric conversion element unit includes a third filter layer that passes light in a third wavelength range, and
a fourth photoelectric conversion element unit includes a fourth filter layer that passes light in a fourth wavelength range.

### [E02]

The light receiving device according to [E01], in which
a first quarter wavelength layer included in the first photoelectric conversion element unit gives a phase difference to the light in the first wavelength range,
a second quarter wavelength layer included in the second photoelectric conversion element unit gives a phase difference to the light in the second wavelength range,
a third quarter wavelength layer included in the third photoelectric conversion element unit gives a phase difference to the light in the third wavelength range, and
a fourth quarter wavelength layer included in the fourth photoelectric conversion element unit gives a phase difference to the light in the fourth wavelength range.

### [E03]

The light receiving device according to [E02], in which the first quarter wavelength layer, the second quarter wavelength layer, the third quarter wavelength layer, and the fourth quarter wavelength layer are disposed in different layers.

### [E04]

The light receiving device according to [E03], in which
the quarter wavelength layer includes a first dielectric layer including a material having a refractive index n₁ and a second dielectric layer including a material having a refractive index n₂ (where n₁>n₂) that are alternately disposed side by side,
thicknesses of the first dielectric layer and the second dielectric layer included in the first quarter wavelength layer, thicknesses of the first dielectric layer and the second dielectric layer included in the second quarter wavelength layer, thicknesses of the first dielectric layer and the second dielectric layer included in the third quarter wavelength layer, and thicknesses of the first dielectric layer and the second dielectric layer included in the fourth quarter wavelength layer are the same, and
the first quarter wavelength layer, the second quarter wavelength layer, the third quarter wavelength layer, and the fourth quarter wavelength layer have different layer thicknesses.

### [E05]

The light receiving device according to [E02], in which the first quarter wavelength layer, the second quarter wavelength layer, the third quarter wavelength layer, and the fourth quarter wavelength layer are disposed in the same layer.

### [E06]

The light receiving device according to [E05], in which
the quarter wavelength layer includes a first dielectric layer including a material having a refractive index n₁ and a second dielectric layer including a material having a refractive index n₂ (where n₁>n₂) that are alternately disposed side by side,
thicknesses of the first dielectric layer and the second dielectric layer included in the first quarter wavelength layer, thicknesses of the first dielectric layer and the second dielectric layer included in the second quarter wavelength layer, thicknesses of the first dielectric layer and the second dielectric layer included in the third quarter wavelength layer, and thicknesses of the first dielectric layer and the second dielectric layer included in the fourth quarter wavelength layer are different, and
the first quarter wavelength layer, the second quarter wavelength layer, the third quarter wavelength layer, and the fourth quarter wavelength layer have the same layer thickness.

### [E07]

The light receiving device according to any one of [A01] to [E06], in which the quarter wavelength layer includes a first dielectric layer including a material having a refractive index n₁ and a second dielectric layer including a material having a refractive index n₂ that are alternately disposed side by side,

### [F01]

The light receiving device according to any one of [A0l] to [E07], in which
a protective film is formed on the wire grid polarizer,
the wire grid polarizer has a line-and-space structure, and
a space part of the wire grid polarizer is an empty space.

### [F02]

The light receiving device according to [F01], in which
a second protective film is provided between the wire grid polarizer and the protective film, and
n₁′>n₂′ is satisfied where n₁′ represents a refractive index of a material included in the protective film and n₂′ represents a refractive index of a material included in the second protective film.

### [F03]

The light receiving device according to [F02], in which the protective film includes SiN and the second protective film includes SiO₂ or SiON.

### [F04]

The light receiving device according to any one of [F01] to [F03], in which a third protective film is provided at least on a side surface of a line part facing the space part of the wire grid polarizer.

### [F05]

The light receiving device according to any one of [F01] to [F04], further including a frame part surrounding the wire grid polarizer, in which
the frame part and a line part of the wire grid polarizer are coupled to each other, and
the frame part has the same structure as the line part of the wire grid polarizer.

### [F06]

The light receiving device according to any one of [F01] to [F05], in which a line part of the wire grid polarizer includes a stack structure in which a light reflection layer including a first electrically-conductive material, an insulating film, and a light absorption layer including a second electrically-conductive material are stacked from side of the photoelectric conversion section.

### [F07]

The light receiving device according to [F06], in which the light reflection layer and the light absorption layer are common to the photoelectric conversion elements.

### [F08]

The light receiving device according to [F06] or [F07], in which the insulating film is formed on an entire top surface of the light reflection layer, and the light absorption layer is formed on an entire top surface of the insulating film.

### [F09]

The light receiving device according to any one of [F06] to [F08], in which an underlying insulating layer is formed below the light reflection layer.

### [F10]

The light receiving device according to any one of [F06] to [F09], in which the insulating film is formed on an entire top surface of the light reflection layer, and the light absorption layer is formed on an entire top surface of the insulating film.

### [G01]

The light receiving device according to any one of [A01] to [F10], in which a memory section is formed in a semiconductor substrate, the memory section being coupled to the photoelectric conversion section and temporarily holding electric charge generated at the photoelectric conversion section.

The present application claims the benefit of Japanese Priority Patent Application JP2020-182692 filed with the Japan Patent Office on Oct. 30, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

3. The light receiving device according to claim 1, wherein M=N=2a (where a is an integer greater than or equal to 2).

4. The light receiving device according to claim 3, wherein polarization orientations of the M kinds of the wire grid polarizers are (180/2a)×m [degrees] (where m=0, 1, 2, 3 . . . , [2a−1]), and fast axis orientations of the N kinds of the quarter wavelength layers are (180/2a)×n [degrees] (where n=0, 1, 2, 3 . . . , [2a−1]).

5. A polarized state measuring method for an object using a light receiving device, wherein
the light receiving device includes a plurality of photoelectric conversion element units,
each of the photoelectric conversion element units includes a plurality of photoelectric conversion elements, the photoelectric conversion elements being M×N in total number, with M photoelectric conversion elements arranged in a first direction, and N photoelectric conversion elements arranged in a second direction different from the first direction,
each of the photoelectric conversion elements includes a quarter wavelength layer, a wire grid polarizer, and a photoelectric conversion section that are disposed in this order from a light entrance side,
the M photoelectric conversion elements disposed side by side along the first direction include the quarter wavelength layers that have a same fast axis orientation,
the N photoelectric conversion elements disposed side by side along the second direction include the quarter wavelength layers that have different fast axis orientations,
the N photoelectric conversion elements disposed side by side along the second direction include the wire grid polarizers that have a same polarization orientation, and
the M photoelectric conversion elements disposed side by side along the first direction include the wire grid polarizers that have different polarization orientations,
the polarized state measuring method comprising
acquiring image data by capturing an image of the object with the light receiving device, and
obtaining a comparison result by comparing, at the light receiving device, the image data acquired that indicates a polarized state with standard polarized state data of a standard object.

6. The polarized state measuring method for an object according to claim 5, comprising applying light having a predetermined polarized state and wavelength to the object to thereby capture the image of the object with the light receiving device.

7. The polarized state measuring method for an object according to claim 5, comprising evaluating a surface state of the object by obtaining the comparison result.

8. The polarized state measuring method for an object according to claim 5, comprising evaluating a state of a film thickness of the object that is in a thin-film form, by obtaining the comparison result on the object.

9. The polarized state measuring method for an object according to claim 5, comprising evaluating presence of a foreign substance in the object by obtaining the comparison result.

10. A light receiving device comprising a plurality of photoelectric conversion element units, wherein
each of the photoelectric conversion element units includes a first photoelectric conversion element, a second photoelectric conversion element, a third photoelectric conversion element, a fourth photoelectric conversion element, a fifth photoelectric conversion element, and a sixth photoelectric conversion element,
the first photoelectric conversion element, the second photoelectric conversion element, the third photoelectric conversion element, and the fourth photoelectric conversion element each include a wire grid polarizer and a photoelectric conversion section that are disposed in this order from a light entrance side,
the fifth photoelectric conversion element and the sixth photoelectric conversion element each include a quarter wavelength layer, a wire grid polarizer, and a photoelectric conversion section that are disposed in this order from the light entrance side,
a polarization orientation targeted for transmission by the wire grid polarizer included in the first photoelectric conversion element is α degrees,
a polarization orientation targeted for transmission by the wire grid polarizer included in the second photoelectric conversion element is (α+45) degrees,
a polarization orientation targeted for transmission by the wire grid polarizer included in the third photoelectric conversion element is (α+90) degrees,
a polarization orientation targeted for transmission by the wire grid polarizer included in the fourth photoelectric conversion element is (α+135) degrees,
a polarization orientation targeted for transmission by the wire grid polarizer included in the fifth photoelectric conversion element is α′ degrees,
a polarization orientation targeted for transmission by the wire grid polarizer included in the sixth photoelectric conversion element is α′ degrees, and
where a fast axis orientation of the quarter wavelength layer included in the fifth photoelectric conversion element is β degrees, a fast axis orientation of the quarter wavelength layer included in the sixth photoelectric conversion element is (β±90) degrees.

11. The light receiving device according to claim 10, wherein α′=(β±45) degrees is satisfied.

12. The light receiving device according to claim 10, wherein
each of the photoelectric conversion element units includes a total of 3×2 photoelectric conversion elements, with three photoelectric conversion elements in a first direction, and two photoelectric conversion elements in a second direction different from the first direction, and
the first photoelectric conversion element, the second photoelectric conversion element, and the fifth photoelectric conversion element are disposed in no particular order in a first row along the first direction, and the third photoelectric conversion element, the fourth photoelectric conversion element, and the sixth photoelectric conversion element are disposed in no particular order in a second row along the first direction.

13. The light receiving device according to claim 10, wherein at least light including a linearly polarized light component and light including a circularly polarized light component enter the photoelectric conversion element units in a mixed state.

14. The light receiving device according to claim 13, wherein
the wire grid polarizer included in the first photoelectric conversion element passes light including a component having a polarization orientation of α degrees, of the light including the linearly polarized light component, and light including a component having the polarization orientation of α degrees, of the light including the circularly polarized light component,
the wire grid polarizer included in the second photoelectric conversion element passes light including a component having a polarization orientation of (α+45) degrees, of the light including the linearly polarized light component, and light including a component having the polarization orientation of (α+45) degrees, of the light including the circularly polarized light component,
the wire grid polarizer included in the third photoelectric conversion element passes light including a component having a polarization orientation of (α+90) degrees, of the light including the linearly polarized light component, and light including a component having the polarization orientation of (α+90) degrees, of the light including the circularly polarized light component, and
the wire grid polarizer included in the fourth photoelectric conversion element passes light including a component having a polarization orientation of (α+135) degrees, of the light including the linearly polarized light component, and light including a component having the polarization orientation of (α+135) degrees, of the light including the circularly polarized light component.

15. The light receiving device according to claim 14, further comprising a data processor, wherein
where an amount of light obtainable by the photoelectric conversion section included in the first photoelectric conversion element is denoted by AL1, an amount of light obtainable by the photoelectric conversion section included in the second photoelectric conversion element is denoted by AL2, an amount of light obtainable by the photoelectric conversion section included in the third photoelectric conversion element is denoted by AL3, an amount of light obtainable by the photoelectric conversion section included in the fourth photoelectric conversion element is denoted by AL4, an amount of light obtainable by the photoelectric conversion section included in the fifth photoelectric conversion element is denoted by AL5, and an amount of light obtainable by the photoelectric conversion section included in the sixth photoelectric conversion element is denoted by AL6, the data processor
determines ΔAL′=AL5−AL6 in a case where AL5≥AL6, and
determines ΔAL′=AL6−AL5 in a case where AL5<AL6, and
the data processor further determines α degree of polarization from a difference ΔAL between a maximum value and a minimum value of a fitting curve obtainable on a basis of the amounts of light AL₁, AL₂, AL₃, and AL₄, and from ΔAL′.

16. The light receiving device according to claim 15, wherein the degree of polarization is determined by:
degree of polarization=ΔAL/(ΔAL+ΔAL′).

17. The light receiving device according to claim 16, wherein the data processor displays, of obtained image data, a region where the degree of polarization is high and a region where the degree of polarization is low in different colors.

18. A light receiving device comprising a plurality of photoelectric conversion element units, wherein
each of the photoelectric conversion element units includes a first photoelectric conversion element, a second photoelectric conversion element, a third photoelectric conversion element, and a fourth photoelectric conversion element,
the first photoelectric conversion element, the second photoelectric conversion element, the third photoelectric conversion element, and the fourth photoelectric conversion element each include a first quarter wavelength layer, a second quarter wavelength layer, a wire grid polarizer, and a photoelectric conversion section that are disposed in this order from a light entrance side,
a polarization orientation targeted for transmission by the wire grid polarizer included in the first photoelectric conversion element is α degrees,
a polarization orientation targeted for transmission by the wire grid polarizer included in the second photoelectric conversion element is (α+45) degrees,
a polarization orientation targeted for transmission by the wire grid polarizer included in the third photoelectric conversion element is (α+90) degrees,
a polarization orientation targeted for transmission by the wire grid polarizer included in the fourth photoelectric conversion element is (α+135) degrees,
a fast axis orientation of the first quarter wavelength layer included in the first photoelectric conversion element is β degrees,
a fast axis orientation of the first quarter wavelength layer included in the second photoelectric conversion element is (β+45) degrees,
a fast axis orientation of the first quarter wavelength layer included in the third photoelectric conversion element is (β+90) degrees,
a fast axis orientation of the first quarter wavelength layer included in the fourth photoelectric conversion element is (β+135) degrees, and
in each of the photoelectric conversion elements, an angle formed between a fast axis orientation of the second quarter wavelength layer and the fast axis orientation of the first quarter wavelength layer is ±45 degrees.

19. The light receiving device according to claim 18, wherein α=β.
